(19) United States
(12) Patent Application Publication
(10) Pub. No.: US 2026/0221163 A1
(43) Pub. Date: Jul. 30, 2026

(54) THREE-DIMENSIONAL MEMORY DEVICE WITH THROUGH-VIA CONTACT STRUCTURES AND DUMMY WORD LINES IN CONTACT REGION AND METHODS FOR FORMING THE SAME

(71) Applicant: Sandisk Technologies, Inc., Milpitas, CA (US)

(72) Inventors: Masanori TSUTSUMI, Yokkaichi (JP); Kento ISERI, Yokkaichi (JP)

(21) Appl. No.: 19/041,265

(22) Filed: Jan. 30, 2025

(51) Int. Cl. G11C 5/06; G11C 16/04; H10B 41/10; H10B 41/27; H10B 41/35; H10B 43/10; H10B 43/27; H10B 43/35

(52) U.S. Cl. CPC G11C 5/063; G11C 16/0483; H10B 41/10; H10B 41/27; H10B 41/35; H10B 43/10; H10B 43/27; H10B 43/35

(57) ABSTRACT

A device structure includes an alternating stack of insulating layers and electrically conductive layers embedding a retro-stepped dielectric material portion. The electrically conductive layers include active electrically conductive layers located below a horizontal plane including a topmost surface of the retro-stepped dielectric material portion and at least one dummy electrically conductive layer overlying the retro-stepped dielectric material portion. Memory openings vertically extend through each of the active electrically conductive layers and are laterally spaced from each of the at least one dummy electrically conductive layer. Memory opening fill structures are located in the memory openings.

### FIELD

The present disclosure relates generally to the field of semiconductor devices, and particularly to a three-dimensional memory device including through-via contact structures and dummy word lines in a contact region and methods for forming the same.

### BACKGROUND

A three-dimensional memory device including three-dimensional vertical NAND strings having one bit per cell is disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a device structure comprises: an alternating stack of insulating layers and electrically conductive layers embedding a retro-stepped dielectric material portion, wherein the electrically conductive layers comprise active electrically conductive layers located below a horizontal plane including a topmost surface of the retro-stepped dielectric material portion and at least one dummy electrically conductive layer overlying the retro-stepped dielectric material portion; memory openings vertically extending through each of the active electrically conductive layers and laterally spaced from each of the at least one dummy electrically conductive layer; and memory opening fill structures located in the memory openings, wherein each of the memory opening fill structures comprises a respective vertical stack of memory elements located at levels of the active electrically conductive layers, a vertical semiconductor channel vertically extending through each of the active electrically conductive layers, and a drain region located above the horizontal plane.

According to another aspect of the present disclosure, a method of forming a device structure comprises: forming an alternating stack of insulating layers and active sacrificial material layers embedding a retro-stepped dielectric material portion over a substrate; forming at least one dummy sacrificial material layer over the retro-stepped dielectric material portion such that the at least one dummy sacrificial material layer does not cover a memory array region in a plan view; forming memory openings through the alternating stack in the memory array region; forming memory opening fill structures in the memory openings, wherein each of the memory openings comprises a respective vertical stack of memory elements; forming lateral isolation trenches through a combination of the alternating stack, the retro-stepped dielectric material portion, and the at least one dummy sacrificial material layer; and replacing remaining portions of the active sacrificial material layers and the at least one dummy sacrificial material layer with electrically conductive layers, wherein the electrically conductive layers comprise active electrically conductive layers that replace the remaining portions of the active sacrificial material layers and at least one dummy electrically conductive layer that replaces remaining portions of the at least one dummy sacrificial material layer.

### BRIEF DESCRIPTION OF THE DRAWINGS

Within each of FIGS. 2A-2E , FIGS. 5A-15E, 17A-18E, and 22A-29E, each figure is labeled with a combination of a figure numeral and an alphabetical suffix. Each set of figures with the same figure numeral corresponds to views for a first exemplary structure at a same processing step. Each figure with the alphabetical suffix “A” is a vertical cross-sectional view along a first horizontal direction. Each figure with the alphabetical suffix “B” is a vertical cross-sectional view along a vertical plane B-B′ in the figure with the same figure numeral and the alphabetical suffix “A.” Each figure with the alphabetical suffix “C” is a vertical cross-sectional view along a vertical plane C-C′ in the figure with the same figure numeral and the alphabetical suffix “A.” Each figure with the alphabetical suffix “D” is a vertical cross-sectional view along a vertical plane -DD′ in the figure with the same figure numeral and the alphabetical suffix “A.” Each figure with the alphabetical suffix “E” is a top-down view for the first exemplary structure shown in figures with the same figure numeral and alphabetical suffices “A,” “B,” “C,” and “D.”

FIG. 1 is a vertical cross-sectional view of a first exemplary structure for forming a semiconductor die after formation of a vertically alternating sequence of first-tier continuous insulating layers and first-tier continuous sacrificial material layers according to an embodiment of the present disclosure.

FIGS. 2A-2E are various views of the first exemplary structure after formation of first-tier stepped cavities according to an embodiment of the present disclosure.

FIGS. 3A-3C are sequential vertical cross-sectional views of a region of the first exemplary structure during thickening of physically-exposed portions of the first-tier active sacrificial material layers according to an embodiment of the present disclosure.

FIGS. 4A-4E are sequential vertical cross-sectional views of a region of the first exemplary structure during a sequence of processing steps that may be employed to locally thicken the physically-exposed portions of the first-tier active sacrificial material layers according to an embodiment of the present disclosure.

FIGS. 5A-5E are various view of the first exemplary structure after local thickening of physically exposed portions of the first-tier continuous sacrificial material layers according to an embodiment of the present disclosure.

FIGS. 6A-6E are various view of the first exemplary structure after formation of first-tier retro-stepped dielectric material portions according to an embodiment of the present disclosure.

FIGS. 7A-7E are various view of the first exemplary structure after deposition and patterning first-tier dummy insulating layers and first-tier dummy sacrificial material layers according to an embodiment of the present disclosure.

FIGS. 8A-8E are various view of the first exemplary structure after formation of a first-tier insulating cap layer according to an embodiment of the present disclosure.

FIGS. 9A-9E are various views of the first exemplary structure after formation of various first-tier openings and various first-tier sacrificial opening fill structures according to an embodiment of the present disclosure.

FIGS. 10A-10E are various views of the first exemplary structure after formation of a vertically alternating sequence of second-tier continuous insulating layers and second-tier continuous sacrificial material layers, and second-tier retro-stepped dielectric material portions according to an embodiment of the present disclosure.

FIGS. 11A-11E are various view of the first exemplary structure after deposition and patterning second-tier dummy insulating layers and second-tier dummy sacrificial material layers according to an embodiment of the present disclosure.

FIGS. 12A-12E are various view of the first exemplary structure after formation of a second-tier insulating cap layer according to an embodiment of the present disclosure.

FIGS. 13A-13E are various views of the first exemplary structure after formation of various second-tier openings and various second-tier sacrificial opening fill structures according to an embodiment of the present disclosure.

FIGS. 14A-14E are various views of the first exemplary structure after formation of dielectric support pillar structures according to an embodiment of the present disclosure.

FIGS. 15A-15E are various views of the first exemplary structure after formation of memory openings according to an embodiment of the present disclosure.

FIGS. 16A-16F illustrate sequential vertical cross-sectional views of a memory opening during formation of a memory opening fill structure according to an embodiment of the present disclosure.

FIGS. 17A-17E are various views of the first exemplary structure after formation of memory opening fill structures according to an embodiment of the present disclosure.

FIGS. 18A-18E are various views of the first exemplary structure after formation of a contact-level dielectric layer and connection cavities according to an embodiment of the present disclosure.

FIG. 19 is a vertical cross-sectional view of the first exemplary structure after formation of contact via cavities according to an embodiment of the present disclosure.

FIG. 20 is a vertical cross-sectional view of the first exemplary structure after formation of annular lateral recesses around the contact via cavities according to an embodiment of the present disclosure.

FIG. 21 is a vertical cross-sectional view of the first exemplary structure after formation of annular dielectric spacers in a subset of the annular lateral recesses according to an embodiment of the present disclosure.

FIGS. 22A-22E are various views of the first exemplary structure after formation of sacrificial through-via structures according to an embodiment of the present disclosure.

FIGS. 23A-23E are various views of the first exemplary structure after formation of lateral isolation trenches according to an embodiment of the present disclosure.

FIGS. 24A-24E are various views of the first exemplary structure after formation of laterally-extending cavities according to an embodiment of the present disclosure.

FIGS. 25A-25E are various views of the first exemplary structure after formation of electrically conductive layers according to an embodiment of the present disclosure.

FIGS. 26A-26E are various views of the first exemplary structure after formation of lateral isolation trench fill structures according to an embodiment of the present disclosure.

FIGS. 27A-27E are various views of the first exemplary structure after removal of the sacrificial through-via structures according to an embodiment of the present disclosure.

FIGS. 28A-28E are various views of the first exemplary structure after formation of through-via contact structures according to an embodiment of the present disclosure.

FIGS. 29A-29E are various views of the first exemplary structure after formation of drain contact via structures according to an embodiment of the present disclosure.

FIG. 30 is a schematic vertical cross-sectional view of the first exemplary structure after formation of a memory die, bonding of the memory die to a logic die, removal of the carrier substrate, and formation of source-side structures according to an embodiment of the present disclosure.

FIG. 31A is a first vertical cross-sectional view of a second exemplary structure after formation of through-via contact structures and drain contact via structures according to an embodiment of the present disclosure. FIG. 31B is a second vertical cross-sectional view of the second exemplary structure after formation of through-via contact structures and drain contact via structures according to an embodiment of the present disclosure.

FIG. 32A is a second vertical cross-sectional view of a third exemplary structure after formation of through-via contact structures and drain contact via structures according to an embodiment of the present disclosure. FIG. 32B is a second vertical cross-sectional view of the third exemplary structure after formation of through-via contact structures and drain contact via structures according to an embodiment of the present disclosure.

### DETAILED DESCRIPTION

As discussed above, embodiments of the present disclosure are directed to a three-dimensional memory device including through-via contact structures and dummy word lines which function as anti-tilt support plates located in contact region and methods for forming the same, the various aspects of which are now described in detail.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements. The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or from each other, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the first continuous structure. For example, a layer may be located between any pair of horizontal planes between, or at, a top surface and a bottom surface of the first continuous structure. A layer may extend horizontally, vertically, and/or along a tapered surface. A substrate may be a layer, may include one or more layers therein, or may have one or more layer thereupon, thereabove, and/or therebelow.

As used herein, a “first-tier level” refers to the level that is most proximal to a growth substrate, a “second-tier level” refers to the level that is most proximal to the growth substrate of the levels that overlie the first-tier level, and a “third-tier level” refers to the level that is most proximal to the growth substrate of the levels that overlie the second-tier level, etc. A “first-tier” element refers to an element that is located within the first-tier level, a “second-tier” element refers to an element that is located within the second-tier level, a “third-tier” element refers to an element that is located within the second-tier level, etc. As used herein, a “memory level” or a “memory array level” refers to the level corresponding to a general region between a first horizontal plane (i.e., a plane parallel to the top surface of the growth substrate) including topmost surfaces of an array of memory elements and a second horizontal plane including bottommost surfaces of the array of memory elements. As used herein, a “through-stack” element refers to an element that vertically extends through a memory level.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

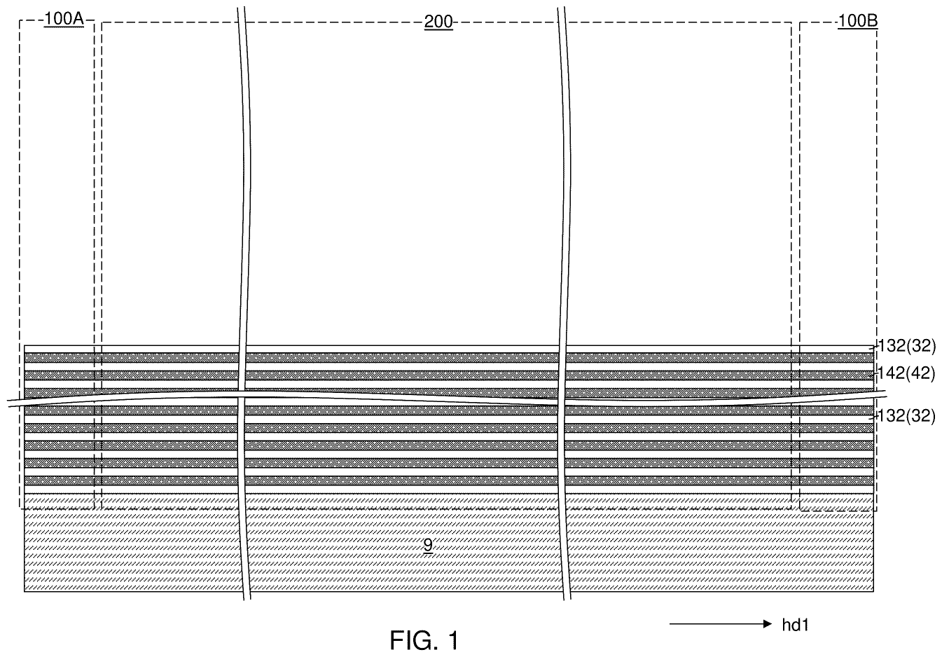

Referring to FIG. 1, a first exemplary structure according to an embodiment of the present disclosure is illustrated, which can be employed to form a two-dimensional array of memory dies formed on a substrate 9. The substrate 9 may be a commercially available wafer such as a silicon wafer. Alternatively, the substrate 9 may comprise another suitable material.

A first vertically alternating sequence of first-tier insulating layers 132 and first-tier active sacrificial material layers 142 can be formed over a substrate 9. As used herein, a vertically alternating sequence refers to a sequence of multiple instances of a first element and multiple instances of a second element that is arranged such that an instance of a second element is located between each vertically neighboring pair of instances of the first element, and an instance of a first element is located between each vertically neighboring pair of instances of the second element. The first vertically alternating sequence of first-tier insulating layers 132 and first-tier active sacrificial material layers 142 is also referred to as a first-tier alternating stack (132, 142). Generally, the first-tier insulating layers 132 are a first subset of insulating layers 32 to be formed in the first exemplary structure, and the first-tier active sacrificial material layers 142 are a first subset of sacrificial material layers 42 to be formed in the first exemplary structure. As such, the first-tier alternating stack (132, 142) may be one of alternating stacks (32, 42) that are formed in the first exemplary structure. The first-tier active sacrificial material layers 142 are sacrificial material layers 42 that are formed at active levels of a first-tier structure to be subsequently formed. As used herein, “active levels” refer to levels at which electrically conductive layers (e.g., word lines) which replace the sacrificial material layers 42 are electrically connected to through-via contact structures. In contrast, “dummy levels” refer to levels at which electrically conductive layers (e.g., word lines) are not electrically connected to through-via contact structures.

The first-tier insulating layers 132 can be composed of the first material, and the first-tier active sacrificial material layers 142 can be composed of the second material, which is different from the first material. Each of the first-tier insulating layers 132 is an insulating layer that continuously extends over the entire area of the substrate 9, and may have a uniform thickness throughout. Each of the first-tier active sacrificial material layers 142 includes a sacrificial material (which may comprise a dielectric material), and continuously extends over the entire area of the substrate 9, and may have a uniform thickness throughout. Insulating materials that may be used for the first-tier insulating layers 132 include, but are not limited to silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the first-tier insulating layers 132 may be silicon oxide.

The second material of the first-tier active sacrificial material layers 142 is a dielectric material, which is a sacrificial material that may be removed selectively to the first material of the first-tier insulating layers 132. As used herein, removal of a first material is “selective to” a second material if the removal process removes the first material at a removal rate that is at least twice the removal rate for the second material. The ratio of the rate of removal of the first material to the rate of removal of the second material is herein referred to as a “selectivity” of the removal process for the first material with respect to the second material.

The thickness of each first-tier insulating layer 132 may be in a range from 12 nm to 50 nm, such as from 15 nm to 30 nm, although lesser and greater thicknesses may also be employed. The thickness of each first-tier active sacrificial material layer 142 may be in a range from 15 nm to 50 nm, such as from 20 nm to 30 nm, although lesser and greater thicknesses may also be employed. The second material of the first-tier active sacrificial material layers 142 may be subsequently replaced with electrically conductive electrodes which may function, for example, as control gate electrodes of a vertical NAND device. In one embodiment, the first-tier active sacrificial material layers 142 may comprise silicon nitride.

Generally, a vertically alternating sequence of unit layer stacks over a substrate. Each of the unit layer stacks comprises a first-tier insulating layer (such as a first-tier insulating layer 132) and a first spacer material layer (such as a first-tier active sacrificial material layer 142). Generally, the first spacer material layers are formed as, or are subsequently replaced with, first-tier electrically conductive layers. While the present disclosure is described employing an embodiment in which the first spacer material layers are formed as first-tier active sacrificial material layers 142 that are subsequently replaced with first-tier electrically conductive layers, embodiments are expressly contemplated herein in which the first spacer material layers are formed as first-tier electrically conductive layers. In such embodiments, steps for replacing the material of the first spacer material layers with an electrically conductive material can be omitted. The first exemplary structure comprises a pair of memory array regions (100A, 100B) and a contact region 200 located between the pair of memory array regions (100A, 100B). The pair of memory regions (100A, 100B) may comprise a first memory array region 100A and a second memory array region 100B.

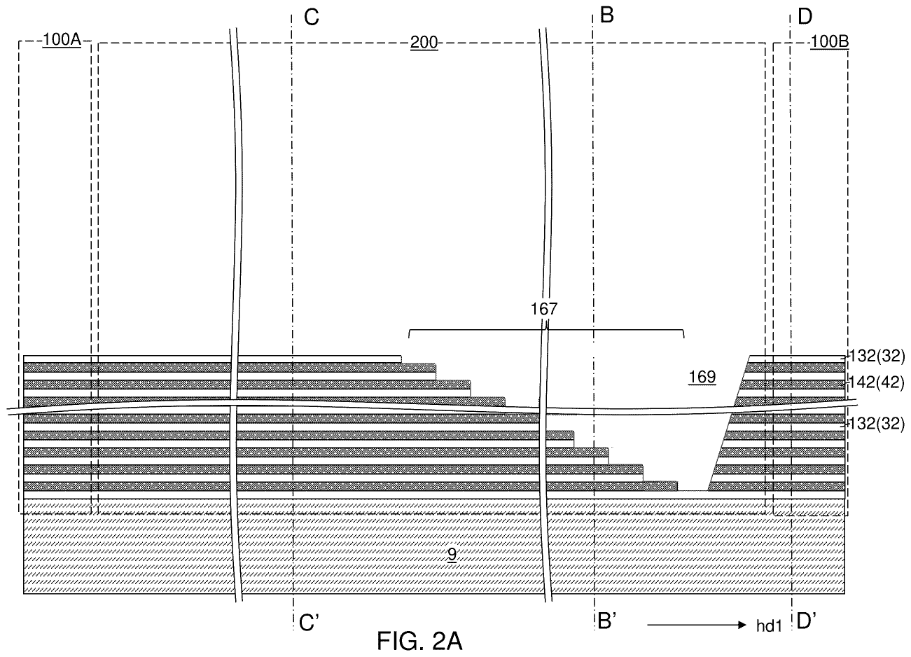

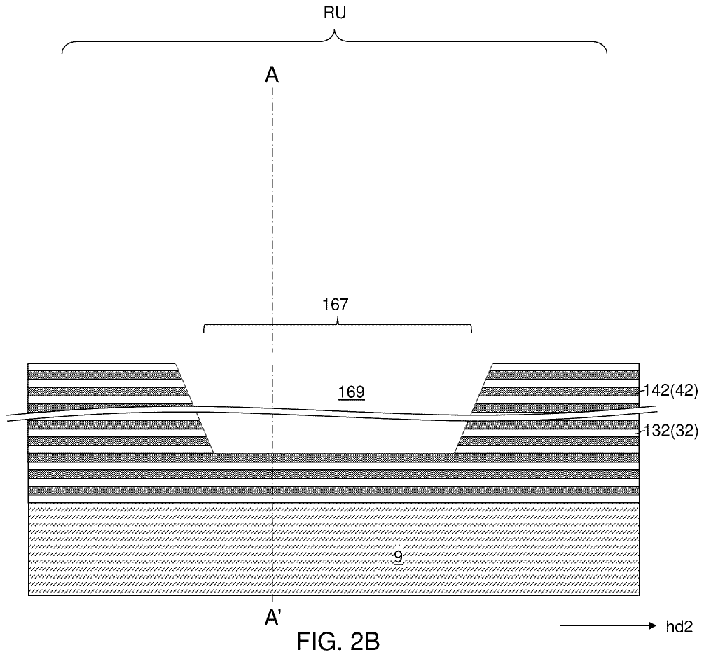

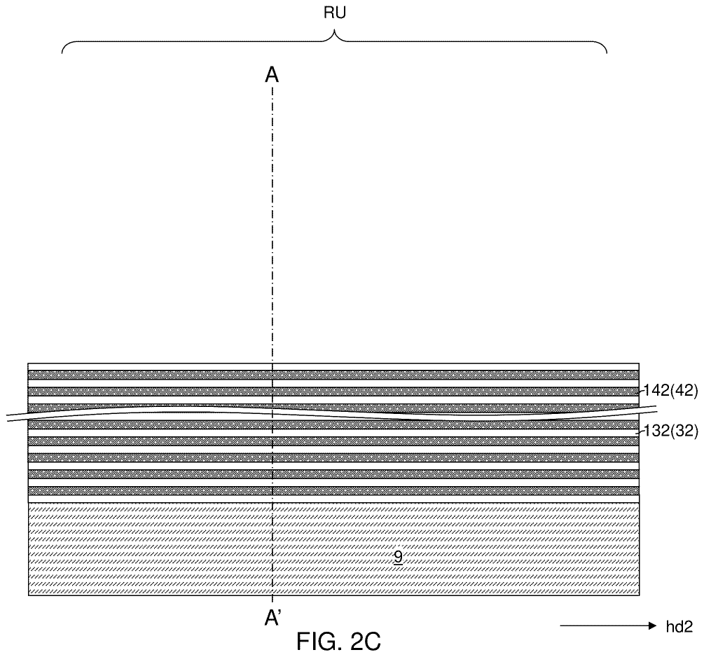

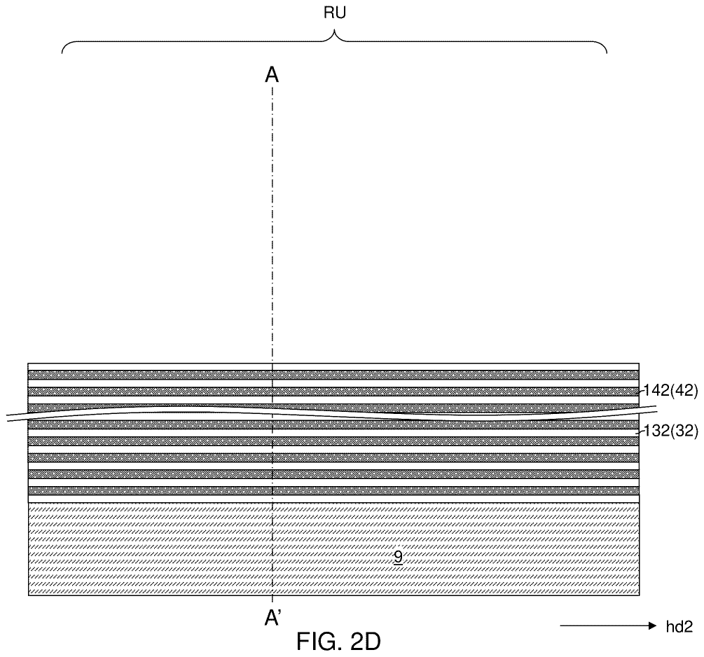

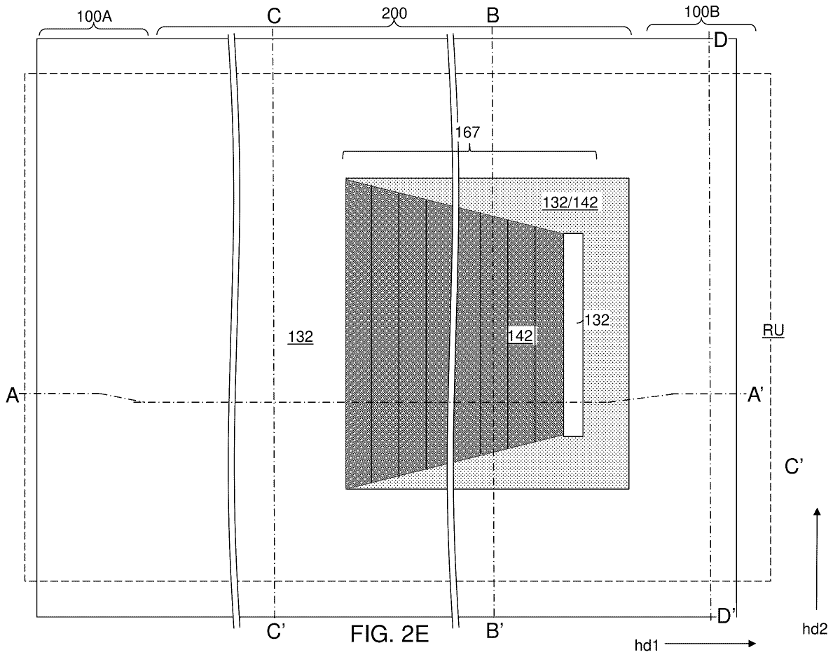

Referring to FIGS. 2A-2E, first-tier stepped cavities 169 can be formed through the first-tier alternating stack (132, 142). The first-tier stepped cavities 169 can be formed in a periodic pattern within the area of the contact region 200. For example, the first memory array region 100A and the second memory array region 100B may be laterally spaced apart from each other along a first horizontal direction (e.g., word line direction) hd1. The contact region 200 may be located between the first memory array region 100A and the second memory array region 100B. The first-tier stepped cavities 169 may be laterally spaced apart along a second horizontal direction (e.g., bit line direction) hd2 that is perpendicular to the first horizontal direction hd1. In one embodiment, the first-tier stepped cavities 169 may be formed as a periodic one-dimensional array of first-tier stepped cavities 169 arranged along the second horizontal direction hd2. In this case, the pattern of the first-tier stepped cavities 169 may be a periodic repetition of a unit pattern located within a repetition unit RU. In the illustrated example, each repetition unit RU laterally extends along the first horizontal direction hd1 through the entirety of the first memory array region 100A (of which only an edge portion is illustrated), the entirety of the second memory array region 100B (of which only an edge portion is illustrated), and the contact region 200. The width of the repetition unit RU may be the same as the periodicity of the periodic one-dimensional array of first-tier stepped cavities 169. Generally, each repetition unit RU may be defined as a rectangular area having a lengthwise edge that is parallel to the first horizontal direction hd1 at any location. In the illustrated example, each repetition unit RU is defined to have lengthwise edges that coincide with two mirror symmetry vertical planes for a neighboring pair of first-tier stepped cavities 169 along the first horizontal direction hd1. In this case, each of the two mirror symmetry vertical planes extends through a respective one of the first-tier stepped cavities 169.

Generally, first-tier stepped surfaces can be formed within the first-tier stepped cavities 169 of the contact region 200 by patterning the first vertically alternating sequence (132, 142). The first-tier stepped surfaces that form the bottom of the first-tier stepped cavities 169 are referred to as a first-tier staircase region 167 which is located in the contact region 200 between the memory array regions (100A, 100B). For example, a combination of a sacrificial hard mask layer and a trimming mask layer may be employed to form the first stepped surfaces. Each first-tier stepped cavity 169 comprises a respective contiguous set of stepped surfaces of the first vertically alternating sequence (132, 142). The stepped surfaces comprise horizontal surface segments separated by vertical surface segments. The lateral extents of the first-tier active sacrificial material layers 142 vary with a vertical distance from the substrate 9 in each first-tier stepped cavity 169. Each of the first-tier active sacrificial material layers 142 has a respective physically exposed horizontal top surface segment within each first-tier stepped cavity 169.

The lateral extent of the physically exposed top surface segments of the first-tier active sacrificial material layers 142 along the first horizontal direction hd1 may be evenly divided among all of the first-tier active sacrificial material layers 142. For example, if the total number of the first-tier active sacrificial material layers 142 is N1, the horizontal length of the physically exposed portion of the physically exposed top surface segment of each first-tier active sacrificial material layer 142 may be 1/N1 times a total stepped surface length. The total stepped surface length may be less than 1/T times the lateral spacing between the first memory array region 100A and the second memory array region 100B. The integer T is the total number of tier structures to be subsequently formed. In the illustrated example, the integer T is 2. The sidewalls of each first-tier staircase region 167 may be tapered. The area in which the physically exposed horizontal surface segments of the first-tier stepped surfaces of a first-tier stepped cavity 169 is located within a plan view is herein referred to as a first-tier stepped surface area.

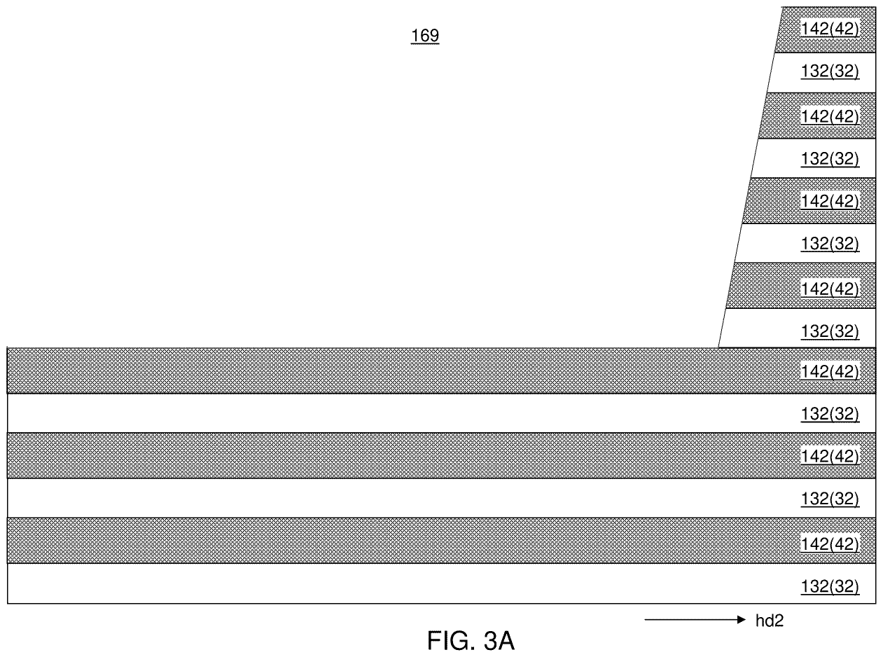

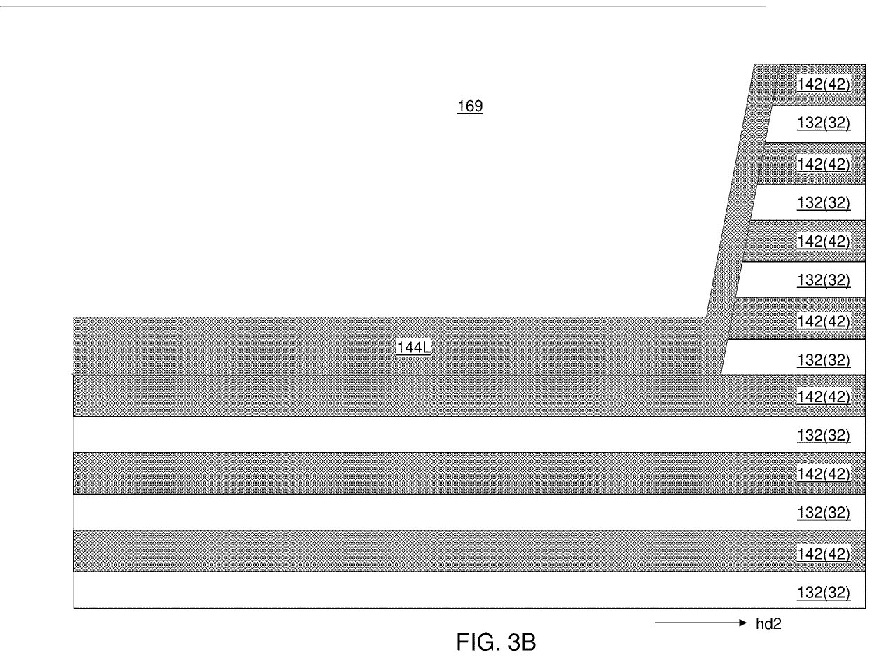

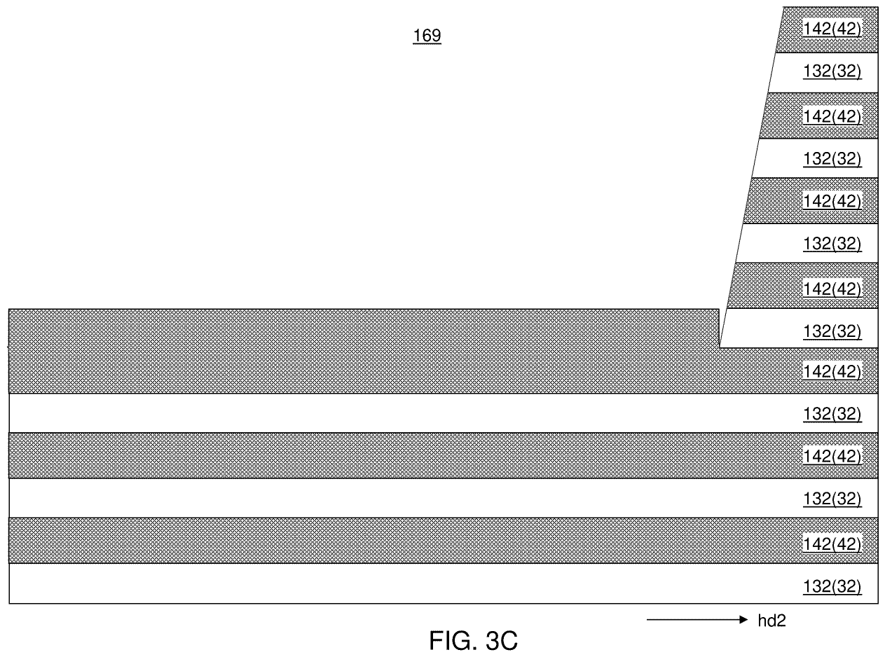

FIGS. 3A-3C are sequential vertical cross-sectional views of a region of the first exemplary structure during thickening of physically-exposed portions of the first-tier active sacrificial material layers according to an embodiment of the present disclosure.

Referring to FIG. 3A, an anisotropic material deposition process can be performed to anisotropically deposit a same material as the material of the first-tier active sacrificial material layers 142 to form a non-conformal sacrificial material layer 144L. In one embodiment, the first-tier active sacrificial material layers 142 comprise silicon nitride, and the anisotropic material deposition process may deposit a silicon nitride material anisotropically. The non-conformal sacrificial material layer 144L is deposited by a non-conformal deposition process such as a plasma-enhanced chemical vapor deposition (PECVD) process. Preferably, the deposition of the sacrificial material of the non-conformal sacrificial material layer 144L is highly anisotropic such that the thickness of each horizontally-extending portion of the non-conformal sacrificial material layer 144L is greater than (e.g., at least twice) the thickness of non-horizontally-extending portions of the non-conformal sacrificial material layer 144L. In one embodiment the thickness of the horizontally-extending portions of the non-conformal sacrificial material layer 144L may be in a range from 50 % to 300 % of the thickness of each first-tier active sacrificial material layer 142.

Referring to FIG. 3B, an isotropic etch process can be performed to isotropically recess the non-conformal sacrificial material layer 144L. The duration of the isotropic etch process can be selected such that the non-horizontally-extending portions of the non-conformal sacrificial material layer 144L are removed by the isotropic etch process. Remaining horizontally-extending portions of the non-conformal sacrificial material layer 144L overlying a top surface segment of a respective one of the first-tier active sacrificial material layers 142 can be incorporated into the respective one of the first-tier active sacrificial material layers 142.

Thus, physically-exposed portions of the sacrificial material layers 42 (such as the first-tier active sacrificial material layers 142) in the staircase region 167 can be thickened such that the thickened portions of the sacrificial material layers 142 has a thickness in a range from 125 % to 250 %, such as from 150 % to 200 %, of the unthickened portion of the first-tier active sacrificial material layers 142 (which is the same as the original thickness of each first-tier active sacrificial material layers 142). While an embodiment is described in which physically exposed portions of the first-tier active sacrificial material layers 142 are locally thickened by anisotropic deposition and isotropic etch-back of a sacrificial material, the physically exposed portions of the first-tier active sacrificial material layers 142 may be locally thickened by alternative methods that can selectively increase the thickness of physically exposed portions of the first-tier active sacrificial material layers 142.

Referring to FIG. 3C, portions of the non-conformal sacrificial material layer 144L that are deposited outside the areas of the first-tier stepped cavities 169 can be removed, for example, by covering the areas of the first-tier stepped cavities 169 with patterned photoresist materials without covering sidewalls of the first-tier stepped cavities 169, and by performing an etch process that etches unmasked portions of the material of the non-conformal sacrificial material layer 144L. Physically exposed portions of the first-tier active sacrificial material layers 142 may be locally thickened within the first-tier stepped cavities 169.

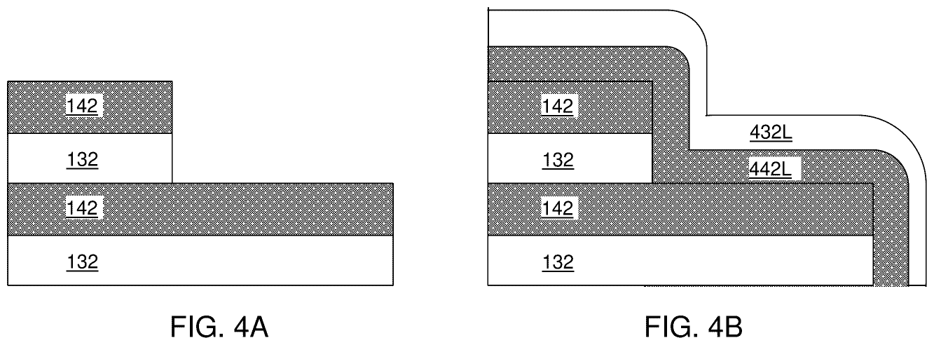

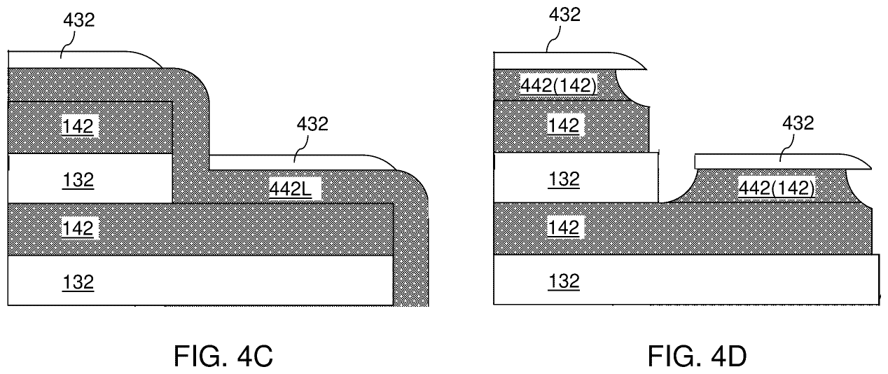

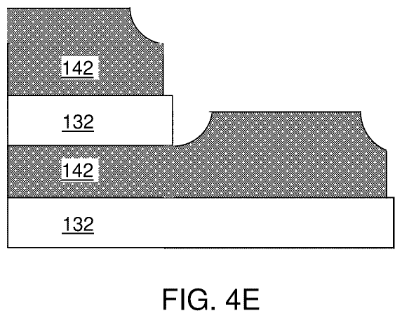

Local thickening of the physically exposed portions of the first-tier active sacrificial material layers 142 may be performed employing alternative methods. FIGS. 4A-4E are sequential vertical cross-sectional views of a region of the first exemplary structure during a sequence of processing steps that may be employed to locally thicken the physically-exposed portions of the first-tier active sacrificial material layers according to an embodiment of the present disclosure.

Referring to FIG. 4A, a region of the first-tier stepped surfaces in a first-tier stepped cavity 169 after the processing steps of FIGS. 2A-2E is illustrated.

Referring to FIG. 4B, an additive sacrificial material layer 442L can be conformally deposited by a conformal deposition process such as a low pressure chemical vapor deposition process. The thickness of the additive sacrificial material layer 442L may be in a range from 40 % to 300 %, such as from 60 % to 150 %, of the thickness of each first-tier active sacrificial material layer 142. The additive sacrificial material layer 442L may comprise the same material as the first-tier active sacrificial material layers 142. For example, if the first-tier active sacrificial material layers 142 comprise silicon nitride, the additive sacrificial material layer 442L may comprise silicon nitride.

Subsequently, a non-conformal cover material layer 432L may be anisotropically deposited. The anisotropic deposition of the non-conformal cover material layer 432L may be effected, for example, by plasma enhanced chemical vapor deposition. The non-conformal cover material layer 432L comprises a material that can function as an etch mask material for subsequently etching unmasked portions of the additive sacrificial material layer 442L. For example, the non-conformal cover material layer 432L may comprise silicon oxide. The vertical thickness of the horizontally-extending portions of the non-conformal cover material layer 432L is greater than the lateral thickness of the vertically-extending portions of the non-conformal cover material layer 432L. The difference between the vertical thickness of the horizontally-extending portions of the non-conformal cover material layer 432L and the lateral thickness of the vertically-extending portions of the non-conformal cover material layer 432L may be in a range from 1.3 to 3.0, such as from 1.5 to 2.0.

Referring to FIG. 4C, an isotropic etch process can be performed to isotropically etch the material of the non-conformal cover material layer 432L. The duration of the isotropic etch process is selected such that the etch distance of the isotropic etch process for the material of the non-conformal cover material layer 432L is greater than the lateral thickness of vertically-extending portions of the non-conformal cover material layer 432L, and is less than the vertical thickness of the horizontally-extending portions of the non-conformal cover material layer 432L. Thus, remaining portions of the non-conformal cover material layer 432L after the isotropic etch process comprise cover material plates 432 that are remaining portions of the non-conformal cover material layer 432L that overlie horizontally-extending portions of the additive sacrificial material layer 442L. The cover material plates 432 have a vertical thickness that is not greater than the difference between the vertical thickness of the horizontally-extending portions of the non-conformal cover material layer 432L and the lateral thickness of vertically-extending portions of the non-conformal cover material layer 432L, and may be in a range from 10 nm to 50 nm, although lesser and greater thicknesses may also be employed.

Referring to FIG. 4D, a selective isotropic etch process can be performed to isotropically etch unmasked portions of the additive sacrificial material layer 442L without etching the materials of cover material plates 432 or the first-tier insulating layers 132. The duration of the selective isotropic etch process may be selected such that the etch distance of the selective isotropic etch process for the material of the additive sacrificial material layer 442L is not less than the uniform thickness of the additive sacrificial material layer 442L. Thus, vertically-extending portions of the additive sacrificial material layer 442L are removed by the selective isotropic etch process, while remaining horizontally-extending portions of the additive sacrificial material layer 442L underlie a respective one of the cover material plates 432. The remaining horizontally-extending portions of the additive sacrificial material layer 442L comprise sacrificial material plates 442, which are incorporated into a respective one of the first-tier active sacrificial material layers 142.

Referring to FIG. 4E, a selective etch process may be optionally performed to remove the cover material plates 432 without removing the materials of the sacrificial material plates 442 or the first-tier active sacrificial material layers 142. The material of sacrificial material plates 442 may be the same as the material of the first-tier active sacrificial material layers 142. Thus, the first-tier active sacrificial material layers 142 incorporate the sacrificial material plates 442, and are locally thickened in the regions of the first stepped surfaces.

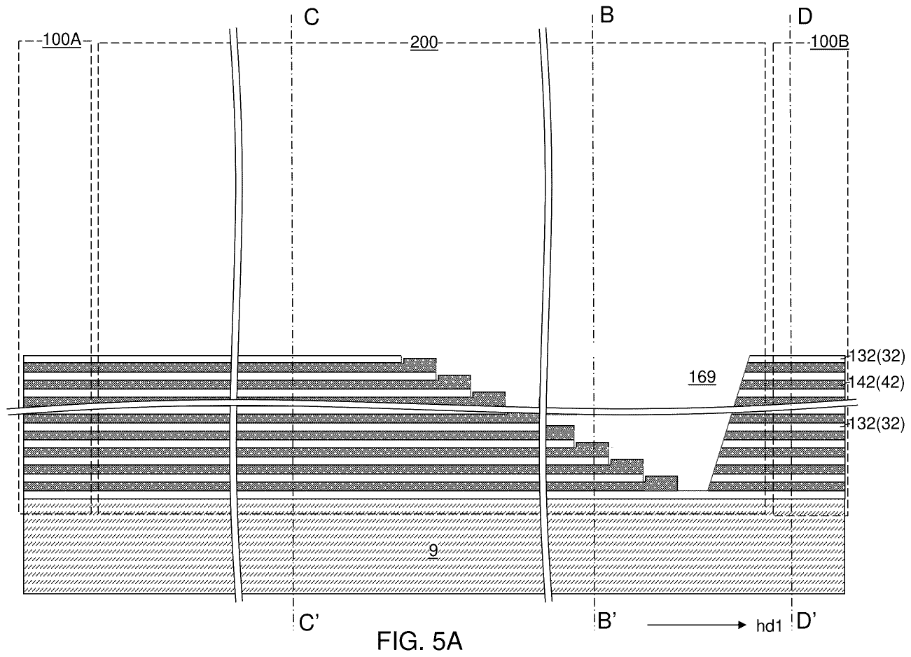

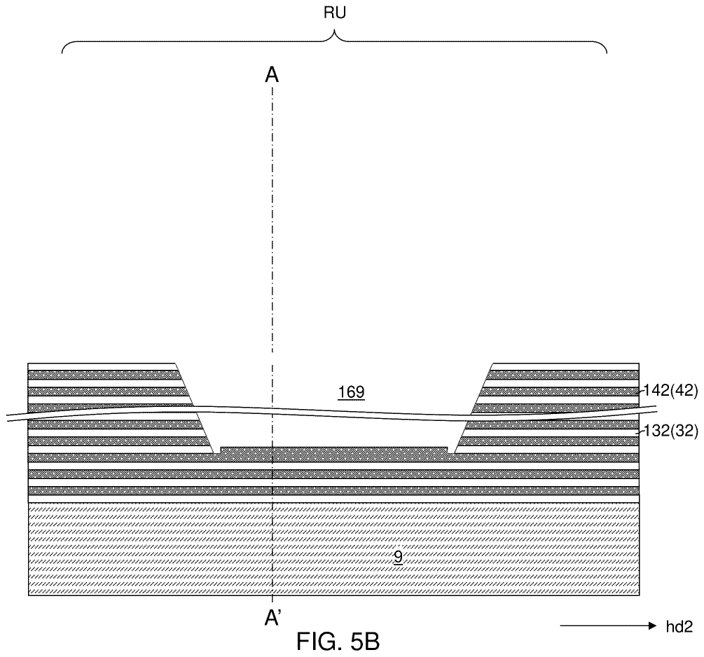

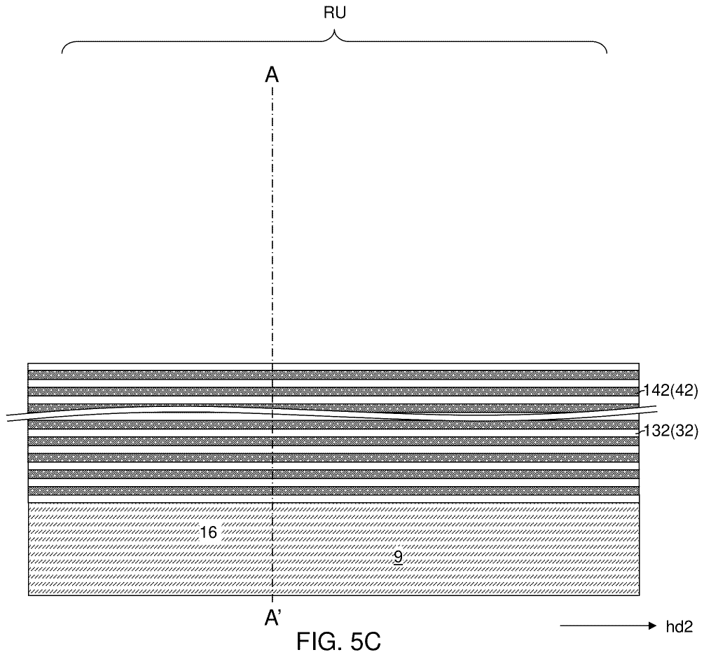

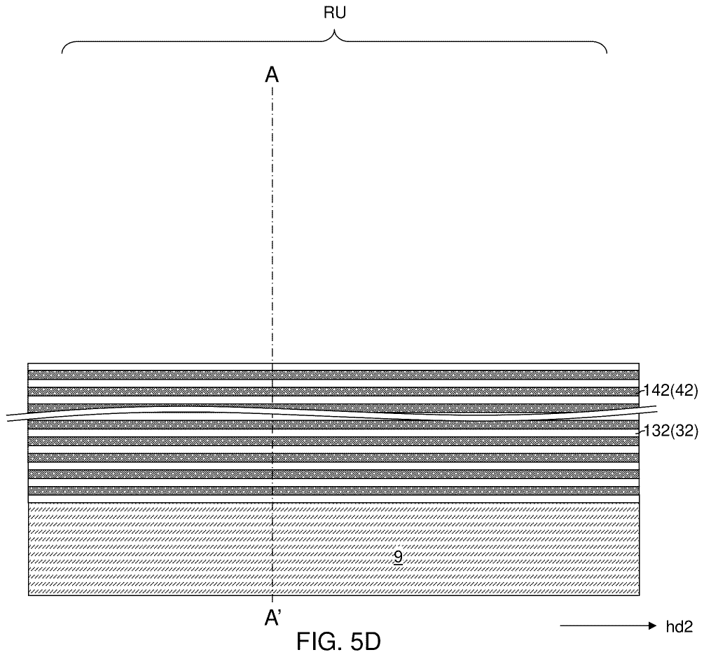

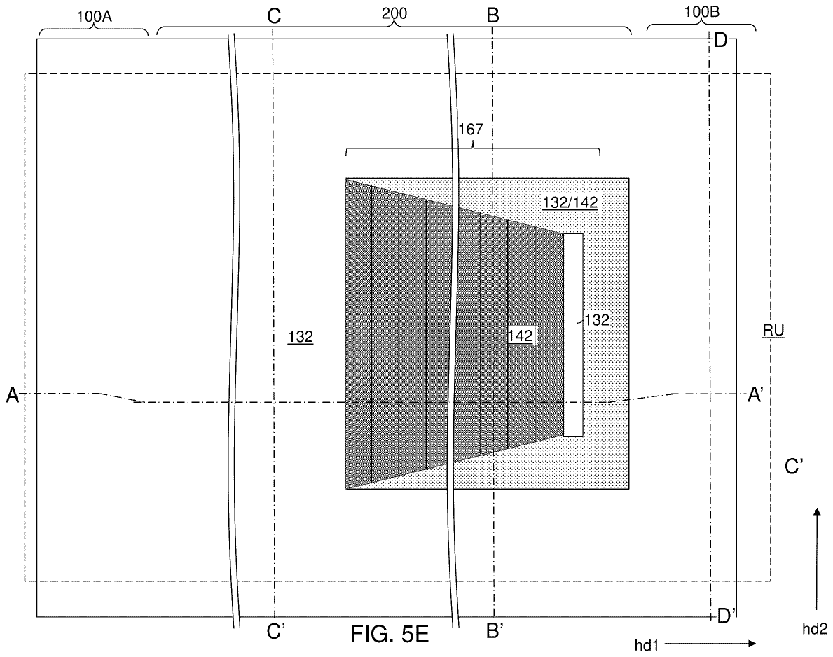

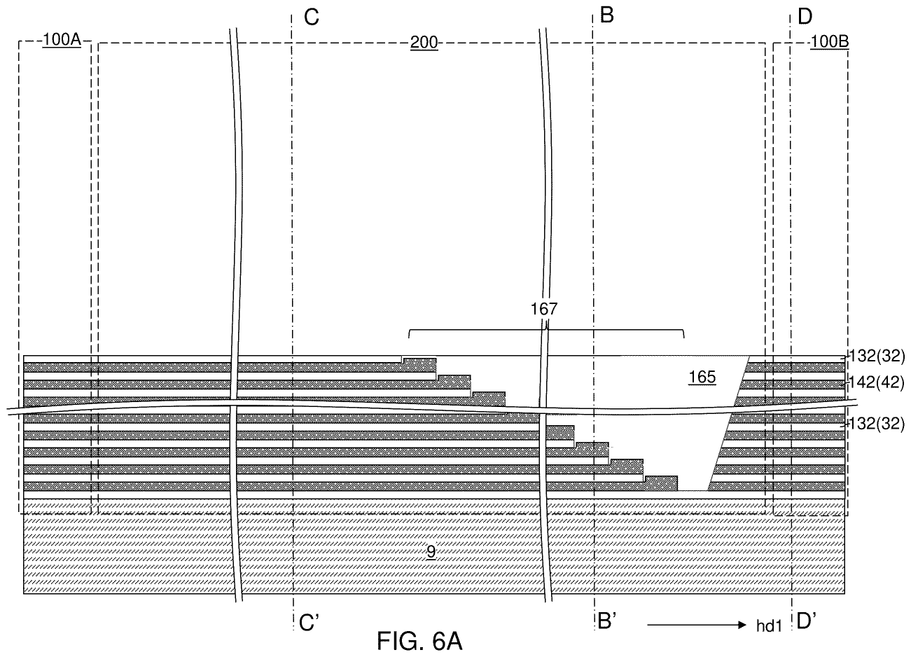

Referring to FIGS. 5A-5E, the first exemplary structure is illustrated after locally thickening the physically exposed portions of the first-tier active sacrificial material layers 142.

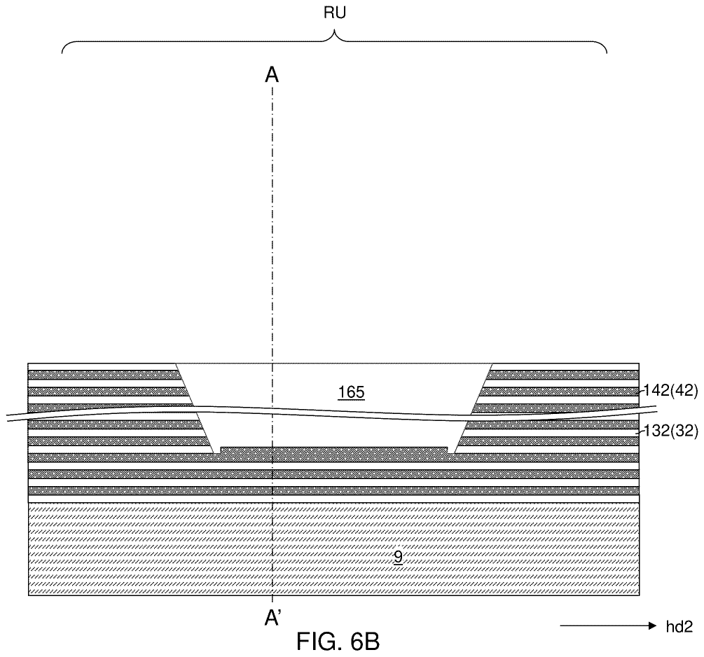

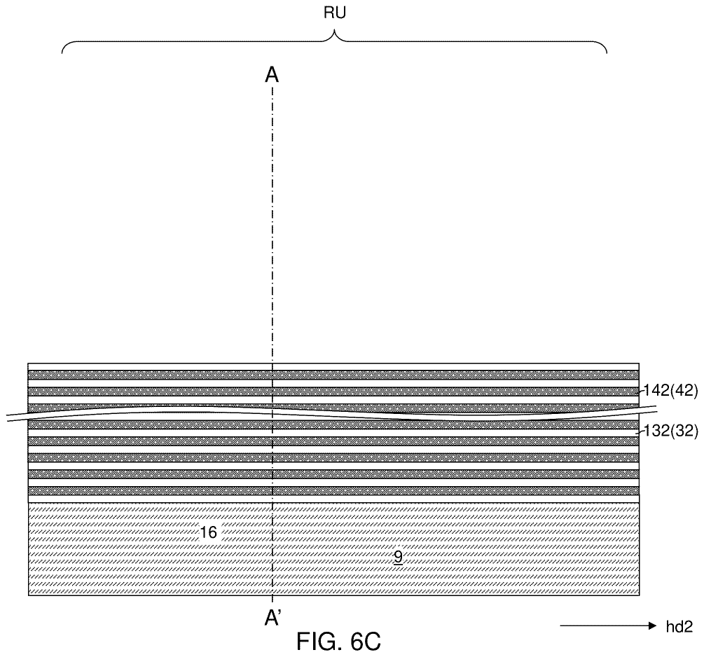

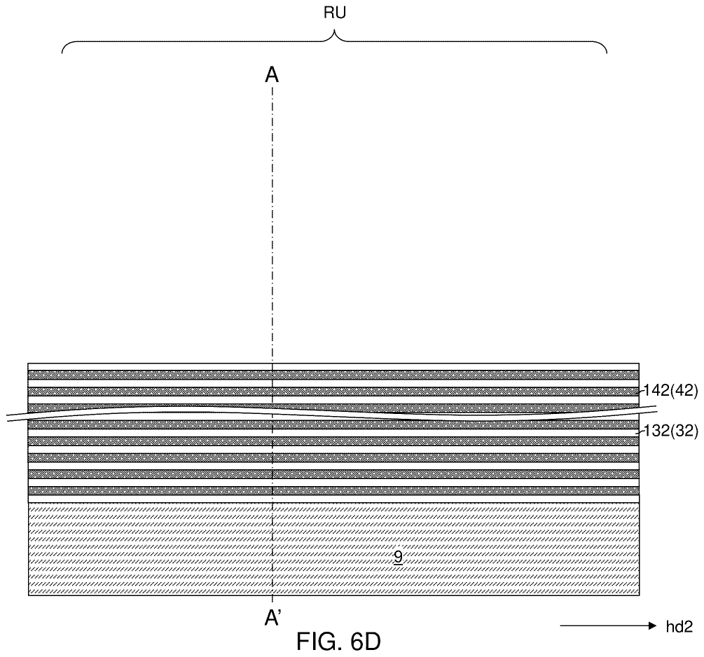

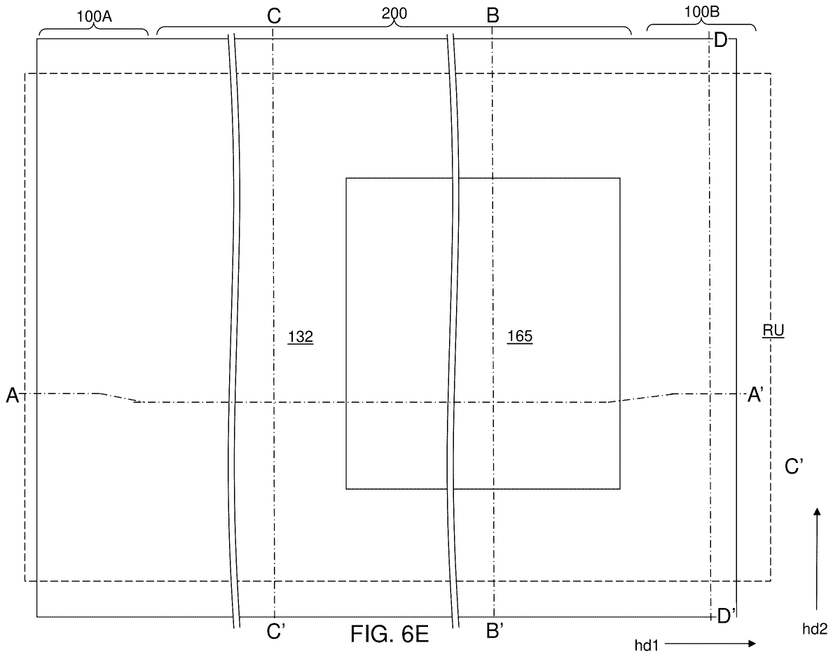

Referring to FIGS. 6A-6E, a first dielectric fill material (such as undoped silicate glass (i.e., silicon oxide) or a doped silicate glass) can be deposited in each first-tier stepped cavity 169. The first dielectric fill material can be planarized to remove excess portions of the first dielectric fill material from above the horizontal plane including the topmost surface of the first vertically alternating sequence (132, 142). Each remaining portion of the first dielectric fill material that fills a respective first-tier stepped cavity 169 constitutes a first-tier retro-stepped dielectric material portion 165. Generally, the first-tier retro-stepped dielectric material portions 165 can be formed in the contact region 200 between the first memory array region 100A and the second memory array region 100B that are laterally spaced apart along the first horizontal direction hd1. The planar top surface of each first-tier retro-stepped dielectric material portion 165 can be located within a horizontal plane including the top surface of a topmost first-tier insulating layer 132.

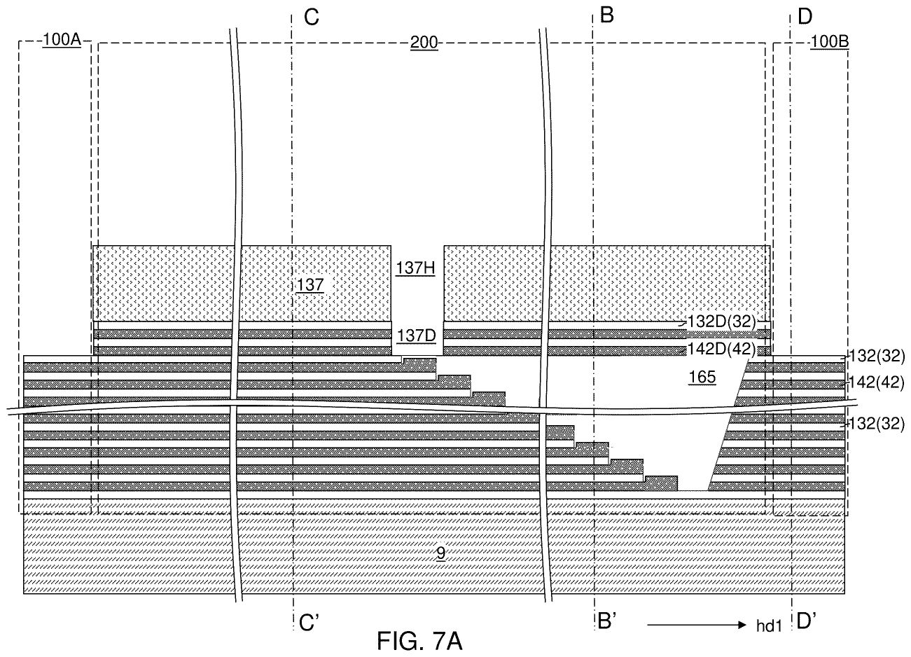

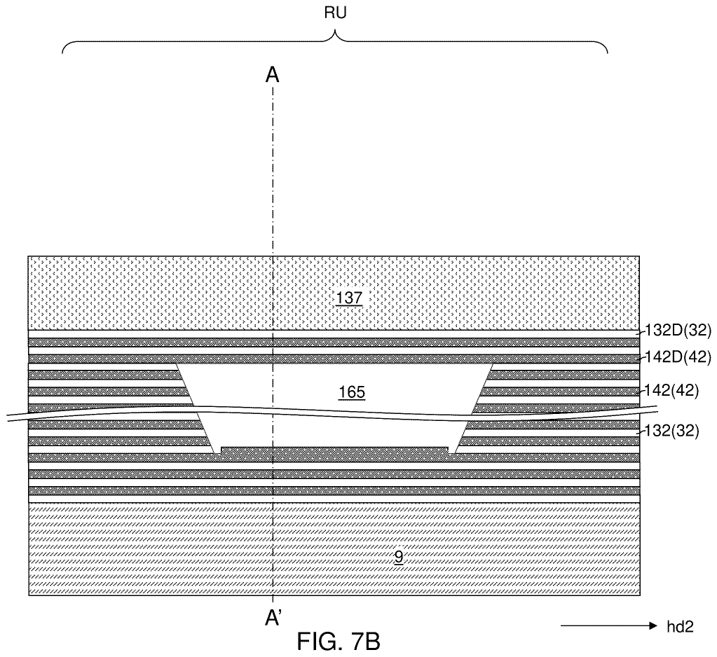

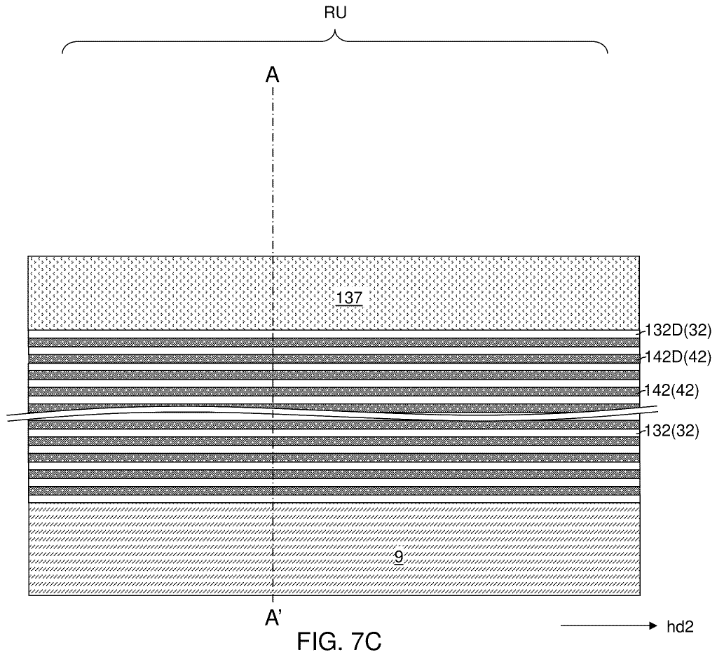

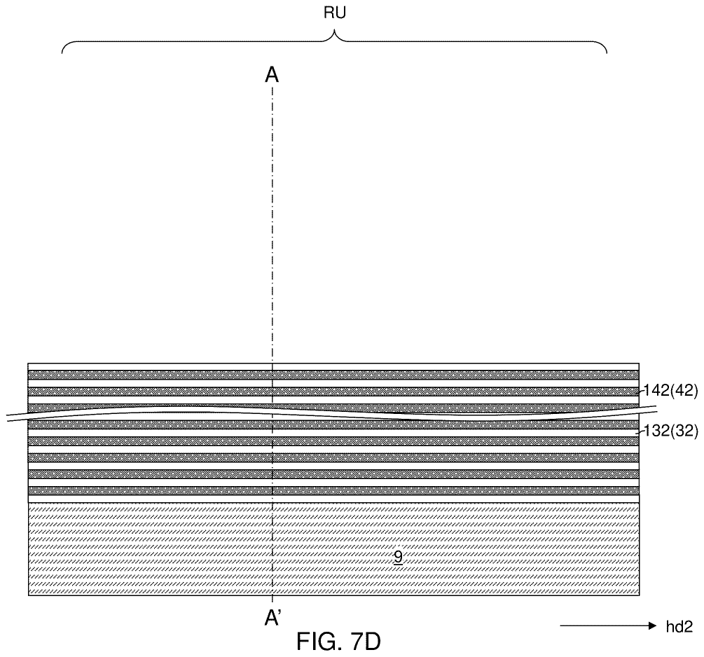

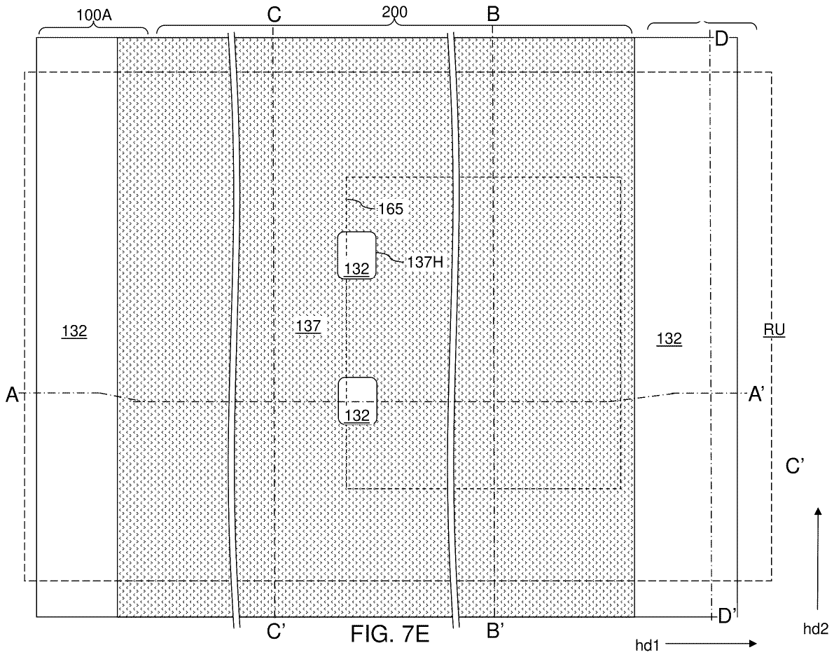

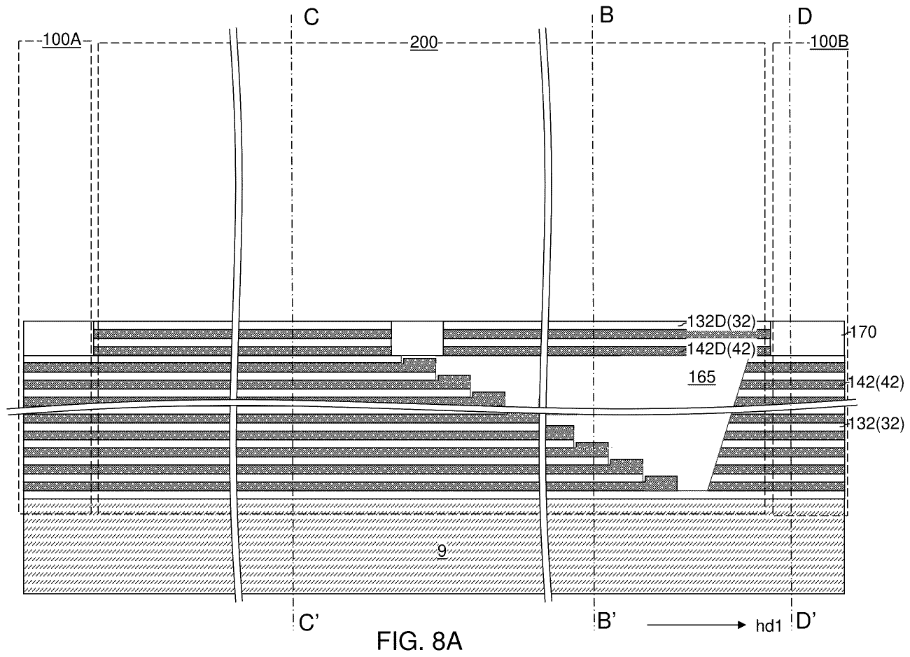

Referring to FIGS. 7A-7E, at least one pair of an insulating layer 32 and a sacrificial material layer 42 can be deposited over the first vertically alternating sequence of first-tier insulating layers 132 and first-tier active sacrificial material layers 142. Each insulating layer 32 within the at least one pair of an insulating layer 32 and a sacrificial material layer 42 is herein referred to as a first-tier dummy insulating layer 132D. Each sacrificial material layer 42 within the at least one pair of an insulating layer 32 and a sacrificial material layer 42 is herein referred to as a first-tier dummy sacrificial material layer 142D. Each first-tier dummy insulating layer 132D and each first-tier dummy sacrificial material layer 142D are dummy level layers. The first-tier dummy sacrificial material layer 142D are subsequently replaced by first-tier dummy electrically conductive layers which do not electrically contact any through-via contact structure. Each first-tier dummy insulating layer 132D may have the same material composition and optionally the same thickness as a first-tier insulating layer 132. Each first-tier dummy sacrificial material layer 142D may have the same material composition and optionally the same thickness as a first-tier active sacrificial material layer 142. The total number of pair(s) of a first-tier dummy insulating layer 132D and a first-tier dummy sacrificial material layer 142D may be in a range from 1 to 6, such as from 1 to 4. In the illustrated example, the total number of pairs of a first-tier dummy insulating layer 132D and a first-tier dummy sacrificial material layer 142D is 2.

A first photoresist layer 137 may be applied over the at least one pair of a first-tier dummy insulating layer 132D and a first-tier dummy sacrificial material layer 142D, and can be lithographically patterned to cover a predominant fraction (i.e., more than 50%) of the contact region 200 without covering any of the memory array regions (100A, 100B). In one embodiment, the areas overlying or located adjacent to locally thickened portions of the topmost first-tier active sacrificial material layer 142 are not covered by the first photoresist layer 137. In this case, holes 137H may be formed through the first photoresist layer 137 over the areas overlying or located adjacent to locally thickened portions of the topmost first-tier active sacrificial material layer 142. In another embodiment, the holes 137H are omitted.

An anisotropic etch process may be performed to remove portions of the at least one pair of a first-tier dummy insulating layer 132D and a first-tier dummy sacrificial material layer 142D that are not covered by the first photoresist layer 137. The at least one pair of a first-tier dummy insulating layer 132D and a first-tier dummy sacrificial material layer 142D may be completely removed from the memory array regions (100A, 100B). At least a predominant fraction (such as greater than 50%, for example 95 to 100%) of the contact area 200 may be coved by the remaining patterned portion of the at least one pair of a first-tier dummy insulating layer 132D and a first-tier dummy sacrificial material layer 142D. An optional hole 137D in the at least one pair of a first-tier dummy insulating layer 132D and a first-tier dummy sacrificial material layer 142D may underlie the respective hole 137H in the first photoresist layer 137, and may overlie each area overlying or located adjacent to the locally thickened portions of the topmost first-tier active sacrificial material layer 142. The holes 137D in the at least one pair of a first-tier dummy insulating layer 132D and a first-tier dummy sacrificial material layer 142D prevent electrical shorting between the locally thickened portions of the topmost first-tier active sacrificial material layer 142 and a bottommost one of the first-tier dummy sacrificial material layer 142D. The first photoresist layer 137 may be subsequently removed, for example, by ashing.

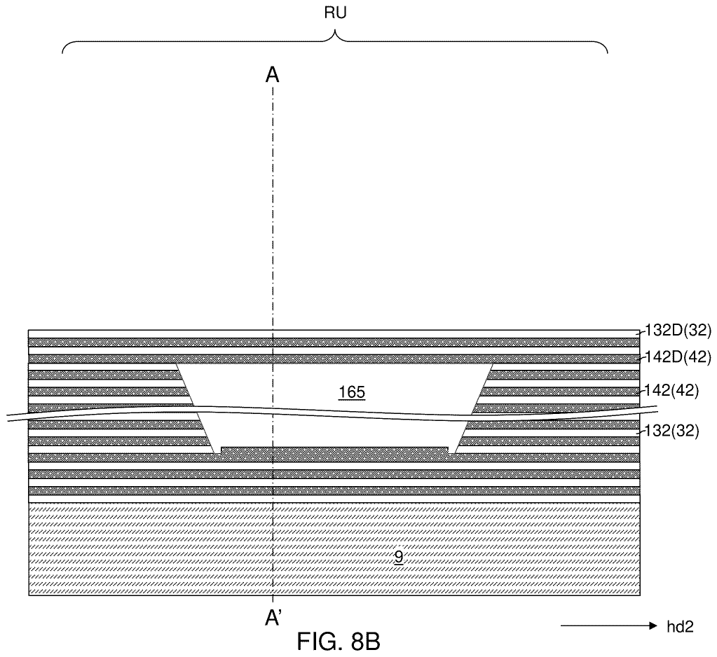

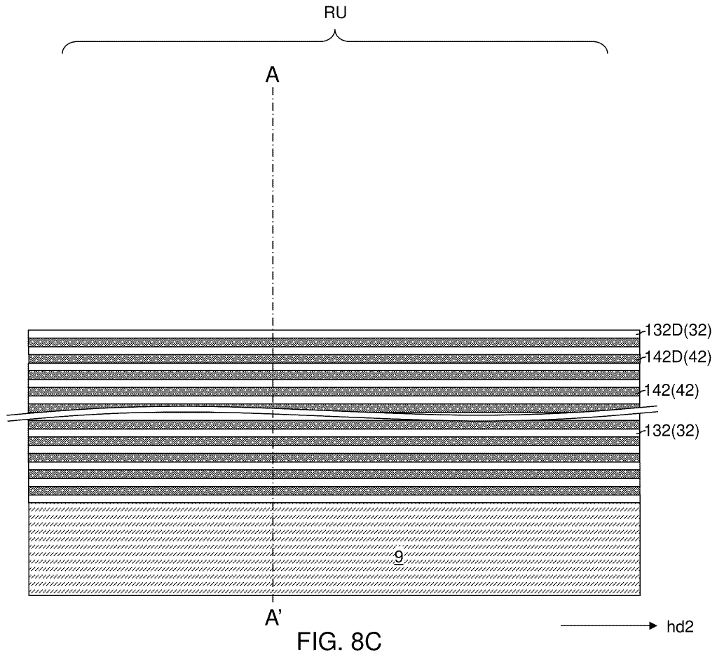

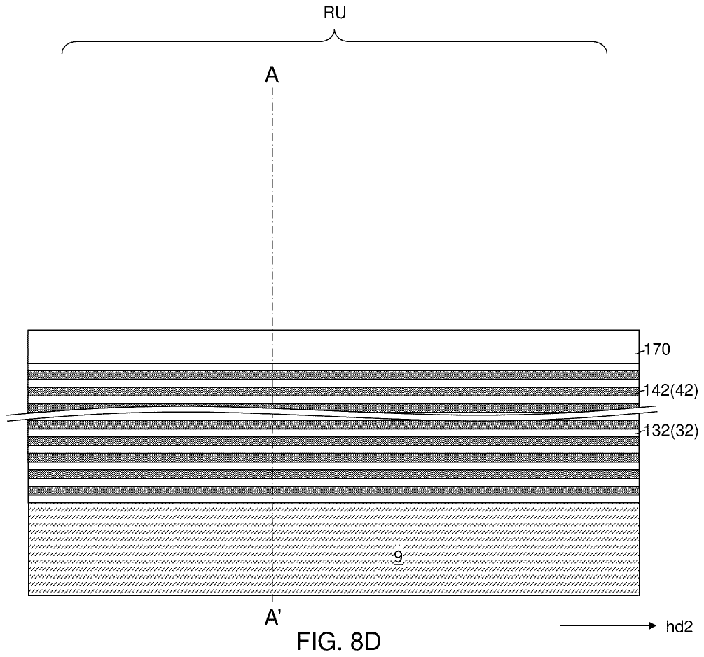

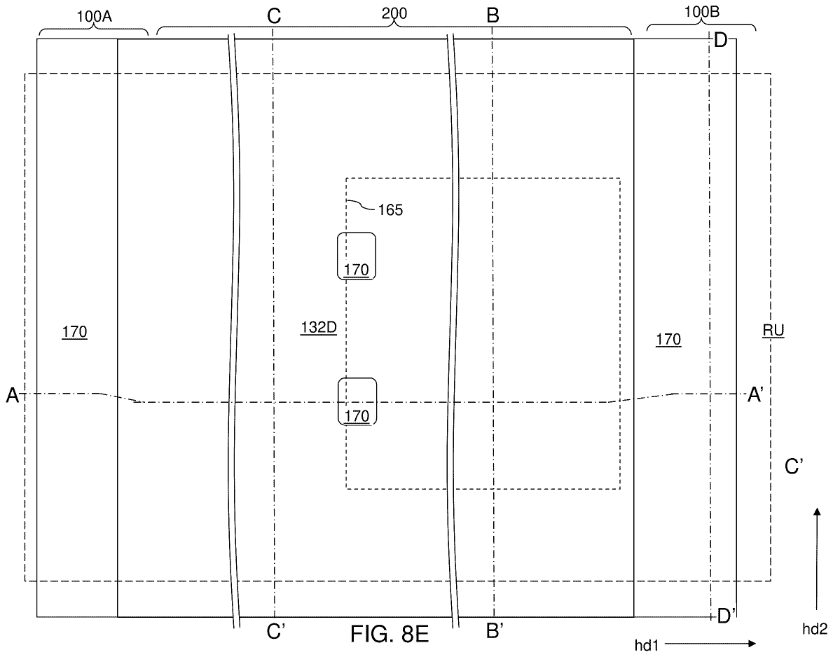

Referring to FIGS. 8A-8E, an insulating material can be deposited over the at least one pair of a first-tier dummy insulating layer 132D and a first-tier dummy sacrificial material layer 142D and over the first vertically alternating sequence of first-tier insulating layers 132 and first-tier active sacrificial material layers 142. A planarization process, such as a chemical mechanical polishing process, may be performed to remove portions of the insulating material from above a horizontal plane including a topmost surface of the at least one pair of a first-tier dummy insulating layer 132D and a first-tier dummy sacrificial material layer 142D. Remaining portions of the insulating material constitute a first-tier insulating cap layer 170. In one embodiment, the first-tier insulating cap layer 170 may comprise the same insulating material as the first-tier insulating layers 132. In one embodiment, the top surface of the first-tier insulating cap layer 170 may be formed in the horizontal plane including the topmost surface of the at least one pair of a first-tier dummy insulating layer 132D and a first-tier dummy sacrificial material layer 142D. If the holes 137D are present, then they may also be filled with the first-tier insulating cap layer 170.

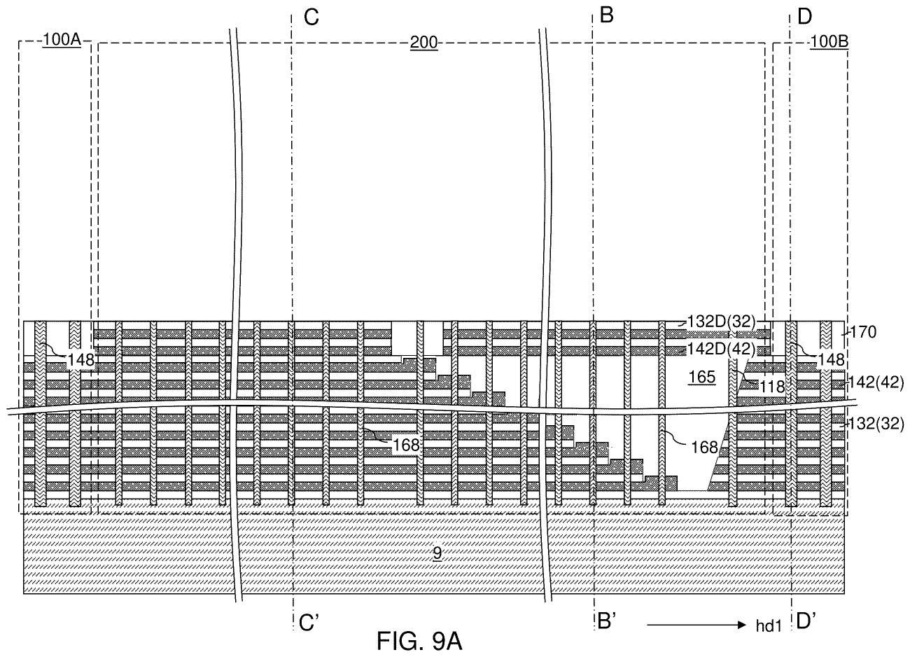

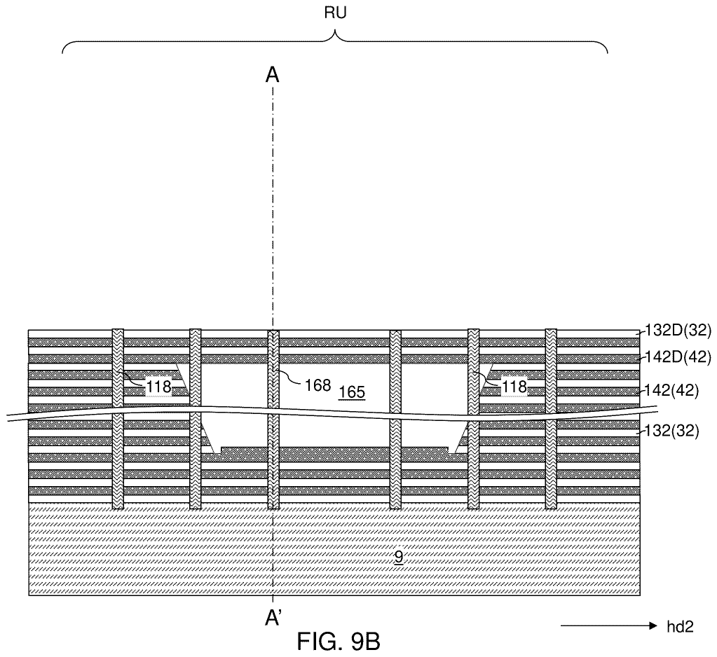

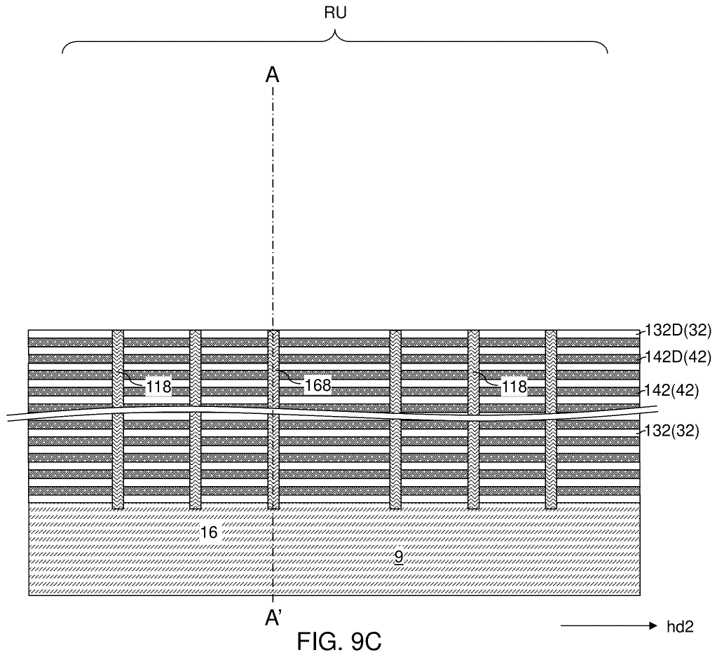

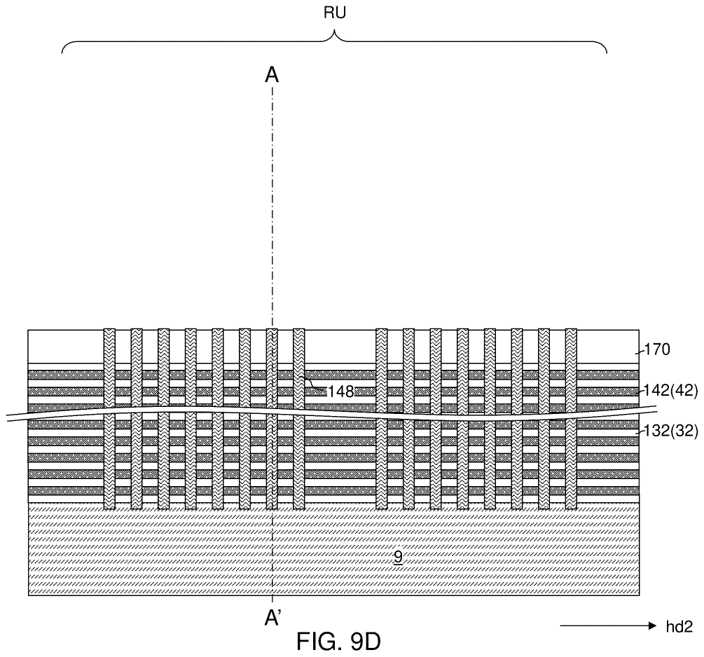

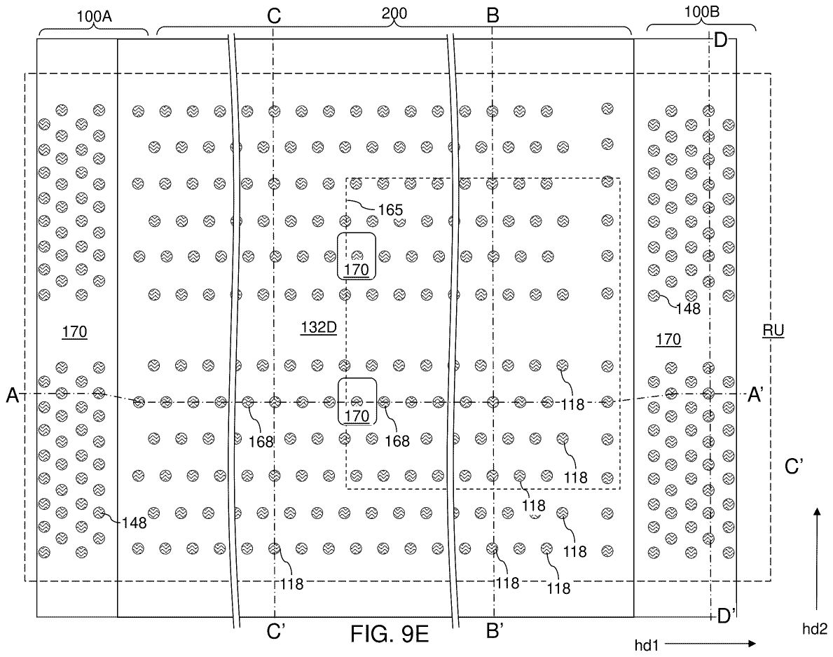

Referring to FIGS. 9A-9E, various first-tier openings may be formed through the first vertically alternating sequence (132, 142) and into the substrate 9. A photoresist layer (not shown) may be applied over the first vertically alternating sequence (132, 142), and may be lithographically patterned to form various openings therethrough. The pattern of openings in the photoresist layer may be transferred through the first vertically alternating sequence (132, 142) and into the substrate 9 by a first anisotropic etch process to form the various first-tier openings concurrently. The various first-tier openings may include first-tier memory openings formed in the memory array regions (100A, 100B) and first-tier support openings formed in the contact regions 200, and first-tier contact openings formed in the staircase regions 167 which are located within the contact regions 200.

Each cluster of first-tier memory openings may be formed as a two-dimensional array of first-tier memory openings. The first-tier support openings are openings that are formed in the contact region 200, and are subsequently employed to form support pillar structures. Each first-tier contact opening is formed in a respective area in which a respective through-via contact structure is to be subsequently formed. A subset of the first-tier support openings may be formed through a respective horizontally-extending surface segment of the first stepped surfaces. A subset of the first-tier contact openings is formed through a respective horizontally-extending surface segment of the first stepped surfaces.

Sacrificial first-tier opening fill structures (148, 118, 168) may be formed in the various first-tier openings. For example, a sacrificial first-tier fill material is concurrently deposited in each of the first-tier openings. The sacrificial first-tier fill material includes a material that may be subsequently removed selectively to the materials of the first-tier insulating layers 132 and the first-tier active sacrificial material layers 142. In one embodiment, the sacrificial first-tier fill material may include a semiconductor material such as silicon (e.g., amorphous silicon or polysilicon), silicon-germanium, germanium, a III-V compound semiconductor material, or a combination thereof. Optionally, a thin etch stop liner (such as a silicon oxide layer or a silicon nitride layer having a thickness in a range from 1 nm to 3 nm) may be used prior to depositing the sacrificial first-tier fill material. The sacrificial first-tier fill material may be formed by a non-conformal deposition or a conformal deposition method.

In another embodiment, the sacrificial first-tier fill material may include a silicon oxide material having a higher etch rate than the material of the first-tier insulating layers 132. For example, the sacrificial first-tier fill material may include borosilicate glass or porous or non-porous organosilicate glass having an etch rate that is at least 100 times higher than the etch rate of densified TEOS oxide (i.e., a silicon oxide material formed by decomposition of tetraethylorthosilicate glass in a chemical vapor deposition process and subsequently densified in an anneal process) in a 100:1 dilute hydrofluoric acid. In this case, a thin etch stop liner (such as a silicon nitride layer having a thickness in a range from 1 nm to 3 nm) may be used prior to depositing the sacrificial first-tier fill material. The sacrificial first-tier fill material may be formed by a non-conformal deposition or a conformal deposition method.

Portions of the deposited sacrificial first-tier fill material may be removed from above the horizontal plane including the top surface of the first-tier insulating cap layer 170. For example, the sacrificial first-tier fill material may be recessed to the horizontal plane including the top surface of the first-tier insulating cap layer 170 using a planarization process. The planarization process may include a recess etch, chemical mechanical planarization (CMP), or a combination thereof. The top surface of the first-tier insulating cap layer 170 may be used as an etch stop layer or a planarization stop layer.

Remaining portions of the sacrificial first-tier fill material comprise sacrificial first-tier opening fill structures (148, 118, 168). Specifically, each remaining portion of the sacrificial first-tier fill material in a first-tier memory opening constitutes a sacrificial first-tier memory opening fill structure 148. Each remaining portion of the sacrificial first-tier fill material in a first-tier support opening constitutes a sacrificial first-tier support opening fill structure 118. Each remaining portion of the sacrificial first-tier fill material in a first-tier contact opening constitutes a sacrificial first-tier contact opening fill structure 168. The various sacrificial first-tier opening fill structures (148, 118, 168) are concurrently formed, i.e., employing a same set of processes including the deposition process that deposits the sacrificial first-tier fill material and the planarization process that removes the first-tier deposition process from above the horizontal plane including the top surface of the first-tier insulating cap layer 170. The top surfaces of the sacrificial first-tier opening fill structures (148, 118, 168) may be coplanar with the top surface of the first-tier insulating cap layer 170. Each of the sacrificial first-tier opening fill structures (148, 118, 168) may optionally include cavities therein. The set of all structures located between the bottommost surface of the first vertically alternating sequence (132, 142) and the topmost surface of the first vertically alternating sequence (132, 142) or embedded within the first vertically alternating sequence (132, 142) constitutes a first-tier structure.

According to an aspect of the present disclosure, each first-tier active sacrificial material layer 142 comprises a respective locally thickened portion underneath each first-tier retro-stepped dielectric material portion 165. A subset of the first-tier contact openings can be formed through a locally thickened portion of a respective first-tier active sacrificial material layer 142. The sacrificial first-tier contact opening fill structures 168 may vertically extend from a horizontal plane including a top surface of the first-tier insulating cap layer 170 at least to a horizontal plane including a bottom surface of the first-tier alternating stack (132, 142).

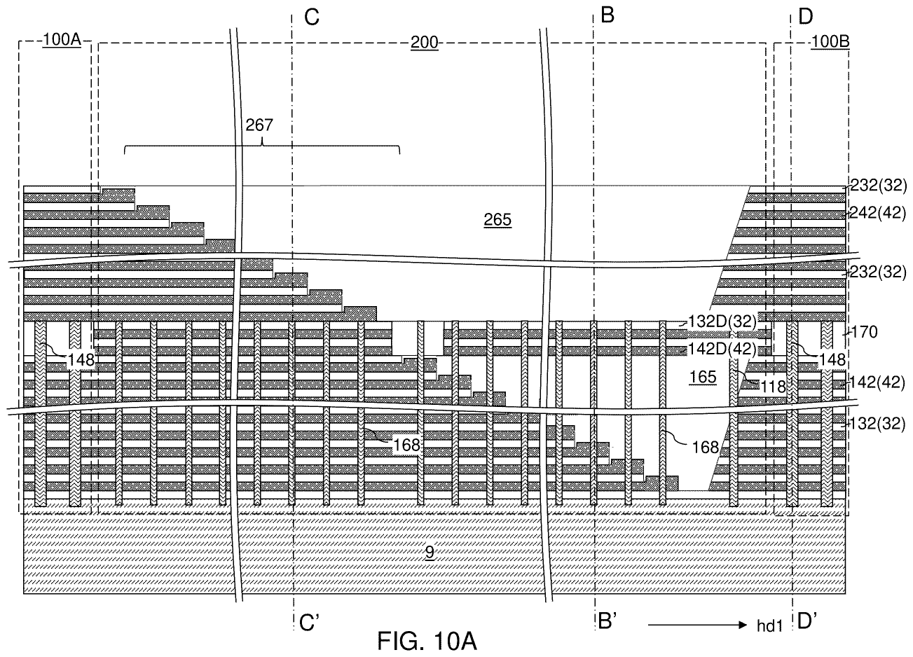

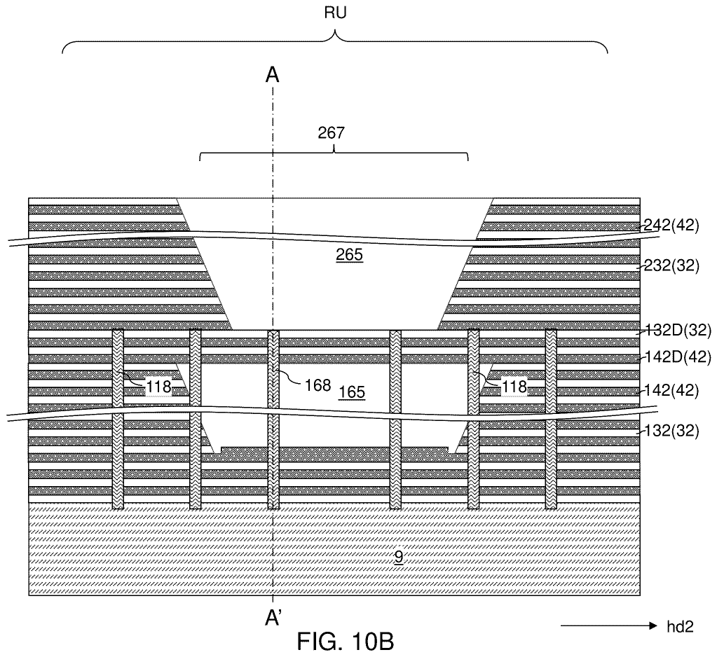

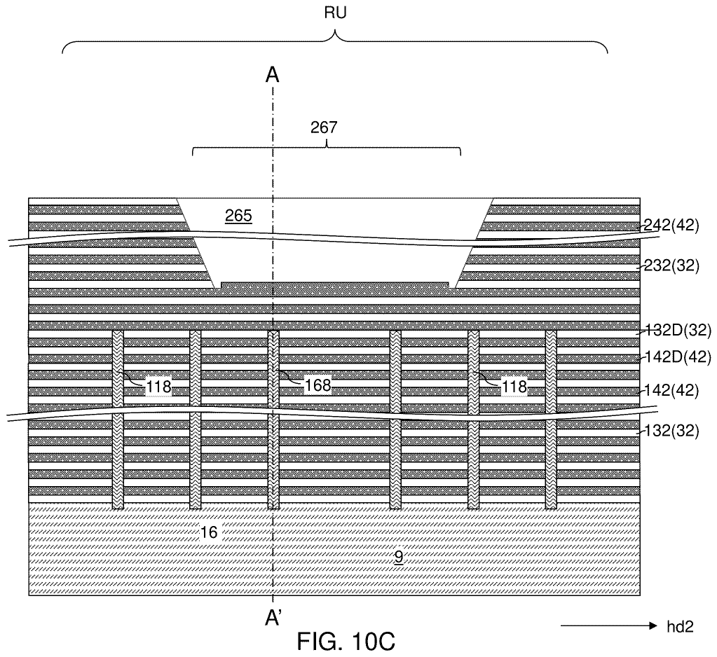

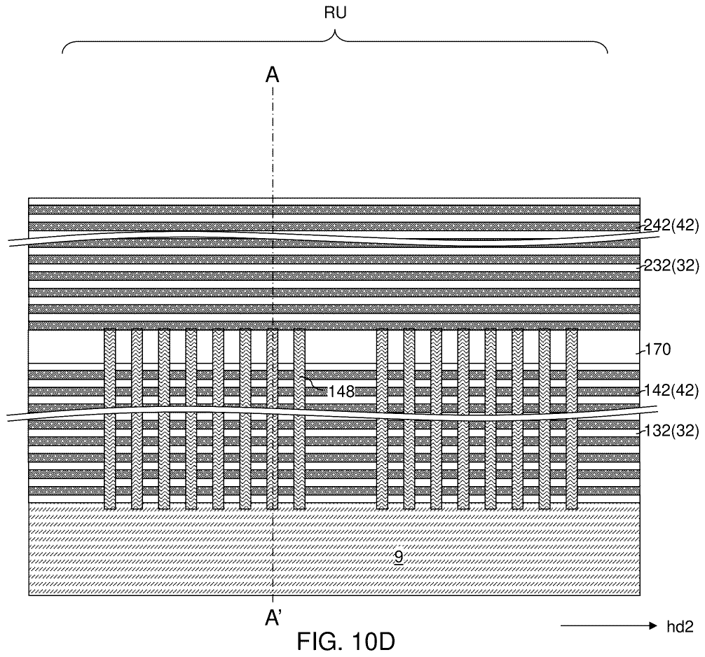

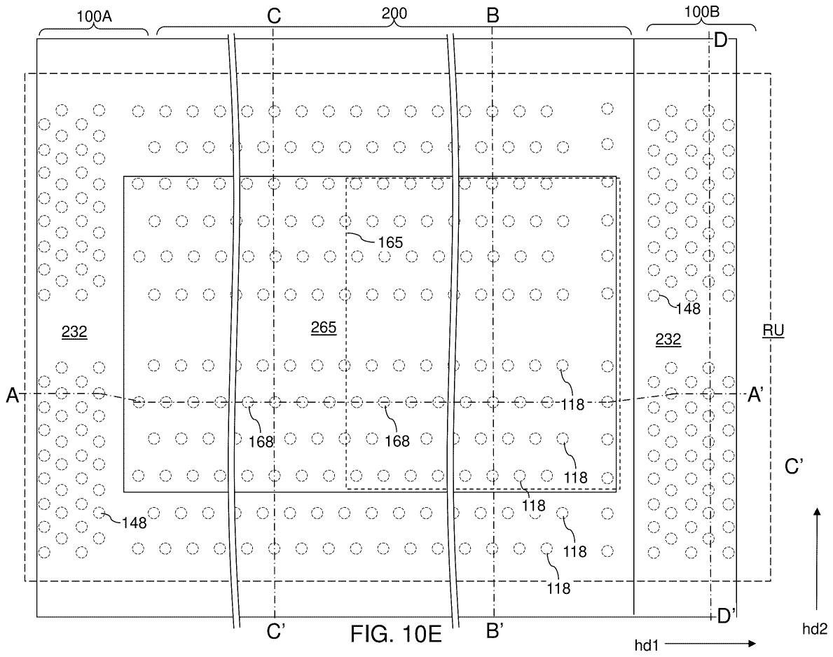

Referring to FIGS. 10A-10E, a second vertically alternating sequence of second-tier insulating layers 232 and second-tier active sacrificial material layers 242 can be formed. Each of the second-tier insulating layers 232 is an insulating layer 32 that continuously extends over the entire area of the substrate 9, and may have a uniform thickness throughout. Each of the second-tier active sacrificial material layers 242 is a sacrificial material layer 42 that includes a dielectric material and continuously extends over the entire area of the substrate 9, and may have a uniform thickness throughout. The second-tier insulating layers 232 can have the same material composition and the same thickness as the first-tier insulating layers 132. The second-tier active sacrificial material layers 242 can have the same material composition and the same thickness as the first-tier active sacrificial material layers 142.

Second stepped surfaces can be formed within each second-tier stepped cavity in the contact region 200 which will be filled with a respective second-tier retro-stepped dielectric material portions 265. For example, a combination of a sacrificial hard mask layer and a trimming mask layer may be employed to form the second stepped surfaces. Generally, the processing steps described with reference to FIGS. 2A-2E can be performed with a change in the masking pattern to form second-tier stepped cavities. Each set of second stepped surfaces may be laterally offset along the first horizontal direction hd1 relative to an adjacent and underlying set of first stepped surfaces of the first vertically alternating sequence (132, 142).

Each second-tier stepped cavity comprises a respective contiguous set of stepped surfaces of the second vertically alternating sequence (232, 242). The lateral extents of the second-tier active sacrificial material layers 242 vary with a vertical distance from the substrate 9 in each second-tier stepped cavity. Each of the second-tier active sacrificial material layers 242 has a respective physically exposed horizontal top surface segment within each second-tier stepped cavity. The lateral extent of the physically exposed top surface segments of the second-tier active sacrificial material layers 242 along the first horizontal direction hd1 may be evenly divided among all of the second-tier active sacrificial material layers 242.

In one embodiment, the lateral extent of each of the second-tier stepped cavities along the first horizontal direction hd1 may be about one half of the lateral distance between the first memory array region 100A and the second memory array region 100B. In this case, the lateral extent of each of the second-tier stepped cavities along the second horizontal direction hd2 may be about twice the lateral extent of the each of the first-tier stepped cavities 169 along the first horizontal direction hd1. For example, if the total number of the second-tier active sacrificial material layers 242 is N2, the horizontal length of the physically exposed portion of the physically exposed top surface segment of each second-tier active sacrificial material layer 242 may be 1/N2 times a total stepped surface length. The total stepped length may be less than 1/T times the lateral spacing between the first memory array region 100A and the second memory array region 100B. The integer T is the total number of tier structures to be subsequently formed. In the illustrated example, the integer T is 2. The sidewalls of each second-tier staircase region 267 may be tapered. The area in which the physically exposed horizontal surface segments of the second-tier stepped surfaces of a second-tier stepped cavity is located within a plan view is herein referred to as a second-tier stepped surface area.

Physically-exposed portions of the second-tier active sacrificial material layers 242 may be locally thickened by performing a sequence of processing steps described with reference to FIGS. 3A-3C or by performing a sequence of processing steps described with reference to FIGS. 4A-4E.

A second dielectric fill material (such as undoped silicate glass (i.e., silicon oxide) or a doped silicate glass) can be deposited in each second-tier stepped cavity. The second dielectric fill material can be planarized to remove excess portions of the second dielectric fill material from above the horizontal plane including the topmost surface of the second vertically alternating sequence (232, 242). Each remaining portion of the second dielectric fill material that fills a respective second-tier stepped cavity constitutes a second-tier retro-stepped dielectric material portion 265. Generally, the second-tier retro-stepped dielectric material portions 265 can be formed in the contact region 200 located between the first memory array region 100A and the second memory array region 100B. The planar top surface of each second-tier retro-stepped dielectric material portion 265 can be located within a horizontal plane including the top surface of the second vertically alternating sequence of second-tier insulating layers 232 and second-tier active sacrificial material layers 242.

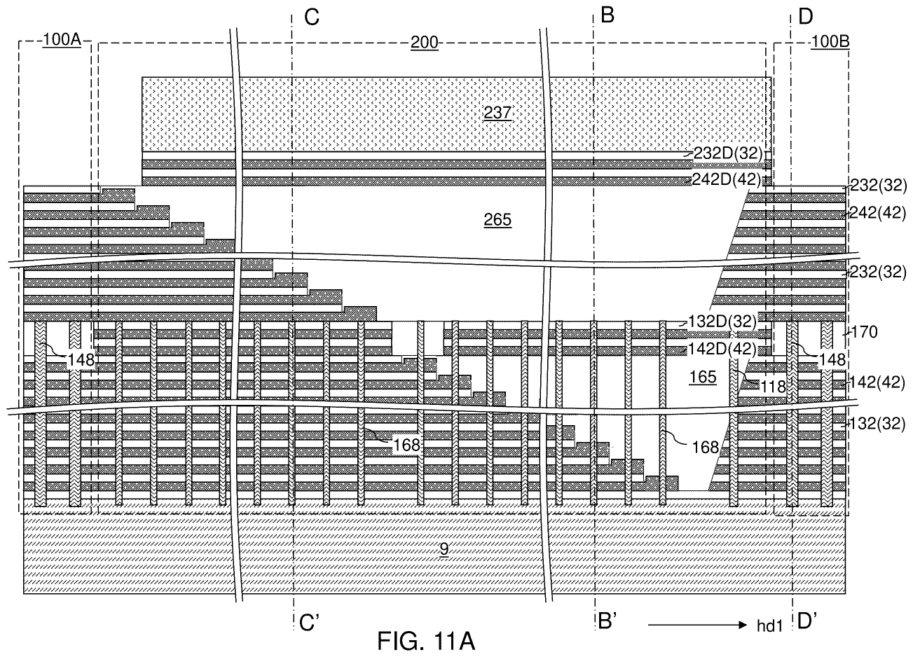

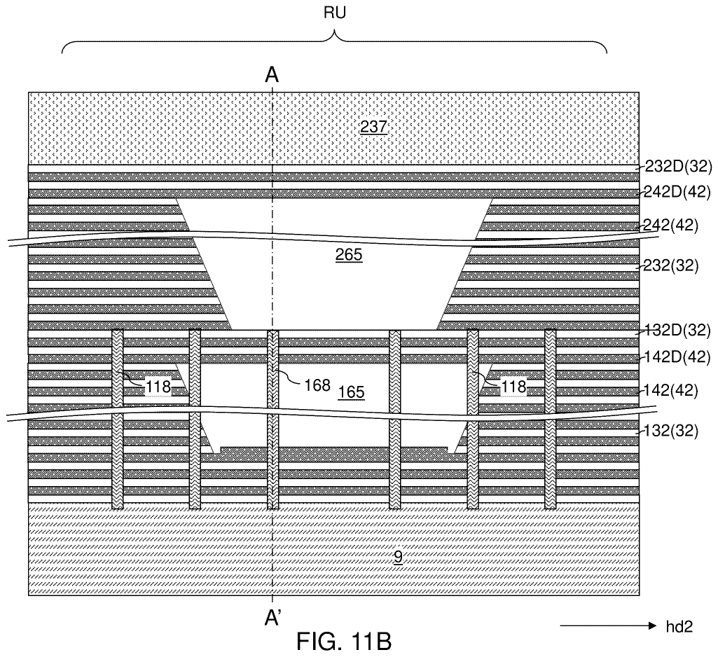

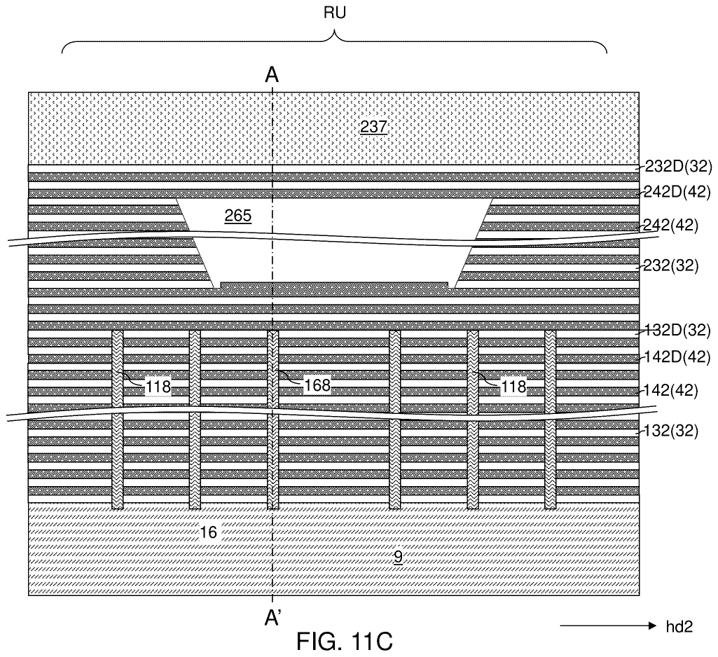

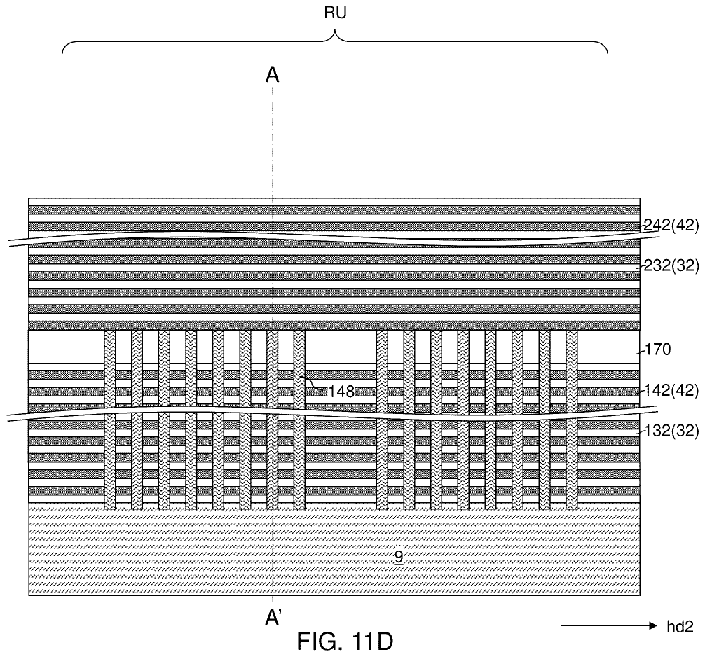

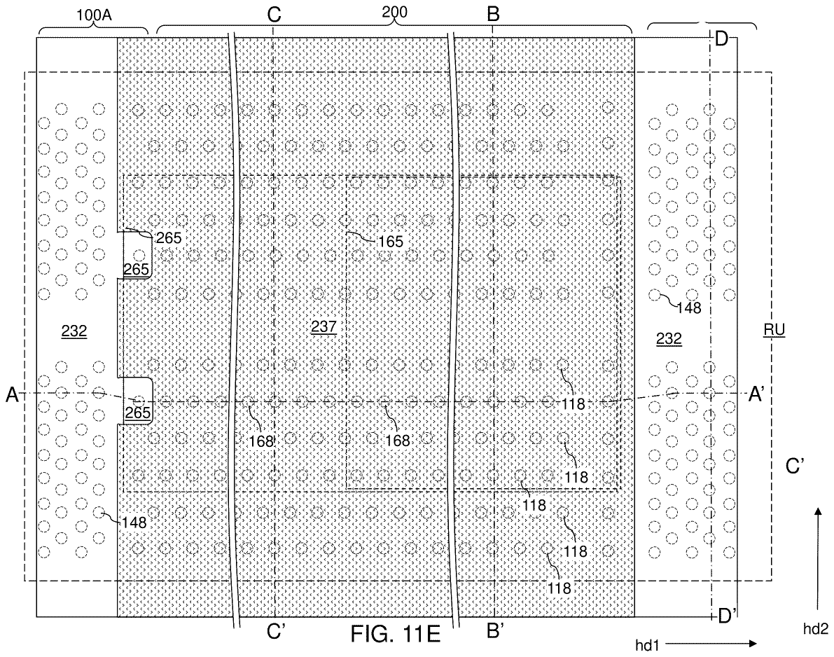

Referring to FIGS. 11A-11E, at least one pair of an insulating layer 32 and a sacrificial material layer 42 can be deposited over the second vertically alternating sequence of second-tier insulating layers 232 and second-tier active sacrificial material layers 242. Each insulating layer 32 within the at least one pair of an insulating layer 32 and a sacrificial material layer 42 is herein referred to as a second-tier dummy insulating layer 232D. Each sacrificial material layer 42 within the at least one pair of an insulating layer 32 and a sacrificial material layer 42 is herein referred to as a second-tier dummy sacrificial material layer 242D. Each second-tier dummy insulating layer 232D and each second-tier dummy sacrificial material layer 242D are dummy level layers. Each second-tier dummy insulating layer 232D may have the same material composition and optionally the same thickness as a second-tier insulating layer 232. Each second-tier dummy sacrificial material layer 242D may have the same material composition and optionally the same thickness as a second-tier active sacrificial material layer 242. The total number of pair(s) of a second-tier dummy insulating layer 232D and a second-tier dummy sacrificial material layer 242D may be in a range from 1 to 6, such as from 1 to 4. In the illustrated example, the total number of pairs of a second-tier dummy insulating layer 232D and a second-tier dummy sacrificial material layer 242D is 2.

A second photoresist layer 237 may be applied over the at least one pair of a second-tier dummy insulating layer 232D and a second-tier dummy sacrificial material layer 242D, and can be lithographically patterned to cover a predominant fraction of the contact region 200 without covering any of the memory array regions (100A, 100B). In one embodiment, the areas overlying or located adjacent to, locally thickened portions of the topmost second-tier active sacrificial material layer 242 may be uncovered by the second photoresist layer 237. In this case, holes may be formed through the second photoresist layer 237 over the areas overlying or located adjacent to locally thickened portions of the topmost second-tier active sacrificial material layer 242.

An anisotropic etch process may be performed to remove portions of the at least one pair of a second-tier dummy insulating layer 232D and a second-tier dummy sacrificial material layer 242D that are not covered by the second photoresist layer 237. The at least one pair of a second-tier dummy insulating layer 232D and a second-tier dummy sacrificial material layer 242D may be completely removed from the memory array regions (100A, 100B). A predominant fraction of the contact area 200 may be coved by the remaining patterned portion of the at least one pair of a second-tier dummy insulating layer 232D and a second-tier dummy sacrificial material layer 242D. An optional hole in the at least one pair of a second-tier dummy insulating layer 232D and a second-tier dummy sacrificial material layer 242D may overlie each area overlying or located adjacent to locally thickened portions of the topmost second-tier active sacrificial material layer 242. The second photoresist layer 237 may be subsequently removed, for example, by ashing.

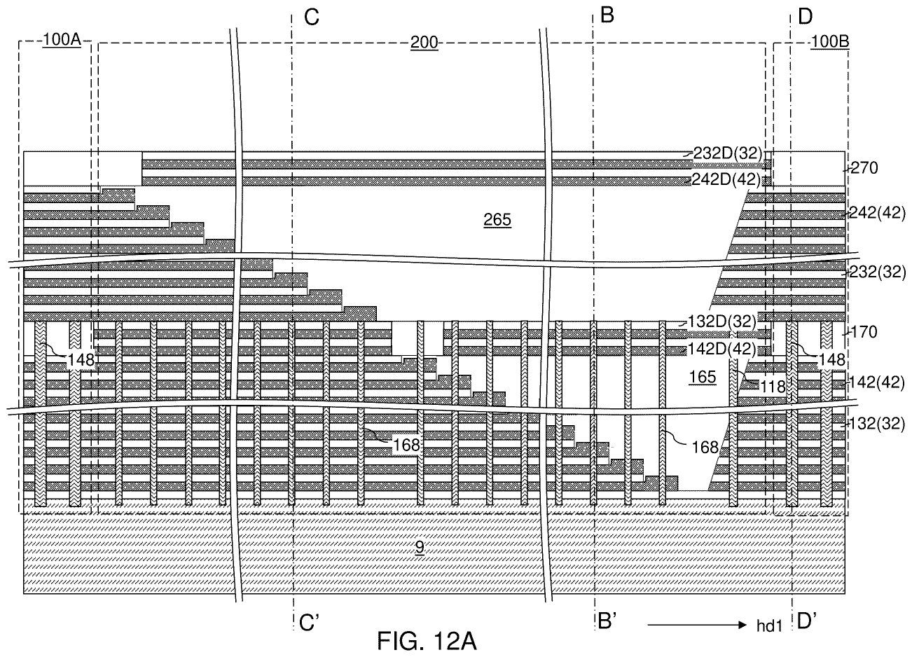

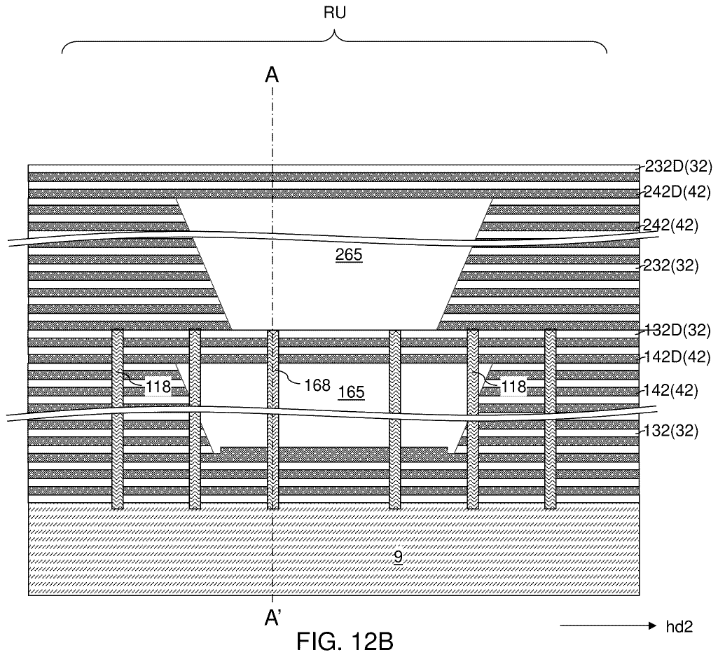

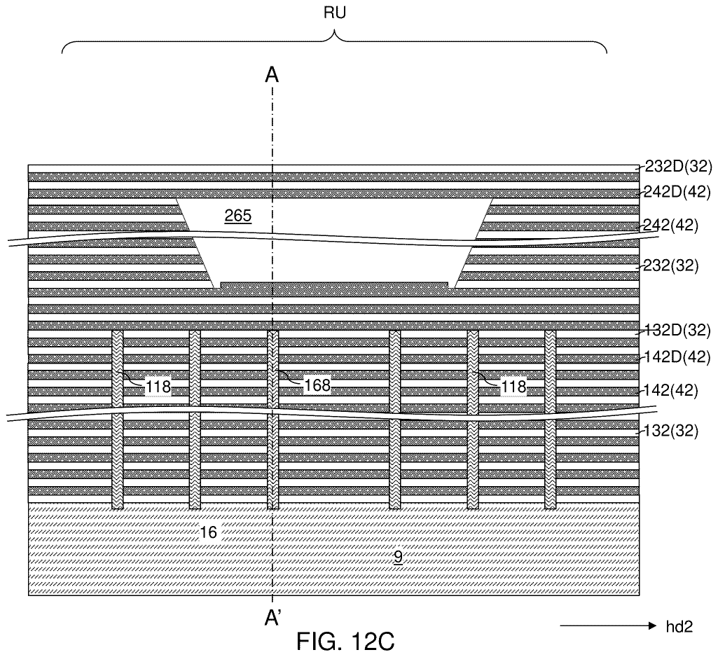

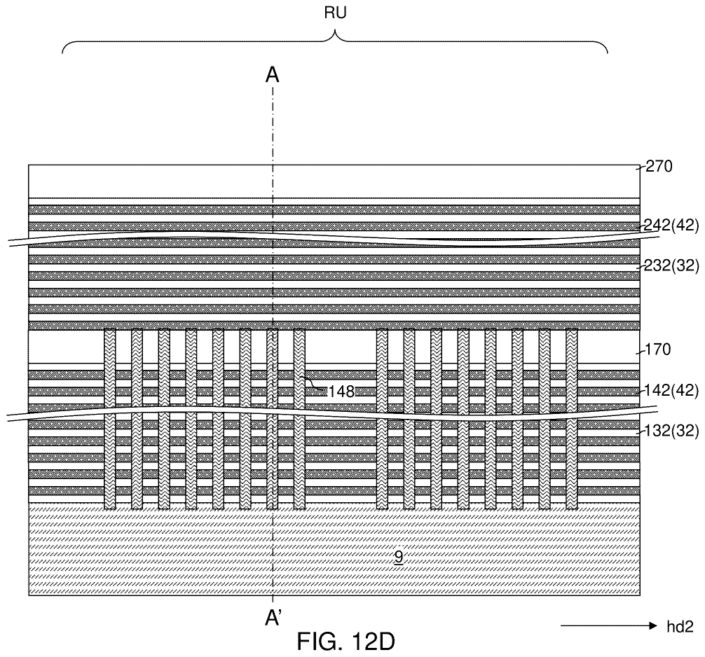

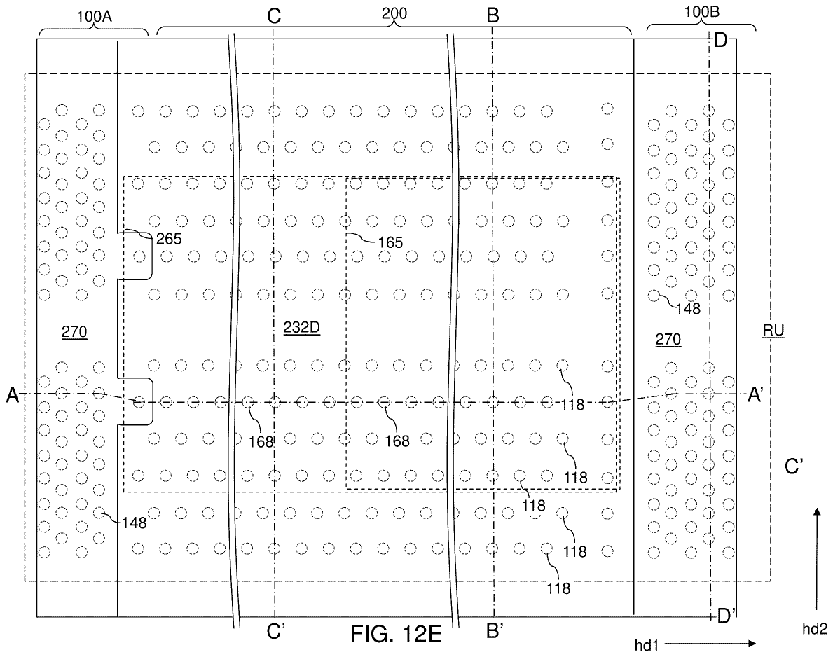

Referring to FIGS. 12A-12E, an insulating material can be deposited over the at least one pair of a second-tier dummy insulating layer 232D and a second-tier dummy sacrificial material layer 242D and over the second vertically alternating sequence of second-tier insulating layers 232 and second-tier active sacrificial material layers 242. A planarization process, such as a chemical mechanical polishing process, may be performed to remove portions of the insulating material from above a horizontal plane including a topmost surface of the at least one pair of a second-tier dummy insulating layer 232D and a second-tier dummy sacrificial material layer 242D. Remaining portions of the insulating material constitute a second-tier insulating cap layer 270. In one embodiment, the second-tier insulating cap layer 270 may comprise the same insulating material as the second-tier insulating layers 232. In one embodiment, the top surface of the second-tier insulating cap layer 270 may be formed in the horizontal plane including the topmost surface of the at least one pair of a second-tier dummy insulating layer 232D and a second-tier dummy sacrificial material layer 242D.

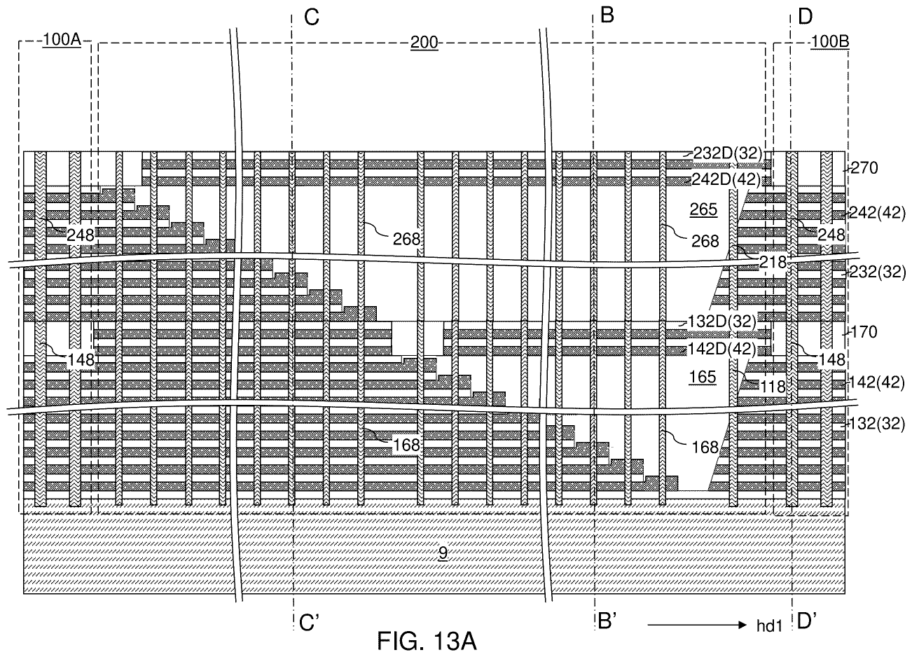

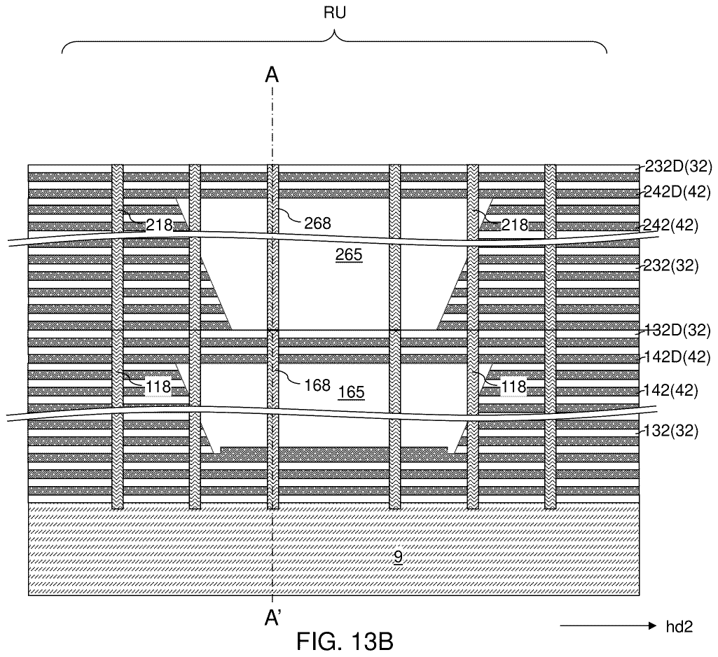

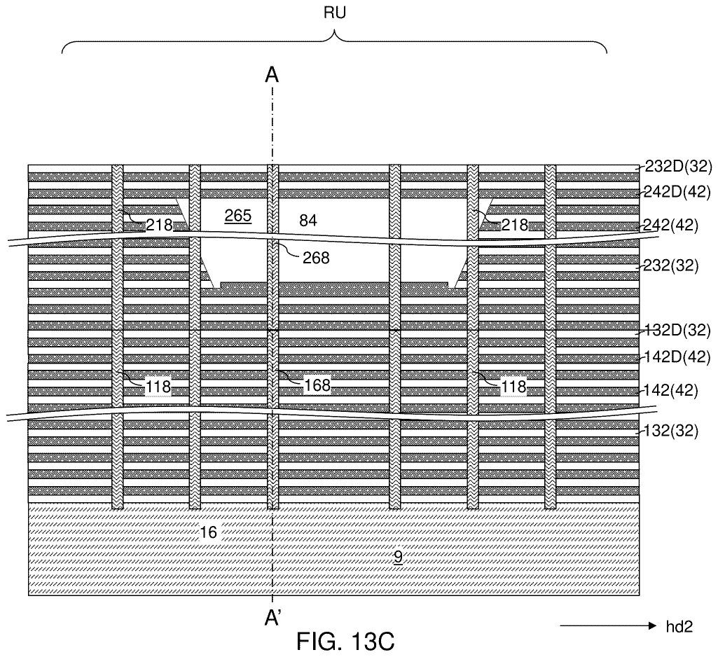

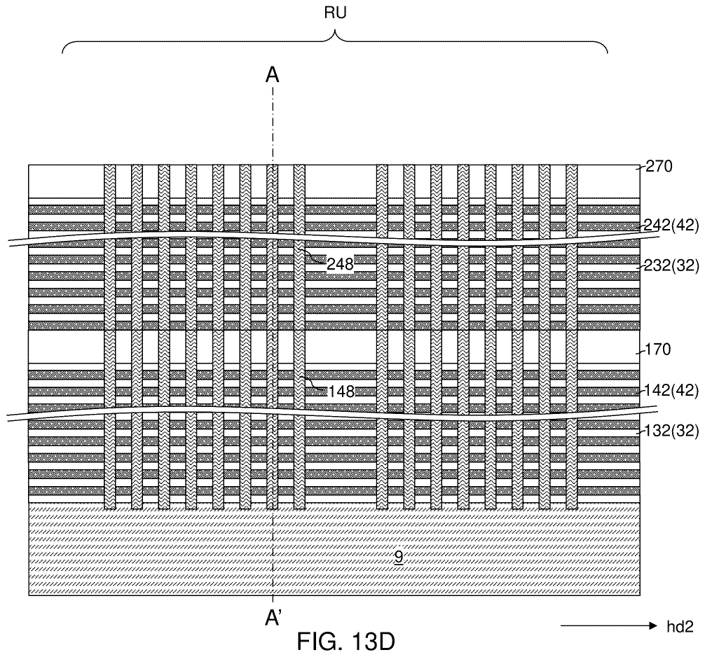

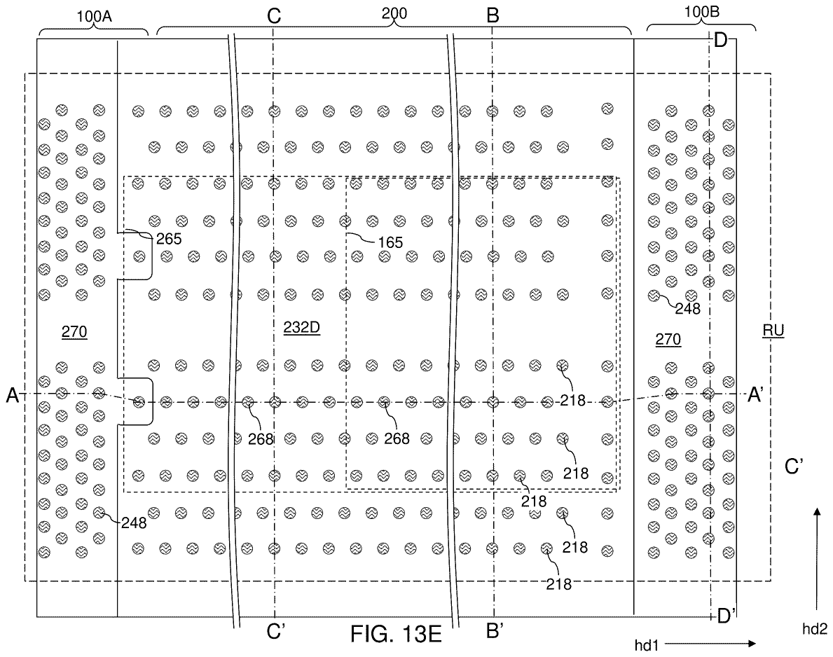

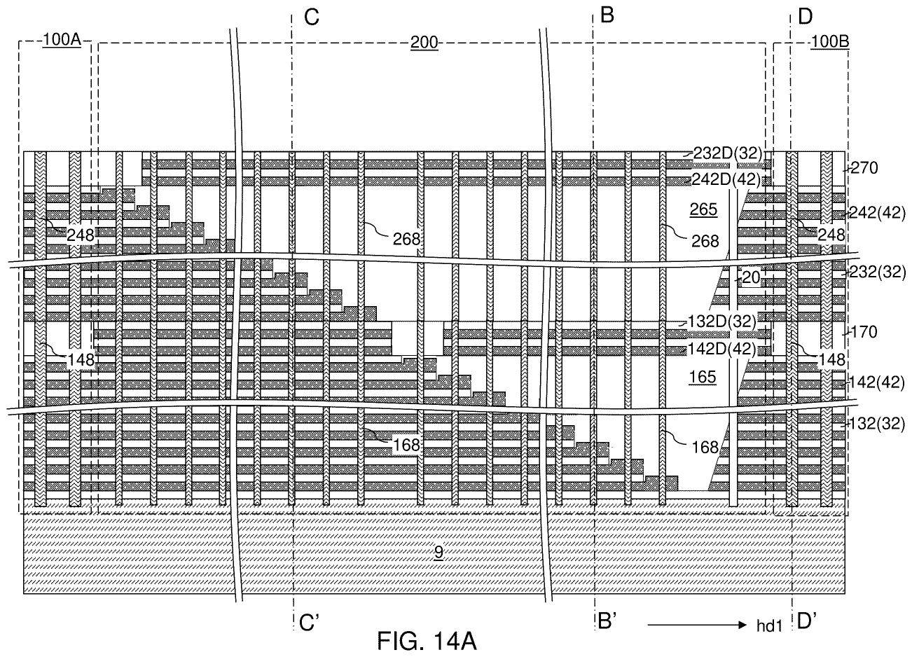

Referring to FIGS. 13A-13E, various second-tier openings may be formed through the second vertically alternating sequence (232, 242). A photoresist layer (not shown) may be applied over the second vertically alternating sequence (232, 242), and may be lithographically patterned to form various openings therethrough. The pattern of openings in the photoresist layer may be transferred through the second vertically alternating sequence (232, 242) by a second anisotropic etch process to form the various second-tier openings concurrently. The various second-tier openings may include second-tier memory openings formed in the memory array regions (100A, 100B) and second-tier support openings formed in the contact regions 200, and second-tier contact openings formed in the staircase regions 267 which are located within the contact regions 200.

Each cluster of second-tier memory openings may be formed as a two-dimensional array of second-tier memory openings. The second-tier support openings are openings that are formed in the contact region 200, and are subsequently employed to form support pillar structures. Each second-tier contact opening is formed in a respective area in which a respective through-via contact structure is to be subsequently formed. A subset of the second-tier support openings may be formed through a respective horizontally-extending surface segment of the second stepped surfaces. A subset of the second-tier contact openings is formed through a respective horizontally-extending surface segment of the second stepped surfaces.

Sacrificial second-tier opening fill structures (248, 218, 268) may be formed in the various second-tier openings. For example, a sacrificial second-tier fill material is concurrently deposited in each of the second-tier openings. The sacrificial second-tier fill material includes a material that may be subsequently removed selectively to the materials of the second-tier insulating layers 232 and the second-tier active sacrificial material layers 242. In one embodiment, the sacrificial second-tier fill material may include a semiconductor material such as silicon (e.g., a-Si or polysilicon), silicon-germanium, germanium, a III-V compound semiconductor material, or a combination thereof. Optionally, a thin etch stop liner (such as a silicon oxide layer or a silicon nitride layer having a thickness in a range from 2 nm to 3 nm) may be used prior to depositing the sacrificial second-tier fill material. The sacrificial second-tier fill material may be formed by a non-conformal deposition or a conformal deposition method.

In another embodiment, the sacrificial second-tier fill material may include a silicon oxide material having a higher etch rate than the material of the second-tier insulating layers 232. For example, the sacrificial second-tier fill material may include borosilicate glass or porous or non-porous organosilicate glass having an etch rate that is at least 100 times higher than the etch rate of densified TEOS oxide (i.e., a silicon oxide material formed by decomposition of tetraethylorthosilicate glass in a chemical vapor deposition process and subsequently densified in an anneal process) in a 100:1 dilute hydrofluoric acid. In this case, a thin etch stop liner (such as a silicon nitride layer having a thickness in a range from 1 nm to 3 nm) may be used prior to depositing the sacrificial second-tier fill material. The sacrificial second-tier fill material may be formed by a non-conformal deposition or a conformal deposition method.

Portions of the deposited sacrificial second-tier fill material may be removed from above the horizontal plane including the top surface of the second-tier insulating cap layer 270. For example, the sacrificial second-tier fill material may be recessed to the horizontal plane including the top surface of the second-tier insulating cap layer 270 using a planarization process. The planarization process may include a recess etch, chemical mechanical planarization (CMP), or a combination thereof. The top surface of the second-tier insulating cap layer 270 may be used as an etch stop layer or a planarization stop layer.

Remaining portions of the sacrificial second-tier fill material comprise sacrificial second-tier opening fill structures (248, 218, 268). Specifically, each remaining portion of the sacrificial second-tier fill material in a second-tier memory opening constitutes a sacrificial second-tier memory opening fill structure 248. Each remaining portion of the sacrificial second-tier fill material in a second-tier support opening constitutes a sacrificial second-tier support opening fill structure 218. Each remaining portion of the sacrificial second-tier fill material in a second-tier contact opening constitutes a sacrificial second-tier contact opening fill structure 268. The various sacrificial second-tier opening fill structures (248, 218, 268) are concurrently formed, i.e., employing a same set of processes including the deposition process that deposits the sacrificial second-tier fill material and the planarization process that removes the second-tier deposition process from above the horizontal plane including the top surface of the second-tier insulating cap layer 270. The top surfaces of the sacrificial second-tier opening fill structures (248, 218, 268) may be coplanar with the top surface of the second-tier insulating cap layer 270. Each of the sacrificial second-tier opening fill structures (248, 218, 268) may optionally include cavities therein. The set of all structures located between the bottommost surface of the second vertically alternating sequence (232, 242) and the topmost surface of the second vertically alternating sequence (232, 242) or embedded within the second vertically alternating sequence (232, 242) constitutes a second-tier structure.

According to an aspect of the present disclosure, each second-tier active sacrificial material layer 242 comprises a respective locally thickened portion underneath each second-tier retro-stepped dielectric material portion 265. A subset of the second-tier contact openings can be formed through a locally thickened portion of a respective second-tier active sacrificial material layer 242. The sacrificial second-tier contact opening fill structures 268 may vertically extend from a horizontal plane including a top surface of the second-tier insulating cap layer 270 at least to a horizontal plane including a bottom surface of the second-tier alternating stack (232, 242).

Referring collectively to FIGS. 1-13E, at least one alternating stack (32, 42) of insulating layers 32 and active sacrificial material layers 42 embedding a respective retro-stepped dielectric material portion (165 or 265) can be formed over a substrate 9. At least one dummy sacrificial material layer (142D and/or 242D) can be formed over each retro-stepped dielectric material portion (165 or 265) overlying the stepped surfaces of a staircase region (167, 267). In one embodiment, the at least one dummy sacrificial material layer (142D and/or 242D) does not cover a memory array region (100A, 100B) in a plan view. The total number of alternating stacks (32, 42) embedding a respective set of retro-stepped dielectric material portions (165 or 265), i.e., the total number of tier structures that are formed over the substrate 9, may be in a range from 1 to 8, such as from 1 to 4. In the illustrated example, the total number of tier structures is 2. Generally, at least one tier structure, and/or each tier structure, may be formed with a respective set of at least one dummy insulating layer and at least one dummy sacrificial material layer that do not have any areal overlap with the memory array regions (100A, 100B).

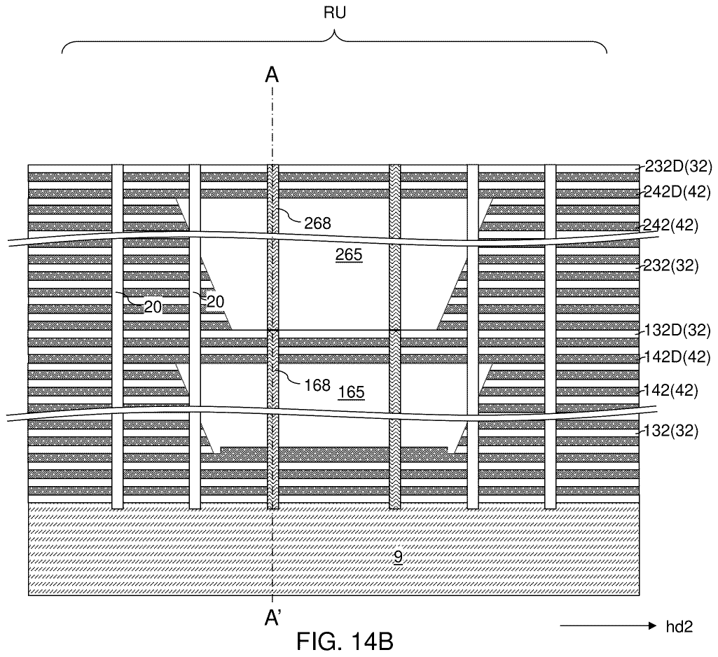

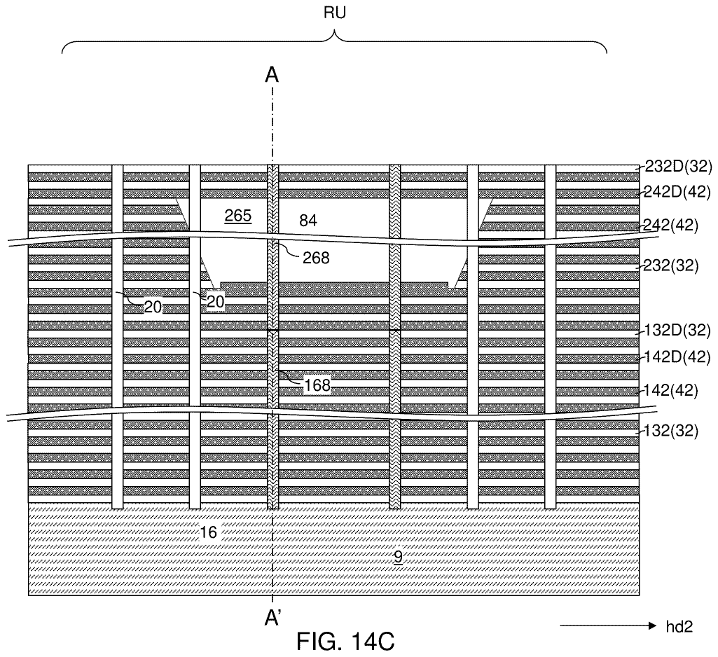

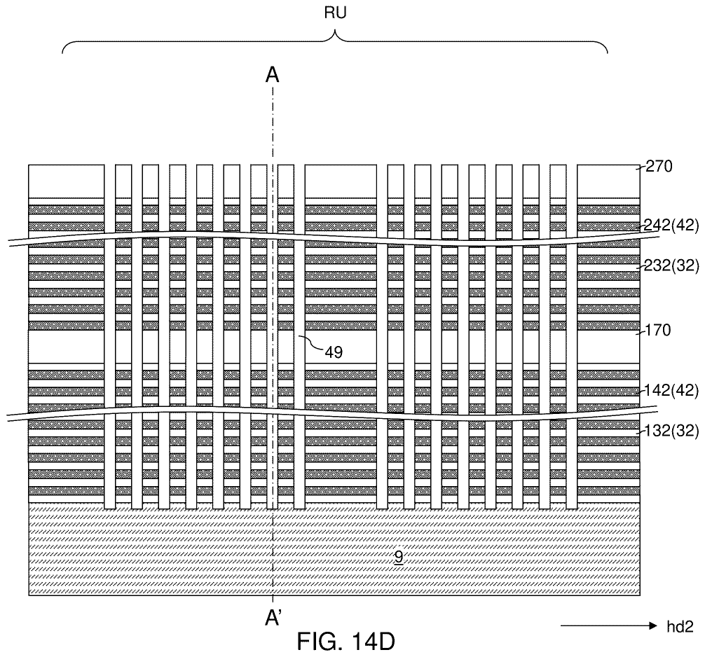

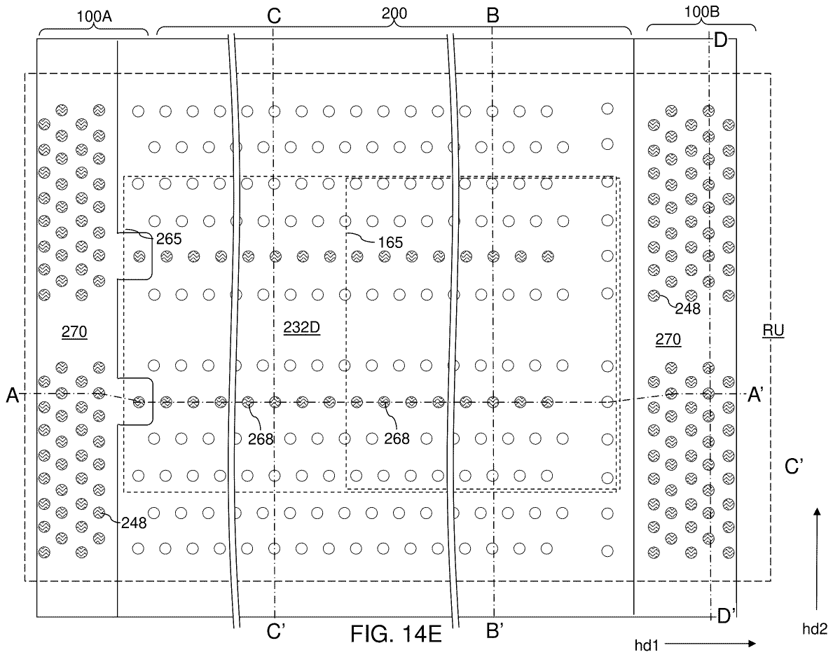

Referring to FIGS. 14A-14E, a photoresist layer (not shown) can be applied over the topmost tier structure (such as the second tier structure), and can be lithographically patterned to form openings over the areas of the sacrificial support opening fill structures (218, 118). The sacrificial fill materials of the sacrificial support opening fill structures (218, 118) can be removed selectively to the materials of retro-stepped dielectric material portions (165, 265), the insulating layers 32, and the sacrificial material layers 42. Support pillar cavities (can be formed in the volumes from which the materials of the sacrificial support opening fill structures (218, 118) are removed. The photoresist layer can be subsequently removed, for example, by ashing.

A dielectric fill material can be deposited in the support pillar cavities by performing a conformal deposition process. The dielectric fill material comprises a dielectric material that is different from the material of the sacrificial material layers 42. For example, the dielectric fill material may comprise undoped silicate glass (i.e., silicon oxide) or a doped silicate glass. Excess portions of the dielectric fill material can be removed from above the horizontal plane including the top surface of the topmost insulating cap layer (such as the second-tier insulating cap layer 270). Each remaining portion of the dielectric fill material that fills a respective support pillar cavity constitutes a support pillar structure 20, which may be also referred to as a dielectric support pillar structure. The support pillar structures 20 can be formed in the contact region 200, and may vertically extend from the substrate 9 to a horizontal plane including the topmost surfaces of the second-tier insulating cap layer 270.

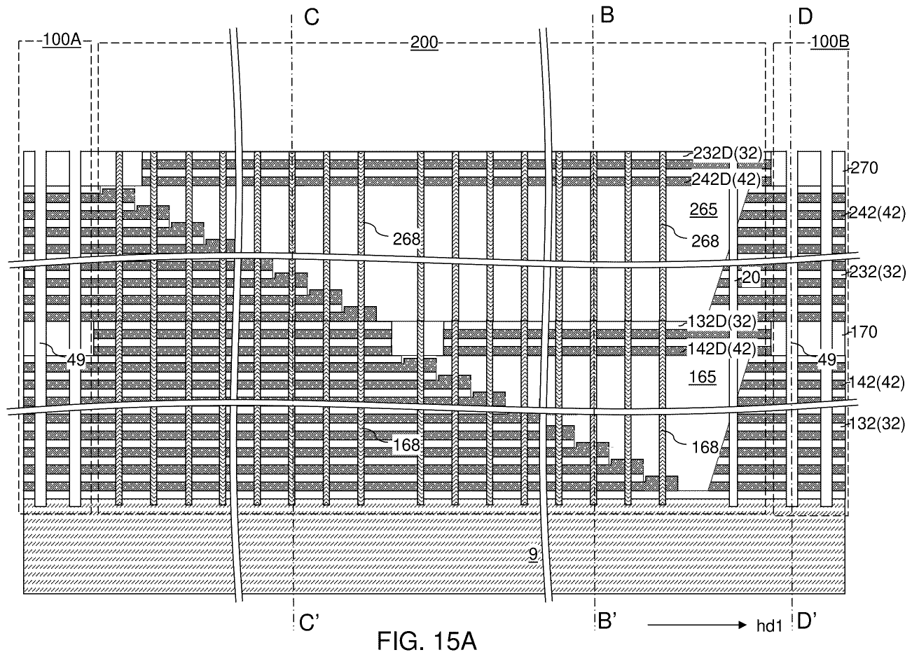

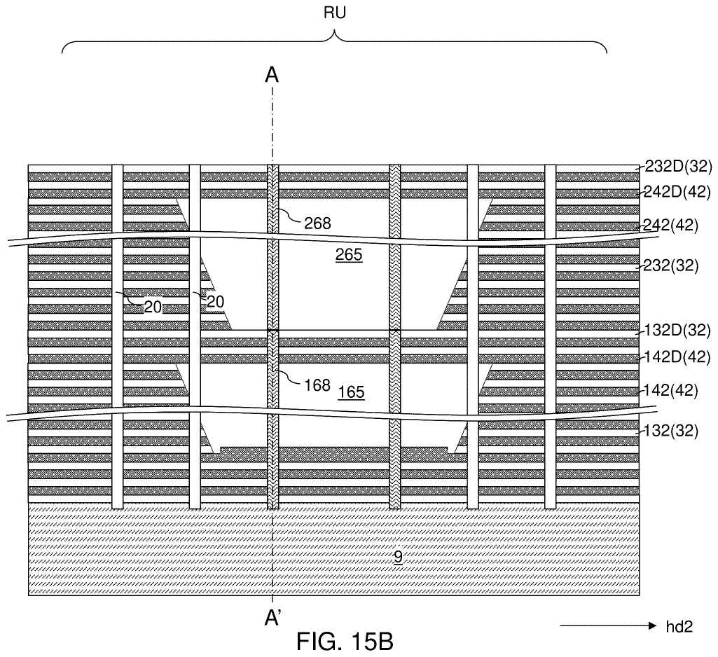

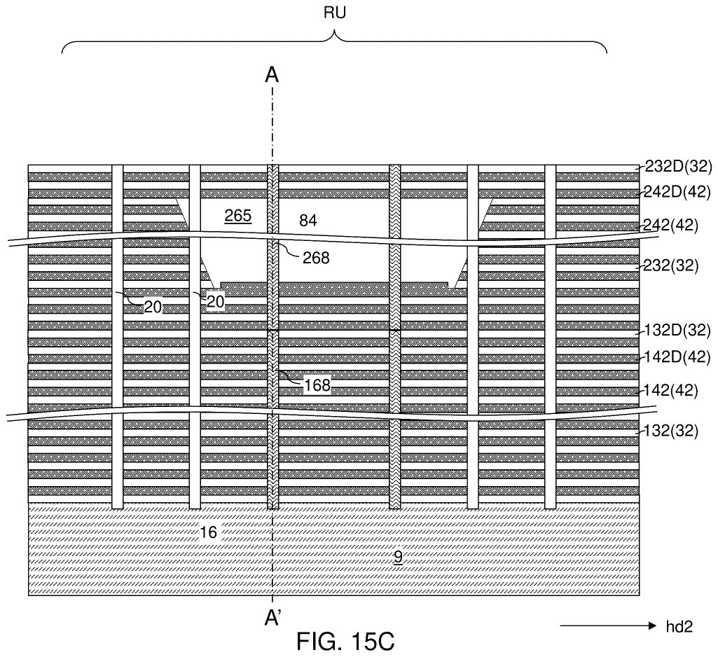

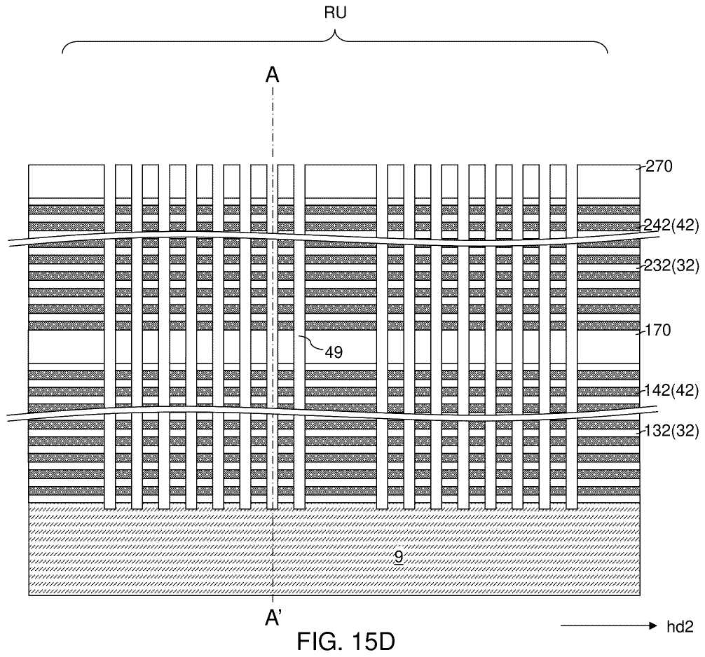

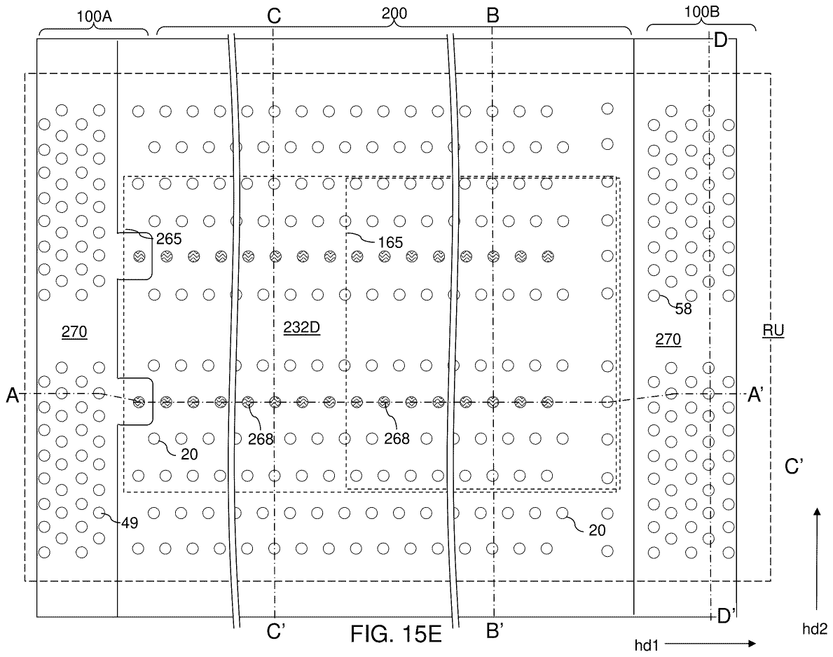

In an alternative embodiment, the sacrificial fill materials of the sacrificial support opening fill structures (218, 118) may be replaced with a same set of materials as memory opening fill structures by omitting the processing steps described with reference to FIGS. 14A-14E , and by replacing the sacrificial fill materials of the sacrificial support opening fill structures (218, 118) with support pillar structures comprising a same set of materials as memory opening fill structures during the processing steps described with reference to FIGS. 15A-17E.

Referring to FIGS. 15A-15E, a photoresist layer (not shown) can be applied over the third-tier structure, and can be lithographically patterned to cover the contact regions 200 without covering the memory array regions 100. The sacrificial fill materials of the sacrificial memory opening fill structures (148, 248) can be removed selectively to the materials of the insulating layers 32, the sacrificial material layers 42, and the substrate 9. Memory openings 49 are formed in the voids from which the sacrificial fill materials of the sacrificial memory opening fill structures (148, 248) are removed.

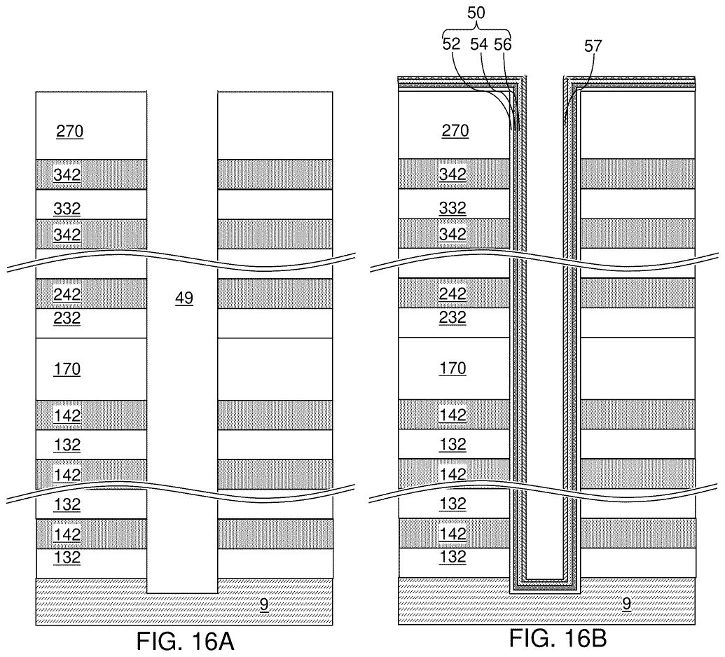

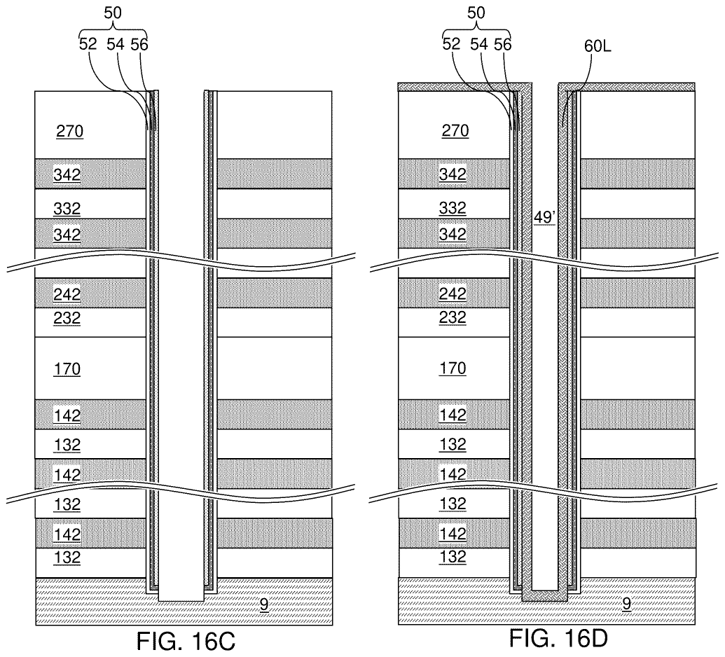

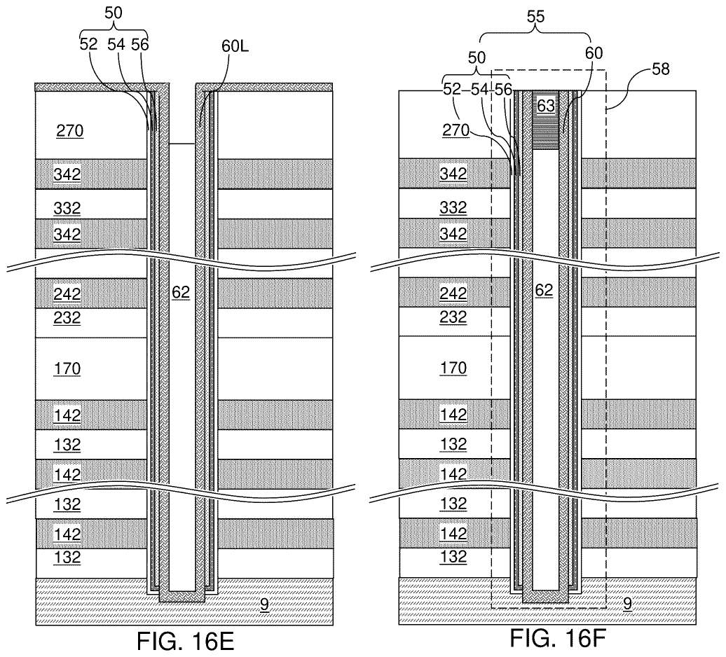

FIGS. 16A-16F illustrate sequential vertical cross-sectional views of a memory opening during formation of a memory opening fill structure according to an embodiment of the present disclosure.

Referring to FIG. 16A, a memory opening 49 in the first exemplary structure of FIGS. 15A-15E is illustrated.

Referring to FIG. 16B, a stack of layers including a blocking dielectric layer 52, a memory material layer 54, a dielectric liner 56, and an optional sacrificial cover layer 57 may be sequentially deposited in the inter-tier memory openings 49. The blocking dielectric layer 52 may include a single dielectric material layer or a stack of a plurality of dielectric material layers. In one embodiment, the blocking dielectric layer 52 may include a dielectric metal oxide layer consisting essentially of a dielectric metal oxide. As used herein, a dielectric metal oxide refers to a dielectric material that includes at least one metallic element and at least oxygen. The dielectric metal oxide may consist essentially of the at least one metallic element and oxygen, or may consist essentially of the at least one metallic element, oxygen, and at least one non-metallic element such as nitrogen. In one embodiment, the blocking dielectric layer 52 may include a dielectric metal oxide having a dielectric constant greater than 7.9, i.e., having a dielectric constant greater than the dielectric constant of silicon nitride. The thickness of the dielectric metal oxide layer may be in a range from 1 nm to 20 nm, although lesser and greater thicknesses may also be used. The dielectric metal oxide layer may subsequently function as a dielectric material portion that blocks leakage of stored electrical charges to control gate electrodes. In one embodiment, the blocking dielectric layer 52 includes aluminum oxide. Alternatively or additionally, the blocking dielectric layer 52 may include a dielectric semiconductor compound such as silicon oxide, silicon oxynitride, silicon nitride, or a combination thereof.

Subsequently, the memory material layer 54 may be formed. Generally, the memory material layer 54 may comprise any memory material known in the art. In one embodiment, the memory material layer 54 may be a continuous layer or patterned discrete portions of a charge trapping material including a dielectric charge trapping material, which may be, for example, silicon nitride. Alternatively, the memory material layer 54 may include a continuous layer or patterned discrete portions of a conductive material such as doped polysilicon or a metallic material that is patterned into multiple electrically isolated portions (e.g., floating gates), for example, by being formed within lateral recesses into sacrificial material layers 42. In one embodiment, the memory material layer 54 includes a silicon nitride layer. In one embodiment, the sacrificial material layers 42 and the insulating layers 32 may have vertically coincident sidewalls, and the memory material layer 54 may be formed as a single continuous layer. Alternatively, the sacrificial material layers 42 may be laterally recessed with respect to the sidewalls of the insulating layers 32, and a combination of a deposition process and an anisotropic etch process may be used to form the memory material layer 54 as a plurality of memory material portions that are vertically spaced apart. The thickness of the memory material layer 54 may be in a range from 2 nm to 20 nm, although lesser and greater thicknesses may also be used.

The dielectric liner 56 includes a dielectric material. In one embodiment, the dielectric liner 56 may comprise a tunneling dielectric layer through which charge tunneling may be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The dielectric liner 56 may include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the dielectric liner 56 may include a stack of a first silicon oxide layer, a silicon oxynitride layer, and a second silicon oxide layer, which is commonly known as an ONO stack. In one embodiment, the dielectric liner 56 may include a silicon oxide layer that is substantially free of carbon or a silicon oxynitride layer that is substantially free of carbon. The thickness of the dielectric liner 56 may be in a range from 2 nm to 20 nm, although lesser and greater thicknesses may also be used. The stack of the blocking dielectric layer 52, the memory material layer 54, and the dielectric liner 56 constitutes a memory film 50 that stores memory bits.

The sacrificial cover layer 57 may comprise a sacrificial material that may be subsequently removed selectively to the material of the dielectric liner 56. For example, the sacrificial cover layer may comprise a semiconductor material (e.g., amorphous silicon), silicon oxide, or a carbon-based material (such as amorphous carbon or diamond-like carbon). The thickness of the sacrificial cover layer may be in a range from 1 nm to 10 nm, although lesser and greater thicknesses may also be employed.

Referring to FIG. 16C, an anisotropic etch process may be performed to remove horizontal portions of the sacrificial cover layer 57, the dielectric liner 56, the memory material layer 54, and the blocking dielectric layer 52. Remaining cylindrical portions of the sacrificial cover layer 57 may be removed selectively to the material of the dielectric liner 56 during the anisotropic etch process, or by an isotropic etch process (such as a wet etch process) or by ashing. Alternatively, if the sacrificial cover layer 57 comprises a semiconductor material (e.g., amorphous silicon), then it may be retained.

Referring to FIG. 16D, a semiconductor channel material layer 60L can be deposited by a conformal deposition process. The semiconductor channel material layer 60L includes a p-doped semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel material layer 60L may have a uniform doping. In one embodiment, the semiconductor channel material layer 60L has a p-type doping in which p-type dopants (such as boron atoms) are present at an atomic concentration in a range from 1.0×10¹²/cm³ to 1.0×10¹⁸/cm³, such as from 1.0×10¹⁴/cm³ to 1.0×10¹⁷/cm³. In one embodiment, the semiconductor channel material layer 60L includes, and/or consists essentially of, boron-doped amorphous silicon or boron-doped polysilicon. In another embodiment, the semiconductor channel material layer 60L has an n-type doping in which n-type dopants (such as phosphor atoms or arsenic atoms) are present at an atomic concentration in a range from 1.0×10¹²/cm³ to 1.0×10¹⁸/cm³, such as from 1.0×10¹⁴/cm³ to 1.0×10¹⁷/cm³. The semiconductor channel material layer 60L may be formed by a conformal deposition method such as a low pressure chemical vapor deposition (LPCVD) process. The thickness of the semiconductor channel material layer 60L may be in a range from 2 nm to 10 nm, although lesser and greater thicknesses may also be used. A cavity 49′ is formed in the volume of each inter-tier memory opening 49 that is not filled with the deposited material layers (52, 54, 56, 60L).

Referring to FIG. 16E, if the cavity 49′ in each memory opening 49 is not completely filled by the semiconductor channel material layer 60L, a dielectric core layer may be deposited in the cavity 49′ to fill any remaining portion of the cavity 49′ within each memory opening 49. The dielectric core layer includes a dielectric material such as silicon oxide or organosilicate glass. The dielectric core layer may be deposited by a conformal deposition method such as a low pressure chemical vapor deposition (LPCVD) process, or by a self-planarizing deposition process such as spin coating. The horizontal portion of the dielectric core layer overlying the third-tier insulating cap layer 370 may be removed, for example, by a recess etch. The recess etch continues until top surfaces of the remaining portions of the dielectric core layer are recessed to a height between the top and bottom surfaces of the third-tier insulating cap layer 370. Each remaining portion of the dielectric core layer constitutes a dielectric core 62.

Referring to FIG. 16F, a doped semiconductor material having a doping of a second conductivity type may be deposited in cavities overlying the dielectric cores 62. The second conductivity type is the opposite of the first conductivity type. For example, if the first conductivity type is p-type, the second conductivity type is n-type, and vice versa. Portions of the deposited doped semiconductor material, the semiconductor channel material layer 60L, the dielectric liner 56, the memory material layer 54, and the blocking dielectric layer 52 that overlie the horizontal plane including the top surface of the third-tier insulating cap layer 370 may be removed by a planarization process such as a chemical mechanical planarization (CMP) process.

Each remaining portion of the doped semiconductor material of the second conductivity type constitutes a drain region 63. The dopant concentration in the drain regions 63 may be in a range from 5.0×10¹⁸/cm³ to 2.0×10²¹/cm³, although lesser and greater dopant concentrations may also be used. The doped semiconductor material may be, for example, doped polysilicon.

Each remaining portion of the semiconductor channel material layer 60L constitutes a vertical semiconductor channel 60 through which electrical current may flow when a vertical NAND device including the vertical semiconductor channel 60 is turned on. A dielectric liner 56 is surrounded by a memory material layer 54, and laterally surrounds a vertical semiconductor channel 60. Each adjoining set of a blocking dielectric layer 52, a memory material layer 54, and a dielectric liner 56 collectively constitute a memory film 50, which may store electrical charges with a macroscopic retention time. In some embodiments, a blocking dielectric layer 52 may not be present in the memory film 50 at this step, and a blocking dielectric layer may be subsequently formed after formation of lateral recesses. As used herein, a macroscopic retention time refers to a retention time suitable for operation of a memory device as a permanent memory device such as a retention time in excess of 24 hours.

Each combination of a memory film 50 and a vertical semiconductor channel 60 within an inter-tier memory opening 49 constitutes a memory stack structure 55. The memory stack structure 55 is a combination of a vertical semiconductor channel 60, a dielectric liner 56, a plurality of memory elements comprising portions of the memory material layer 54, and an optional blocking dielectric layer 52. The memory stack structures 55 can be formed through memory array regions 100 of the first and second vertically alternating sequences in which all layers of the first and second vertically alternating sequences are present. Each combination of a memory stack structure 55, a dielectric core 62, and a drain region 63 within an inter-tier memory opening 49 constitutes a memory opening fill structure 58. Generally, memory opening fill structures 58 are formed within the memory openings 49. Each of the memory opening fill structures 58 comprises a respective memory film 50 and a respective vertical semiconductor channel 60.

In one embodiment, each of the memory stack structures 55 comprises vertical NAND string including the respective vertical stack of memory elements (comprising portions of a memory material layer 54 located at levels of the sacrificial material layers 42) and a vertical semiconductor channel 60 that vertically extend through the sacrificial material layers 42 adjacent to the respective vertical stack of memory elements.

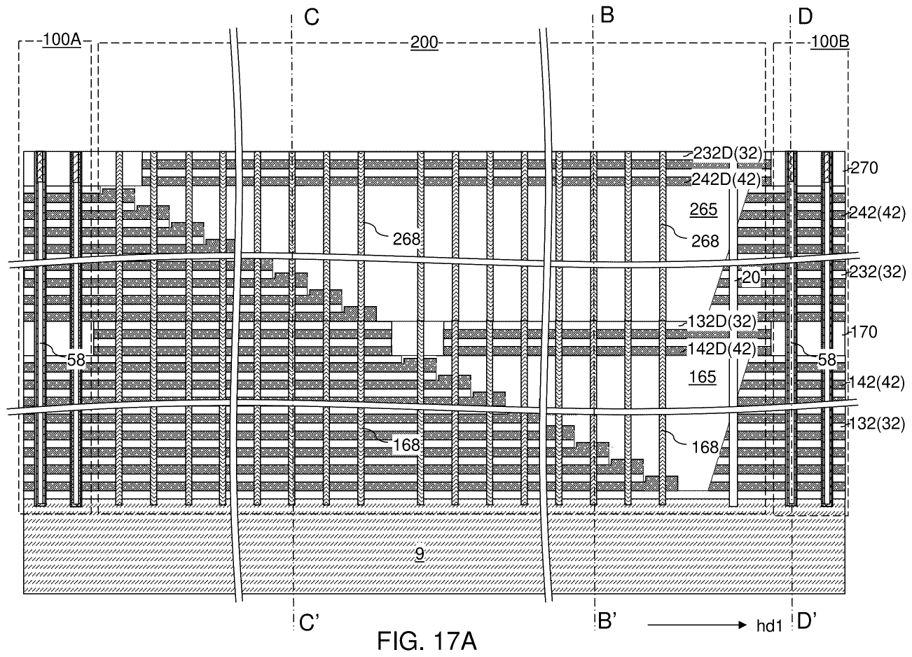

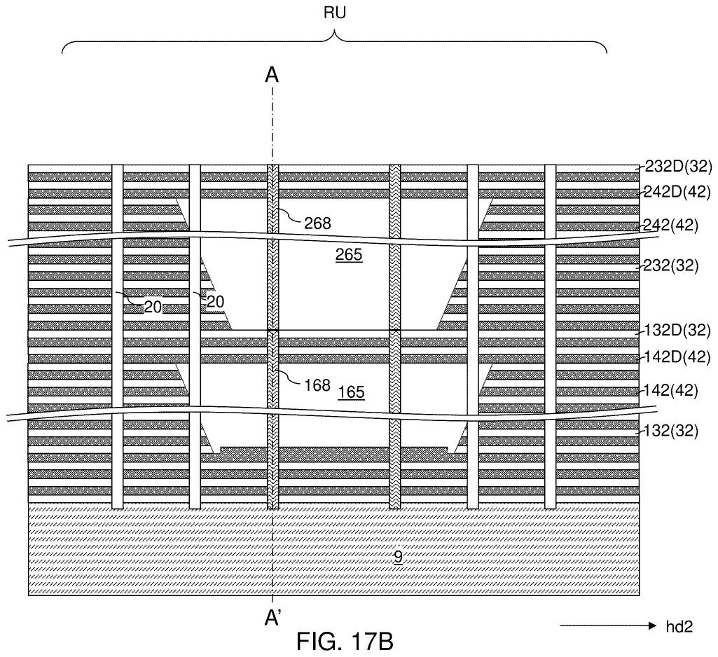

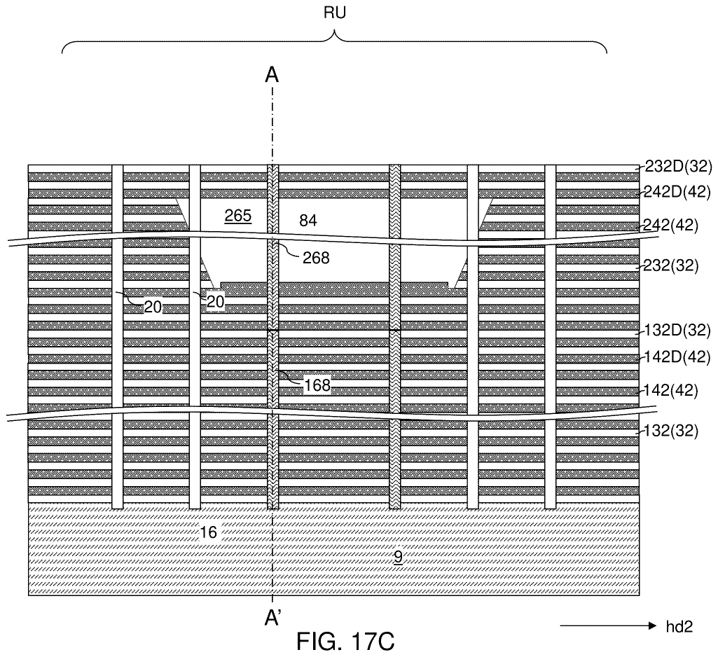

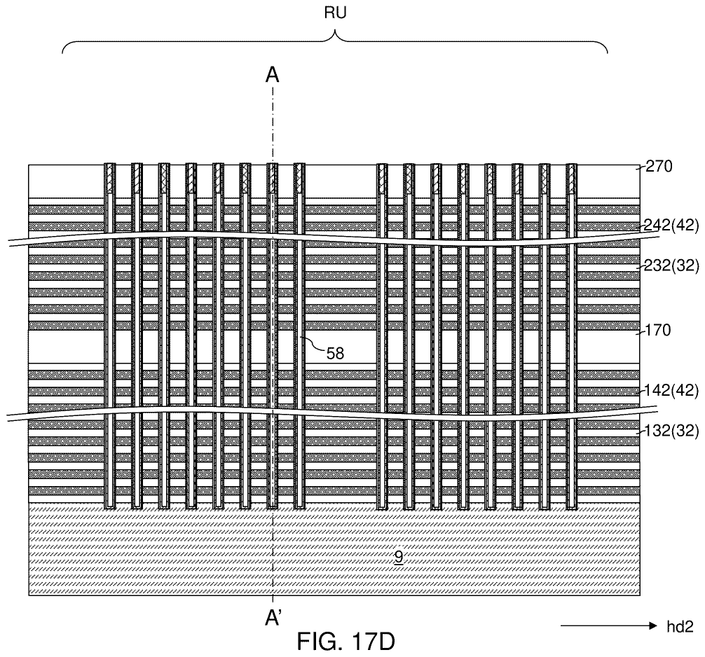

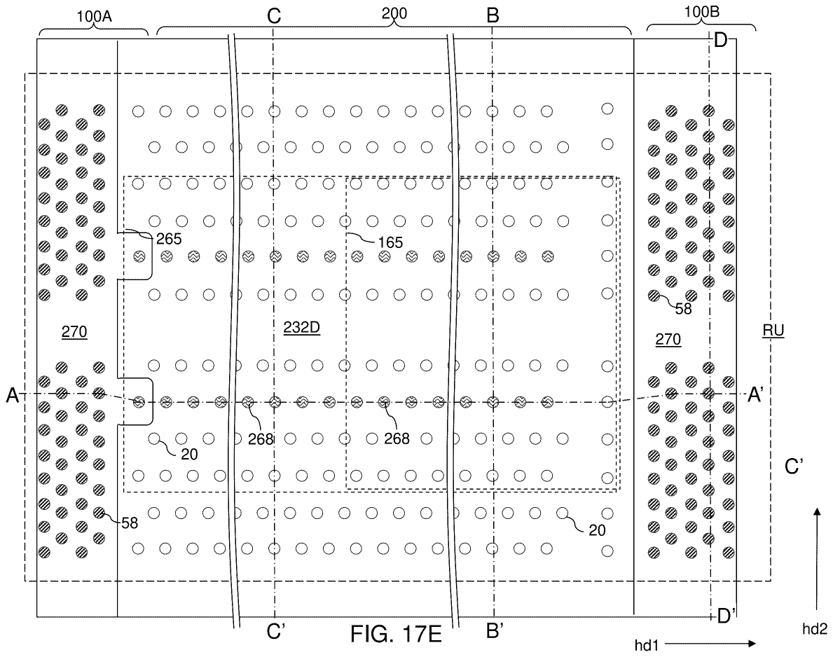

Referring to FIGS. 17A-17E, the first exemplary structure is illustrated after the processing steps of FIG. 16F, i.e., after formation of the memory opening fill structures 58 in the memory openings 49. In one embodiment, support pillar structures (not shown) may be formed in the support openings. Generally, each of the memory opening fill structures 58 comprises a respective vertical stack of memory elements located at levels of the active sacrificial material layers (142, 242) within memory openings 49, and further comprises a respective vertical semiconductor channel 60 that vertically extends through the memory openings 49.

In summary, at least one alternating stack (32, 42) of insulating layers 32 and sacrificial material layers 42 is formed over a substrate 9. Each alternating stack (32, 42) of insulating layers 32 and sacrificial material layers 42 embeds a respective set of retro-stepped dielectric material portions (165 or 265). Within each tier structure, the sacrificial material layers 42 comprise active sacrificial material layers (142, 242) located below a horizontal plane including a topmost surface of an embedded set of retro-stepped dielectric material portions (165 or 265), and at least one dummy sacrificial material layer (142D or 242D) overlying the embedded set of retro-stepped dielectric material portions (165 or 265). Memory openings 49 can be formed through at least one alternating stack (32, 42) in the memory array regions (100A, 100B). The memory openings 49 vertically extend through each of the active sacrificial material layers (142, 242) and are laterally spaced from, and does not contact, each of the at least one dummy sacrificial material layer (142D or 242D). Memory opening fill structures 58 can be formed in the memory openings 49. Each of the memory openings 49 comprises a respective vertical stack of memory elements (e.g., portions of the memory film 50) located at levels of the active sacrificial material layers (142, 242), a vertical semiconductor channel 60 vertically extending through each of the active sacrificial material layers (142, 242), and a drain region 63 located above the horizontal plane.

For each tier structure, an insulating cap layer (170 or 270) having a bottom surface located within or above a horizontal plane including a top surface of the set of retro-stepped dielectric material portions (165 or 265) can be provided. The memory openings 49 vertically extend through the insulating cap layer (170 or 270). Within each tier structure, each of the at least one dummy sacrificial material layer (142D or 242D) is located entirely between a first horizontal plane including a bottom surface of the insulating cap layer (170 or 270) and a second horizontal plane including a top surface of the insulating cap layer (170 or 270). For each tier structure, the insulating cap layer (170 or 270) overlies each of the active sacrificial material layers (142, 242) of the tier structure, and has a bottom surface located within or above a bottommost surface of the at least one dummy sacrificial material layer (142D or 242D) of the tier structure, and contacts sidewalls of the memory opening fill structures 58.

In one embodiment, top surfaces of the memory opening fill structures 58 are located within a horizontal plane including a top surface of the insulating cap layer (such as the second-tier insulating cap layer 270) of the topmost tier structure. Support pillar structures 20 vertically extend through the alternating stack (32, 42), and have top surfaces located within a horizontal plane including a topmost surface of the topmost tier structure, such as a top surface of the second-tier insulating cap layer 270 in the illustrated example. In one embodiment, a subset of the support pillar structures 20 vertically extends through at least one of the retro-stepped dielectric material portions (165 or 265).

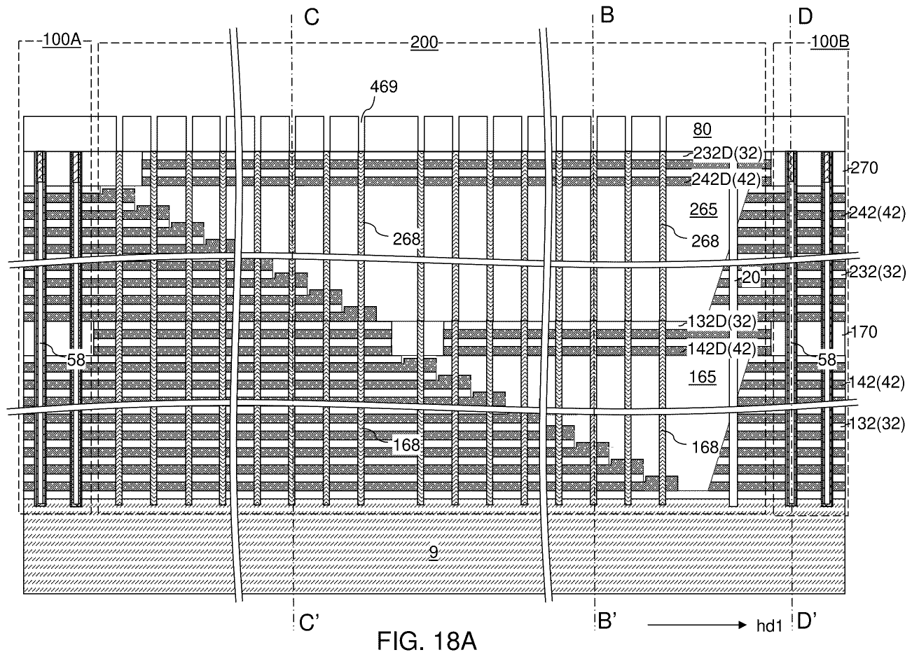

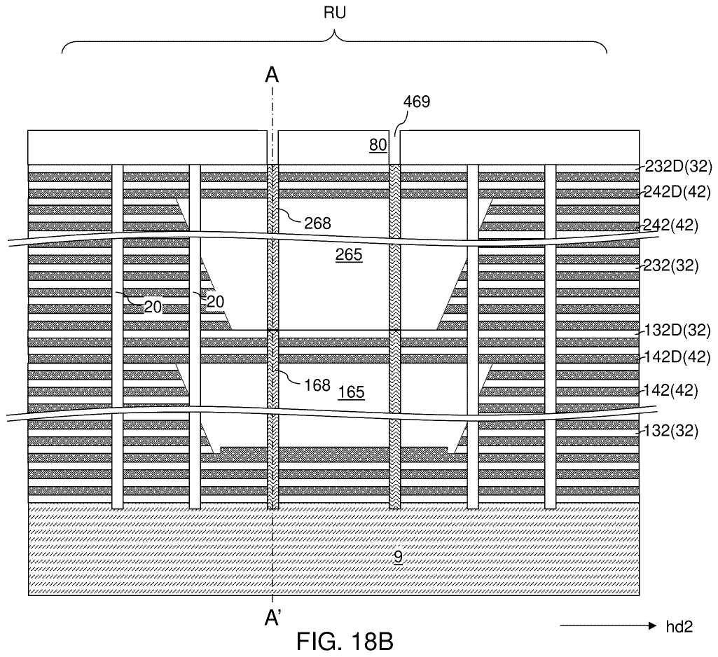

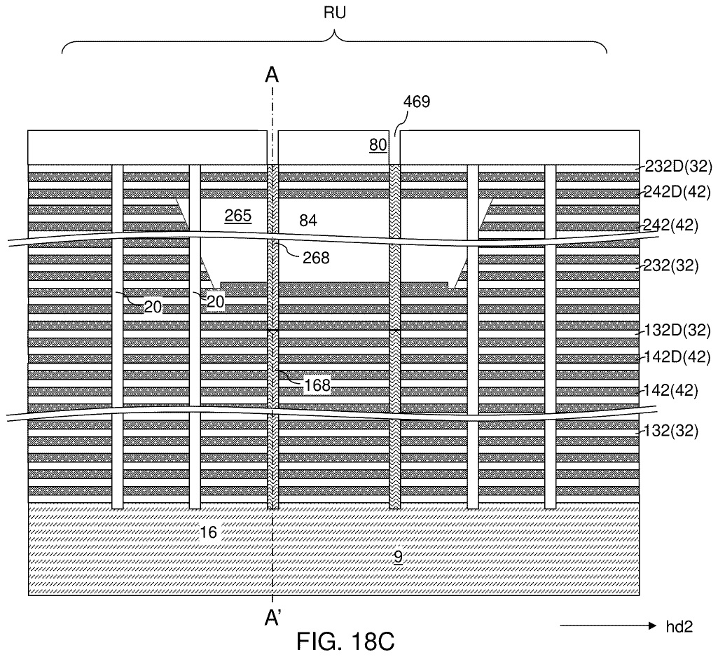

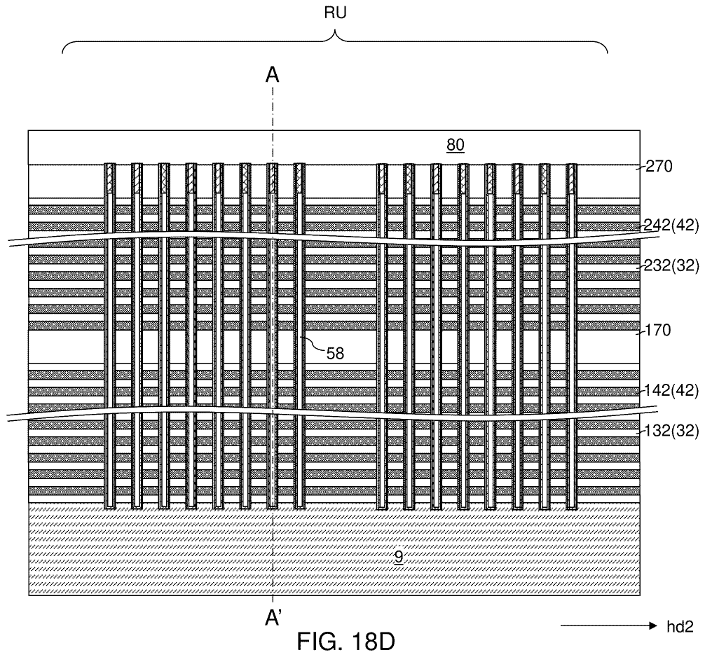

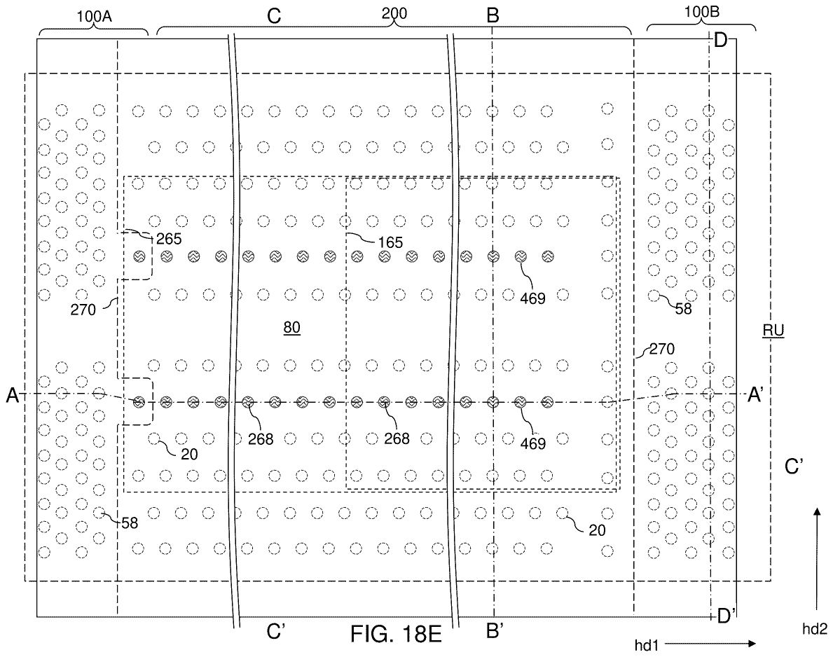

Referring to FIGS. 18A-18E, a contact-level dielectric layer 80 can be deposited over the second-tier insulating cap layer 270. The contact-level dielectric layer 80 comprises a dielectric material such as silicon oxide, and may have a thickness in a range from 100 nm to 800 nm, although lesser and greater thicknesses may also be employed.

A photoresist layer (not shown) can be applied over the contact-level dielectric layer 80, and can be lithographically patterned to form openings over the areas of the sacrificial contact opening fill structures (268, 168). An anisotropic etch process can be performed to form connection cavities 469 over the sacrificial second-tier contact opening fill structures 268. The photoresist layer may be subsequently removed, for example, by ashing.

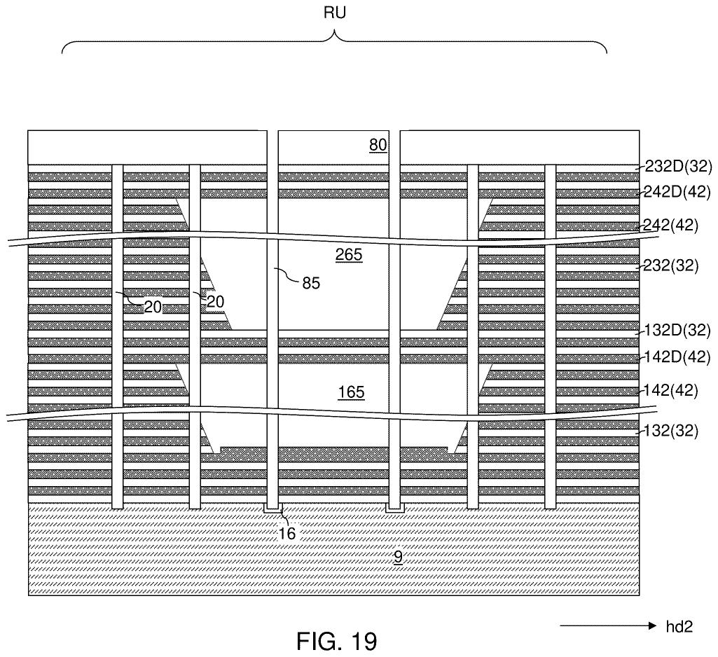

Referring to FIG. 19, the sacrificial fill materials of the sacrificial second-tier contact opening fill structures 268 and the sacrificial first-tier contact opening fill structures 168 can be removed selectively to the materials of retro-stepped dielectric material portions (165, 265), the insulating layers 32, the sacrificial material layers 42, and the support pillar structures (not shown). Contact via cavities 85 are formed in the volumes from which the materials of the sacrificial second-tier contact opening fill structures 268 and the sacrificial first-tier contact opening fill structures 168 are removed. Each contact via cavity 85 vertically extends from the horizontal plane including the planar top surfaces of the third-tier retro-stepped dielectric material portion 365 to the substrate 9. Each contact via cavity 85 may vertically extend through a respective set of at least one insulating layer 32 and a respective set of at least one sacrificial material layer 42 of an alternating stack of insulating layers 32 and sacrificial material layers 42. Each contact via cavity 85 vertically extends through a thickened portion of the topmost sacrificial material layer within the respective set of at least one sacrificial material layer 42.

In summary, each contact via cavities 85 can be formed through a respective subset of the retro-stepped dielectric material portions (165, 265). Each contact via cavity 85 may be formed through a locally thickened portion of a respective sacrificial material layer 42. Each contact via cavity 85 vertically extends through a thickened portions of only a single sacrificial material layer 42. In other words, each contact via cavity 85 vertically extends through no more than one thickened portion of the sacrificial material layers 42.

If the substrate 9 comprises a semiconductor material, such as silicon, an oxidation process may be performed to convert physically exposed surface portions of the substrate 9 underneath the contact via cavities 85 into semiconductor oxide spacer liners 16. The thickness of the semiconductor oxide spacer liners 16 may be in a range from 3 nm to 8 nm, although lesser and greater thicknesses may also be employed. In one embodiment, collateral oxidation of the physically exposed surfaces of the sacrificial material layers 42 may be minimized by reducing the thickness of the semiconductor oxide spacer liners 16.

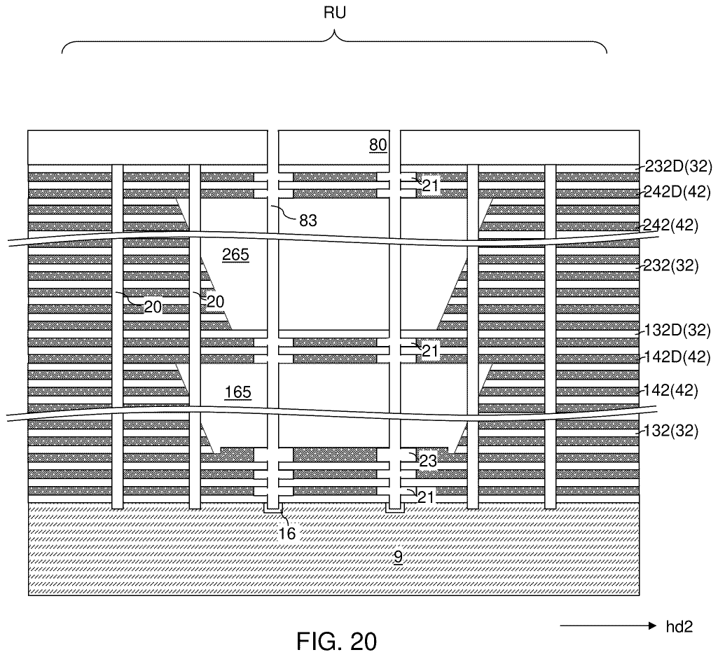

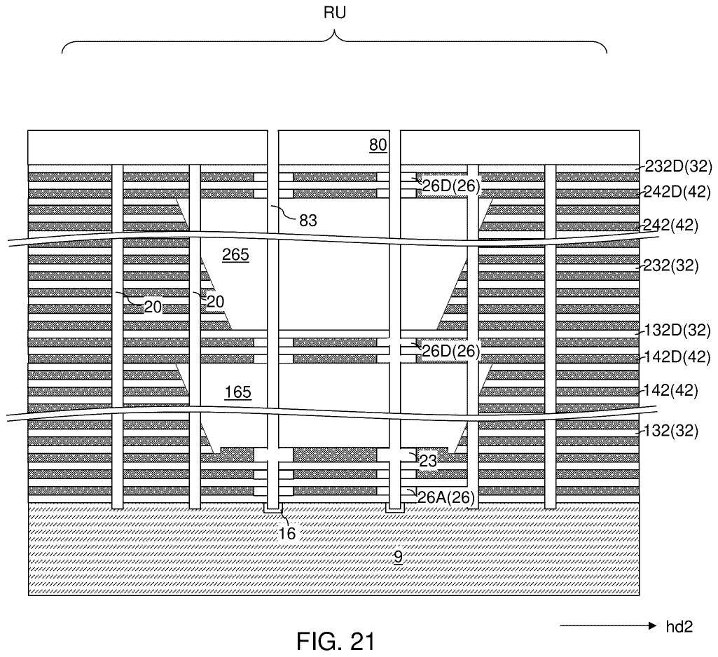

Referring to FIG. 20, a first isotropic etch process can be performed to isotropically etch proximal portions of the sacrificial material layers 42 around each contact via cavity 85 selective to the insulating layers 32 and the retro-stepped dielectric material portions (165, 265). For example, if the sacrificial material layers 42 comprise silicon nitride and if the retro-stepped dielectric material portions (165, 265) comprises silicon oxide, the first isotropic etch process may comprise a wet etch process employing hot phosphoric acid which etches silicon nitride selective to silicon oxide materials. The duration of the first isotropic etch process can be selected such that the lateral recess distance of the first isotropic recess etch process is in a range from 100 % to 1,000 %, such as from 200 % to 500 %, of the thickness of unthickened portions of the sacrificial material layers 42. For each contact via cavity 85 that vertically extends through at least one unthickened portion of the sacrificial material layers 42, at least one first annular recess region 21 may be formed in volumes from which material portions of sacrificial material layers 42 are removed selectively to the insulating layers 32. For each contact via cavity 85, a second annular recess region 23 can be formed by isotropically etching a proximal region of a thickened portion of a respective sacrificial material layer 23 selective to the insulating layers 32. Each contact via cavity 85 is laterally expanded at one or more levels of the sacrificial material layers 42 through formation of the annular recess regions (21, 23), and is converted into a respective laterally-expanded contact via cavity 83. Generally, the annular recess regions (21, 23) can be formed by laterally recessing proximal portions of the active sacrificial material layers 42 and the at least one dummy sacrificial material layer (142D and/or 242D) that are proximal to the contact via cavities 85.

Referring to FIG. 21, a recess-fill dielectric material layer (not shown) can be formed by conformally depositing a recess-fill dielectric material, such as silicon oxide, in the first annular recess regions 21 and the second annular recess regions 23, and over sidewalls of the laterally-expanded contact via cavities 83 (i.e., contact via cavities 85 as laterally expanded by the first isotropic etch process). The thickness of the recess-fill dielectric material layer can be greater than one half of the thickness of the unthickened portions of the sacrificial material layers 42, and can be less than one half of the thickness of the thickened portions of the sacrificial material layers 42. Thus, each first annular recess region 21 is completely filled with the recess-fill dielectric material layer, while each second annular recess region 23 is only partly filled by the recess-fill dielectric material layer.

A second isotropic etch process can be performed to isotropically etch the material of the recess-fill dielectric material layer. For example, the second isotropic etch process may comprise a wet etch process employing dilute hydrofluoric acid, such as 100:1 dilute hydrofluoric acid. According to an aspect of the present disclosure, the duration of the second isotropic etch process can be selected to ensure removal of the entirety of each portion of the recess-fill dielectric material layer that fills the second annular recess regions 23 of the laterally-expanded contact via cavities 83. In one embodiment, the duration of the second isotropic etch process can be selected such that the recess etch distance of the second isotropic etch process for the material of the recess-fill dielectric material layer is in a range from 105 % to 150 %, such as from 100 % to 130 %, of the thickness of the recess-fill dielectric material layer.

The second isotropic etch process removes the recess-fill dielectric material layer from an entire volume of each second annular recess region 23. Thus, the recess-fill dielectric material layer is entirely removed from each second annular recess region 23. Each remaining portion of the recess-fill dielectric material layer that fills a respective one of the first annular recess regions 21 comprises an annular dielectric spacer 26. Thus, each first annular recess region 21 is filled within a respective annular dielectric spacer 26. For each contact via cavity 85 that vertically extends through three or more sacrificial material layers 42, a vertical stack of annular dielectric spacers 26 can be formed around the contact via cavity 85. In other words, for each laterally-expanded contact via cavity 83 that vertically extends through three or more sacrificial material layers 42, a vertical stack of annular dielectric spacers 26 can fill two or more first annular recess regions 21. For each contact via cavity 85 that vertically extends through a plurality of sacrificial material layers 42, each unthickened annular portion of the plurality of sacrificial material layers 42 around the contact via cavity 85 can be replaced with a respective annular dielectric spacer 26.

Thus, the annular dielectric spacers 26 are formed within a subset of the annular recess regions (21, 23), i.e., within the first annular recess regions 21. The annular dielectric spacers 26 comprise active-level annular dielectric spacers 26A that are formed at levels of, and are in direct contact with, the active sacrificial material layers (142, 242), and dummy-level annular dielectric spacers 26D that are formed at levels of, and are in direct contact with, the dummy sacrificial material layers (142D, 242D). Thus, the annular dielectric spacers (26, 26D) are formed within a subset of the annular recess regions (21, 23), i.e., within the first annular recess regions 21.

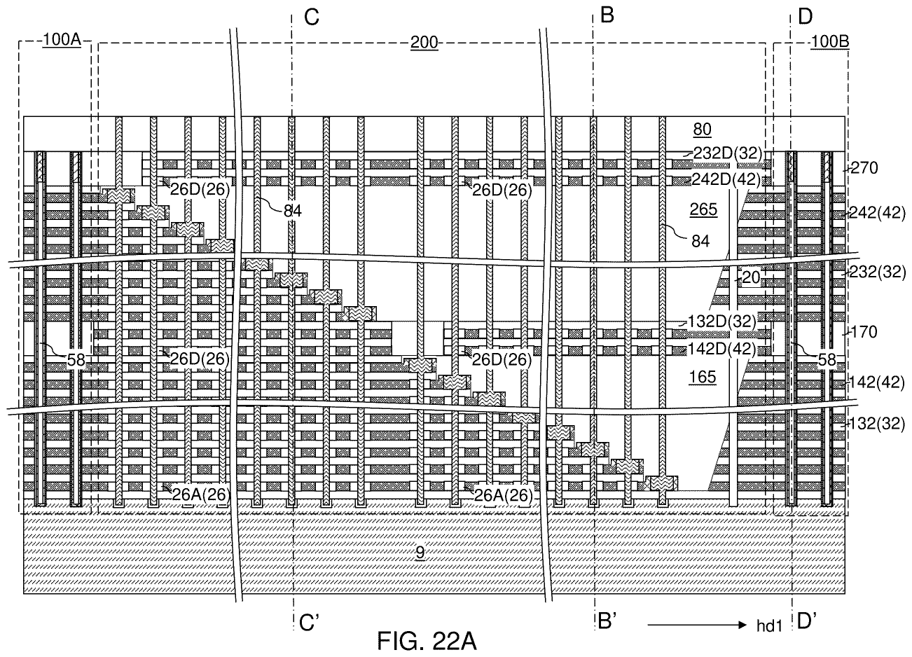

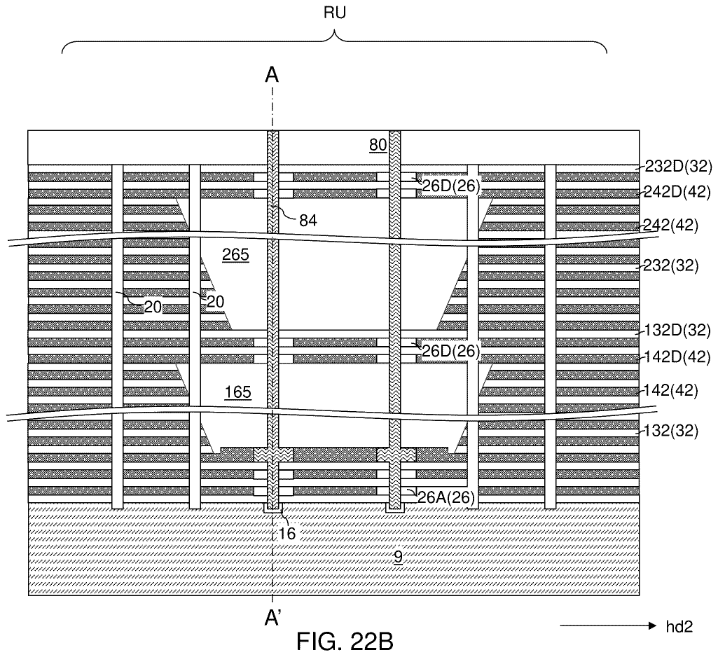

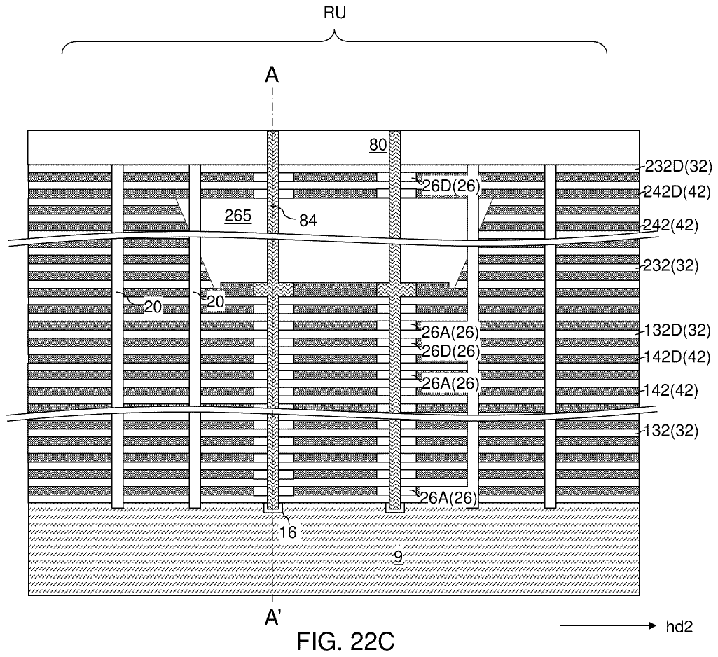

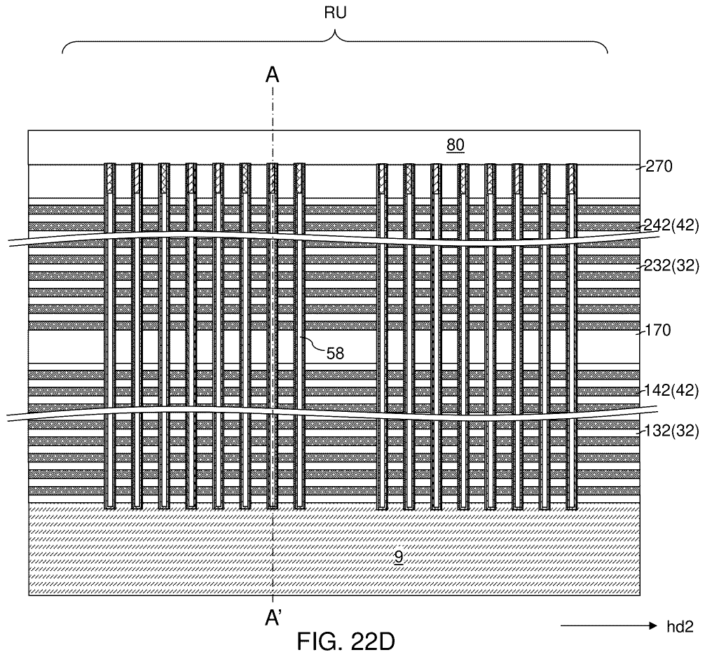

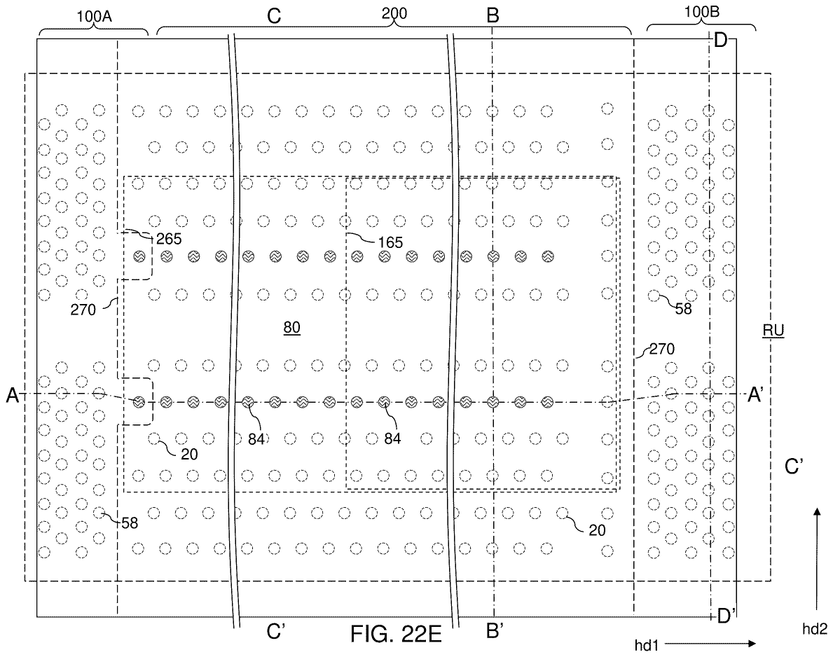

Referring to FIGS. 22A-22E, a sacrificial fill material can be deposited within volumes of the laterally-expanded contact via cavities 83 that are not filled with the annular dielectric spacers 26. The sacrificial fill material may comprise any material that is different from the materials of the insulating layers 32 and the sacrificial material layers 42. For example, the sacrificial fill material may comprise a semiconductor material (e.g., amorphous silicon), organosilicate glass, a polymer material, a photoresist material, or any other sacrificial material that may be subsequently removed selective to materials of the insulating layers 32, the retro-stepped dielectric material portions (165, 265), and electrically conductive layers to be subsequently formed. Excess portions of the sacrificial fill material may be removed from above the horizontal plane including the top surface of the contact-level dielectric layer 80. Each remaining portion of the sacrificial fill material that fills a respective one of the laterally-expanded contact via cavities 83 constitutes a sacrificial through-via structure 84.

Each sacrificial through-via structure 84 is in direct contact with a cylindrical sidewall of a thickened portion of a respective one of the sacrificial material layers 42, and may optionally vertically extend through one or more additional sacrificial material layers 42. Each sacrificial through-via structure 84 is in contact with at least one of the first-tier retro-stepped dielectric material portion 165, the second-tier retro-stepped dielectric material portion 265, and the third-tier retro-stepped dielectric material portion 365. Each sacrificial through-via structure 84 that vertically extends through at least one opening through at least one unthickened portion of the sacrificial material layers 42 is laterally surrounded by, and is contacted by, one or more of the annular dielectric spacers 26. A subset of the sacrificial through-via structures 84 can be laterally surrounded by a respective set of at least one annular dielectric spacer 26. In one embodiment, a subset of the sacrificial through-via structures 84 can be laterally surrounded by a respective vertical stack of annular dielectric spacers 26.

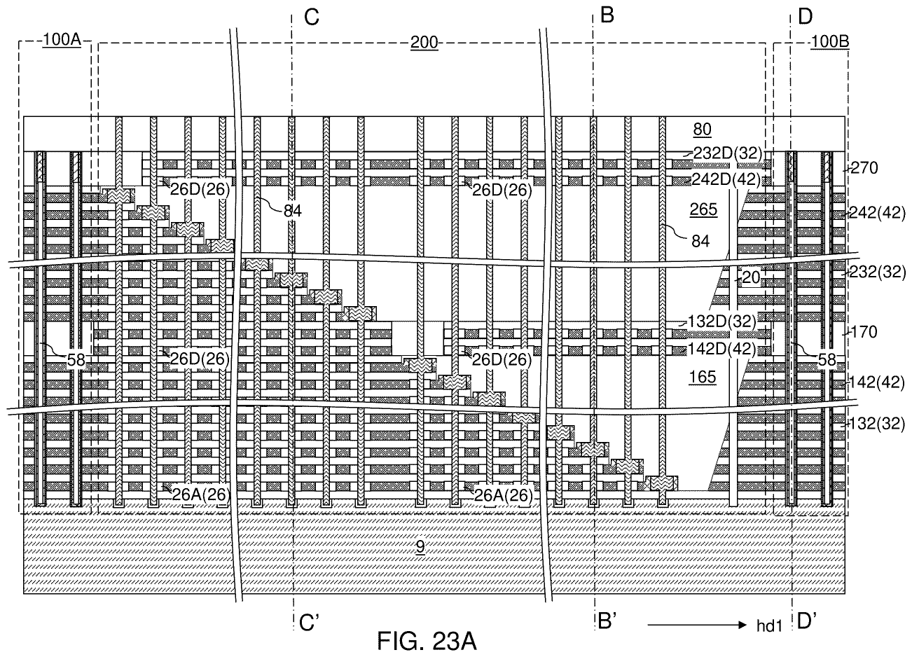

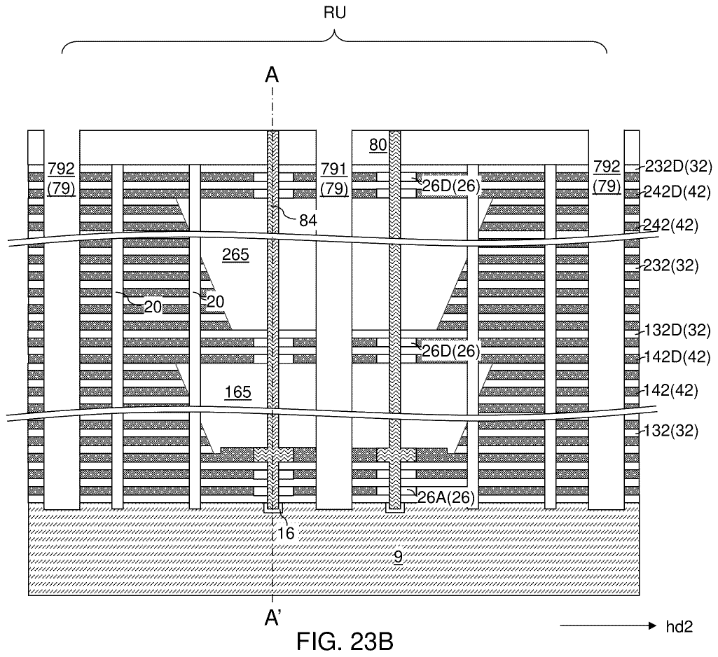

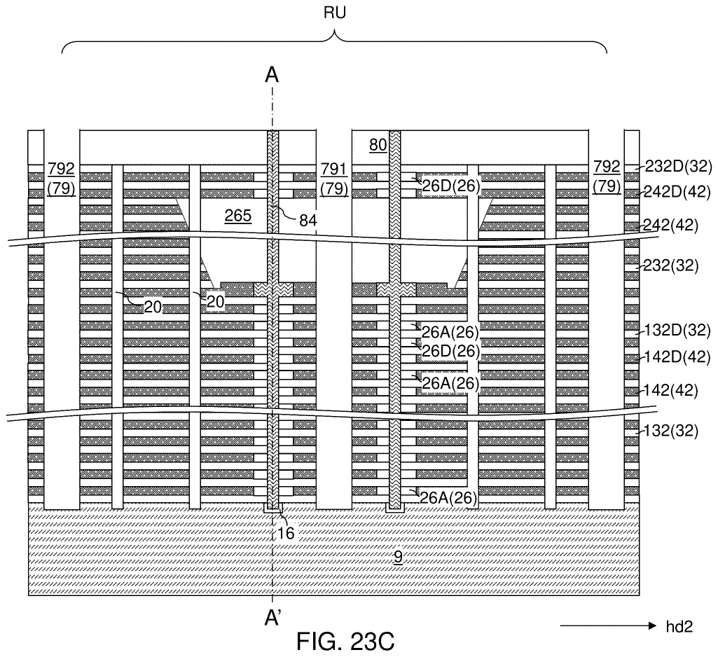

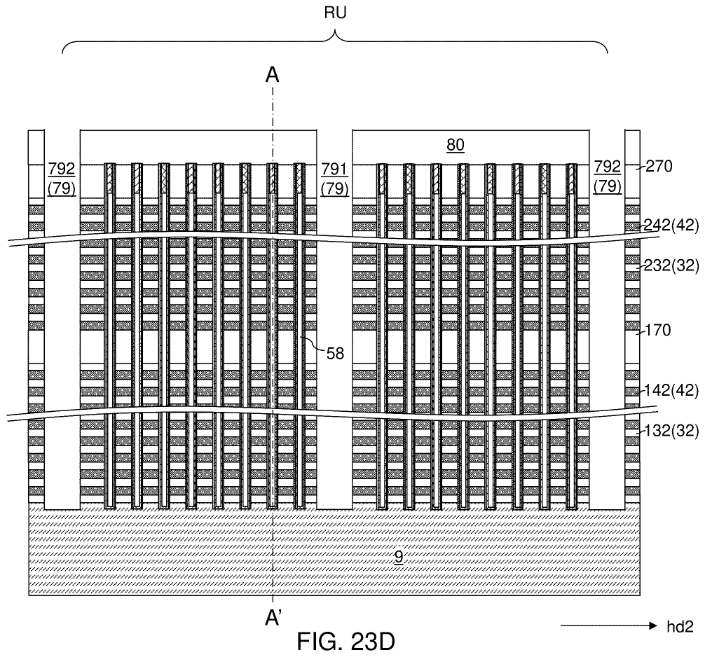

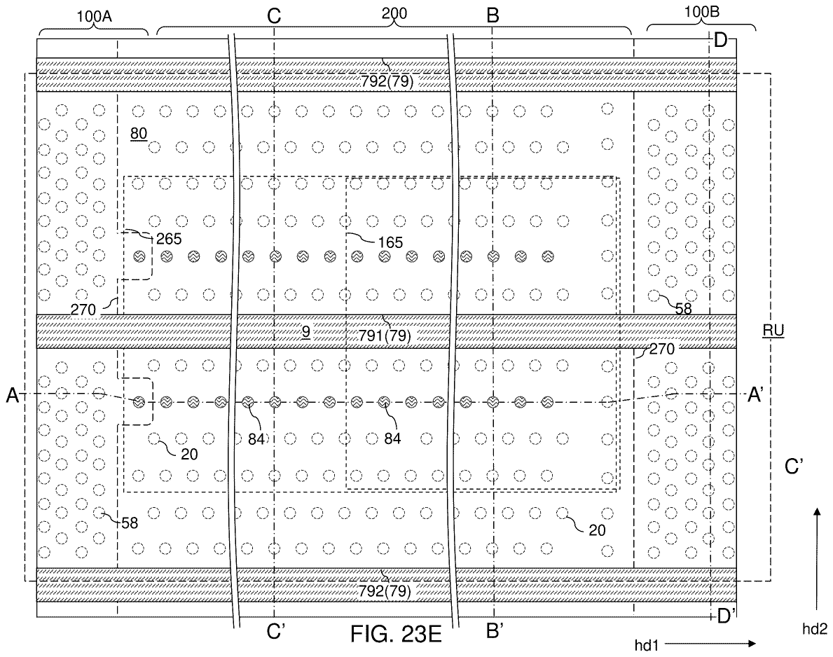

Referring to FIGS. 23A-23E, a patterning film (not shown) can be anisotropically deposited over the contact-level dielectric layer 80. The patterning film comprises a material that may be subsequently employed as an etch mask material. For example, the patterning film may comprise amorphous carbon or diamond-like carbon. The patterning film can be deposited with a highly directional deposition method, such as plasma-enhanced chemical vapor deposition. The patterning film may be subsequently patterned, for example, by applying and lithographically patterning a photoresist layer (not shown). In one embodiment, elongated openings laterally extending along the first horizontal direction hd1 can be formed in the photoresist layer. In one embodiment, the elongated openings may comprise rectangular openings having a uniform width along the second horizontal direction hd2.

In one embodiment, the elongated openings may comprise a one-dimensional array of elongated openings laterally extending along the first horizontal direction hd1, having a uniform width along the second horizontal direction hd2, and having a uniform pitch along the second horizontal direction hd2 that is one half of the periodicity of the repetition unit RU along the second horizontal direction hd2. In one embodiment, each elongated opening may have a uniform width throughout, and may laterally extend through the entirety of the first memory array region 100A, the second memory array region 100B, and the contact region 200. The photoresist layer may be removed after patterning the patterning film, or may be collaterally removed during a subsequent anisotropic etch process that transfers the pattern in the patterning film through the alternating stacks (32, 42) and the retro-stepped dielectric material portions (165, 265).

An anisotropic etch process can be performed to transfer the pattern of the elongated openings in the patterning film through the contact-level dielectric layer 80, the alternating stacks (32, 42), and the retro-stepped dielectric material portions (165, 265). Lateral isolation trenches 79 can be formed in the volumes from which the materials of the contact-level dielectric layer 80, the alternating stacks (32, 42), and the retro-stepped dielectric material portions (165, 265) are removed. In one embodiment, the lateral isolation trenches 79 may comprise first-type lateral isolation trenches 791 that divide the second-tier retro-stepped dielectric material portions 265 and the first-tier retro-stepped dielectric material portions 165. Further, the lateral isolation trenches 79 may comprise second-type lateral isolation trenches 792 that do not intersect any of the retro-stepped dielectric material portions (165, 265) (which extend through bridge regions of the alternating stacks (32, 42) located laterally between the retro-stepped dielectric material portions (165, 265) in the contact region 200). The patterning film can be subsequently removed, for example, by ashing or selective etching. The lateral isolation trenches 79 are laterally spaced from each of the contact via cavities 85. Optionally, an oxidation process may be performed to convert physically exposed surface portions of the substrate 9 into semiconductor oxide trench liners (not illustrated).

The lateral isolation trenches 79 divide each alternating stack (32, 42) of insulating layers 32 and sacrificial material layers 42 into a respective plurality of alternating stacks (32, 42) of insulating layers 32 and sacrificial material layers 42. For the purpose of distinguishing layers in the first exemplary structure prior to formation of the lateral isolation trenches 79 from layers in the first exemplary structure after formation of the lateral isolation trenches 79, each insulating layer 32 prior to formation of the lateral isolation trenches 79 may be referred to as a continuous insulating layer 32. The continuous insulating layers 32 in the first exemplary structure prior to formation of the lateral isolation trenches 79 may comprise first-tier continuous insulating layers 132 and second-tier continuous insulating layers 232. Likewise, each sacrificial material layer 42 prior to formation of the lateral isolation trenches 79 may be referred to as a continuous sacrificial material layer 42. The continuous sacrificial material layers 42 in the first exemplary structure prior to formation of the lateral isolation trenches 79 may comprise first-tier continuous sacrificial material layers 142 and second-tier continuous sacrificial material layers 242.

Thus, the first-tier alternating stack of first-tier continuous insulating layers 132 and first-tier active sacrificial material layers 142 is divided into a plurality of alternating stacks of first-tier insulating layers 132 and first-tier active sacrificial material layers 142. The second-tier alternating stack of second-tier continuous insulating layers 232 and second-tier active sacrificial material layers 242 is divided into a plurality of alternating stacks of second-tier insulating layers 232 and second-tier active sacrificial material layers 242.

A vertical stack of a first-tier alternating stack (132, 142), a combination of a first-tier insulating cap layer 170 and at least one pair of a first-tier dummy insulating layer 132D and a first-tier dummy sacrificial material layer 142D, a second-tier alternating stack (232, 242), and a combination of a second-tier insulating cap layer 270 and at least one pair of a second-tier dummy insulating layer 232D and a second-tier dummy sacrificial material layer 242D is formed between each neighboring pair of lateral isolation trenches 79. Within each vertical stack, a combination of a first-tier alternating stack (132, 142), a first-tier insulating cap layer 170, a second-tier alternating stack (232, 242), and a second-tier insulating cap layer 270 may be referred to as an alternating stack of insulating layers 32 and sacrificial material layers 42, in which the distinction among the different tier structures and between the active sacrificial material layers (142, 242) and the dummy sacrificial material layers (142D, 242D) is ignored. Each first-tier retro-stepped dielectric material portion 165 may comprise a respective lengthwise sidewall that is parallel to the first horizontal direction hd1 and is exposed to a respective first-type lateral isolation trench 791. Each second-tier retro-stepped dielectric material portion 265 may comprise a respective lengthwise sidewall that is parallel to the first horizontal direction hd1 and is exposed to a respective second-type lateral isolation trench 792.

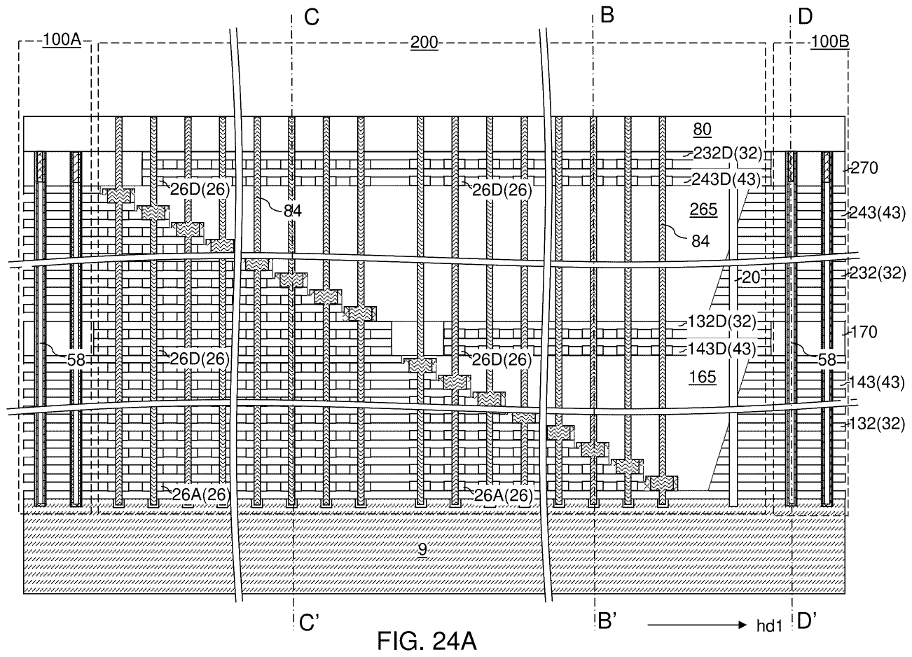

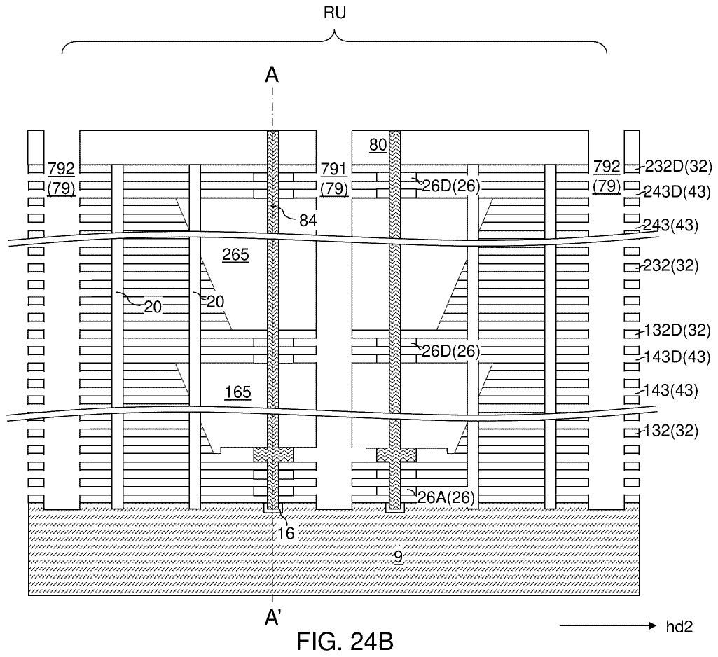

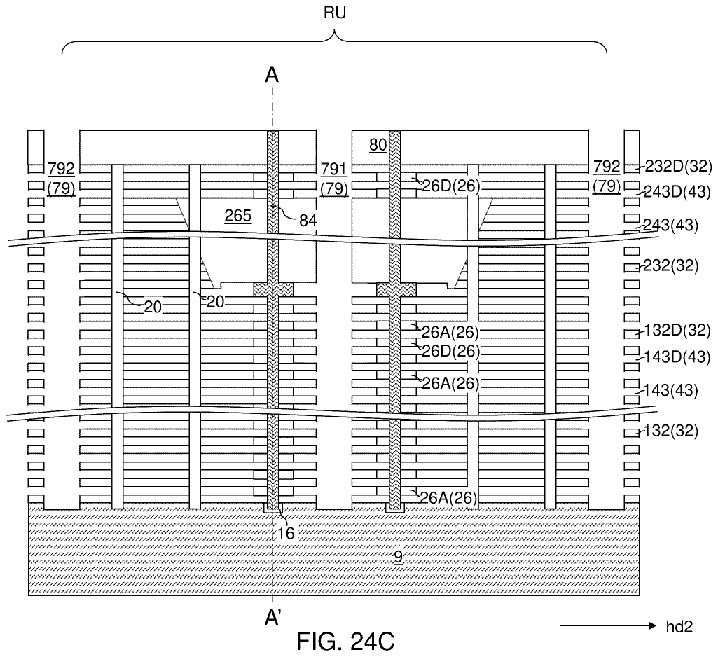

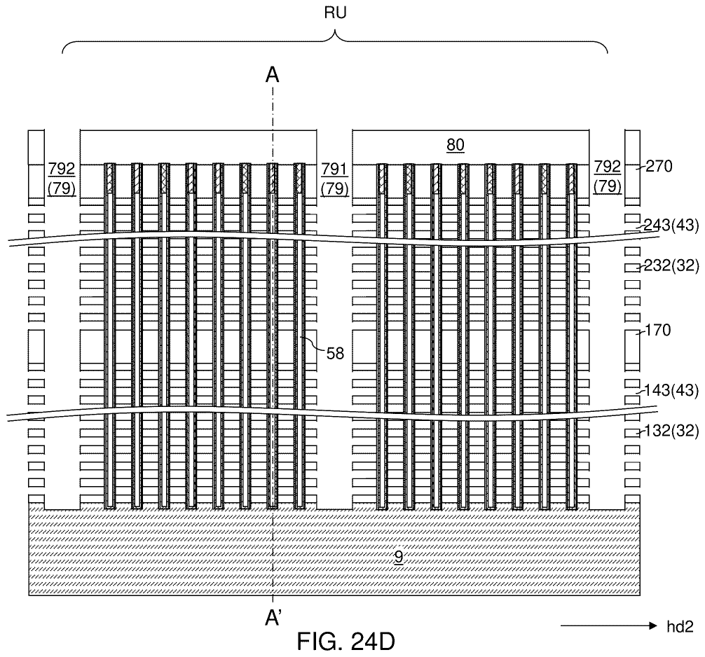

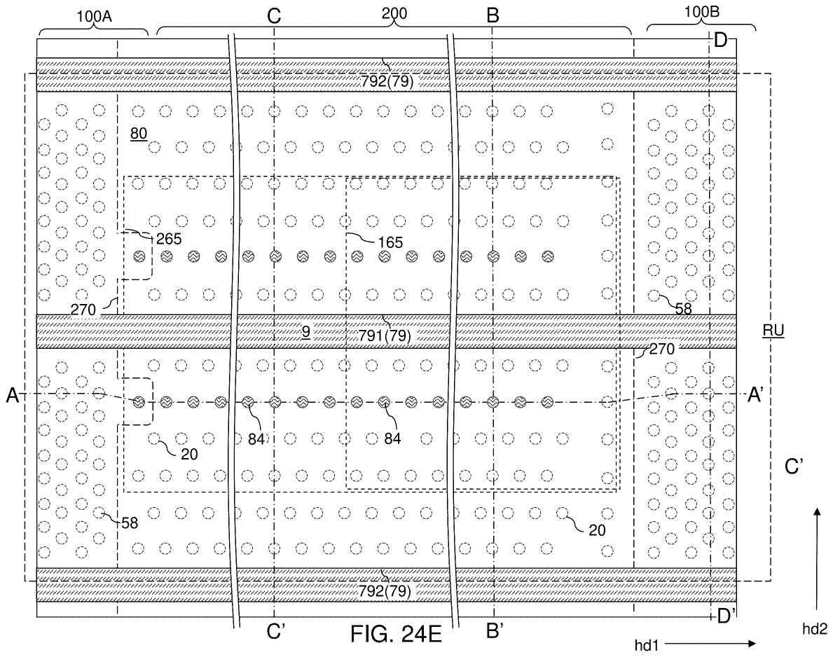

Referring to FIGS. 24A-24E, laterally-extending cavities 43 can be formed by selective removal of the sacrificial material layers 42. A selective etch process can be performed to remove the sacrificial material layers 42 selectively to the insulating layers 32 employing the contact via cavities 85 and the lateral isolation trenches 79 as conduits for transporting an isotropic etchant of the selective etch process. Specifically, the sacrificial material layers 42 may be isotropically etched selective to the insulating layers 32, the annular dielectric spacers 26, and the retro-stepped dielectric material portions (165, 265) by supplying an isotropic etchant into the lateral isolation trenches 79 and into the contact via cavities 85. In one embodiment, an etchant that selectively etches the materials of the sacrificial material layers 42 with respect to the materials of the insulating layers 32, the annular dielectric spacers 26, the retro-stepped dielectric material portions (165, 265), and the material of the outermost layer of the memory films 50 may be introduced into the lateral isolation trenches, for example, using an isotropic etch process.

The isotropic etch process may be a wet etch process using a wet etch solution, or may be a gas phase (dry) etch process in which the etchant is introduced in a vapor phase into the lateral isolation trench. For example, if the sacrificial material layers 42 comprise silicon nitride, and if the insulating layers 32, the annular dielectric spacers 26, the retro-stepped dielectric material portions (165, 265), and the outermost layer of the memory films 50 comprise silicon oxide materials, the etch process may comprise a hot phosphoric acid etch process, which etches silicon nitride selective to silicon oxide, silicon, and various other materials used in the art.

The laterally-extending cavities 43 are formed in volumes from which the sacrificial material layers 42 are removed. The laterally-extending cavities 43 include first-tier active-level laterally-extending cavities 143 that are formed in volumes from which the first-tier active sacrificial material layers 142 are removed, second-tier active-level laterally-extending cavities 243 that are formed in volumes from which the second-tier active sacrificial material layers 242 are removed, first-tier dummy-level laterally-extending cavities 143D that are formed in volumes from which the first-tier dummy sacrificial material layers 142D are removed, and second-tier dummy-level laterally-extending cavities 243D that are formed in volumes from which the second-tier dummy sacrificial material layers 242D are removed.

Each of the laterally-extending cavities 43 may be a laterally extending cavity having a greater lateral dimension that is greater than a vertical extent. In other words, the lateral dimension of each of the laterally-extending cavities 43 may be greater than the height of the respective laterally-extending cavity. A plurality of laterally-extending cavities 43 may be formed in the volumes from which the material of the sacrificial material layers 42 is removed. Each of the laterally-extending cavities 43 may extend substantially parallel to the top surface of the substrate 9. A laterally-extending cavity 43 may be vertically bounded by a top surface of an underlying insulating layer 32 and a bottom surface of an overlying insulating layer 32.

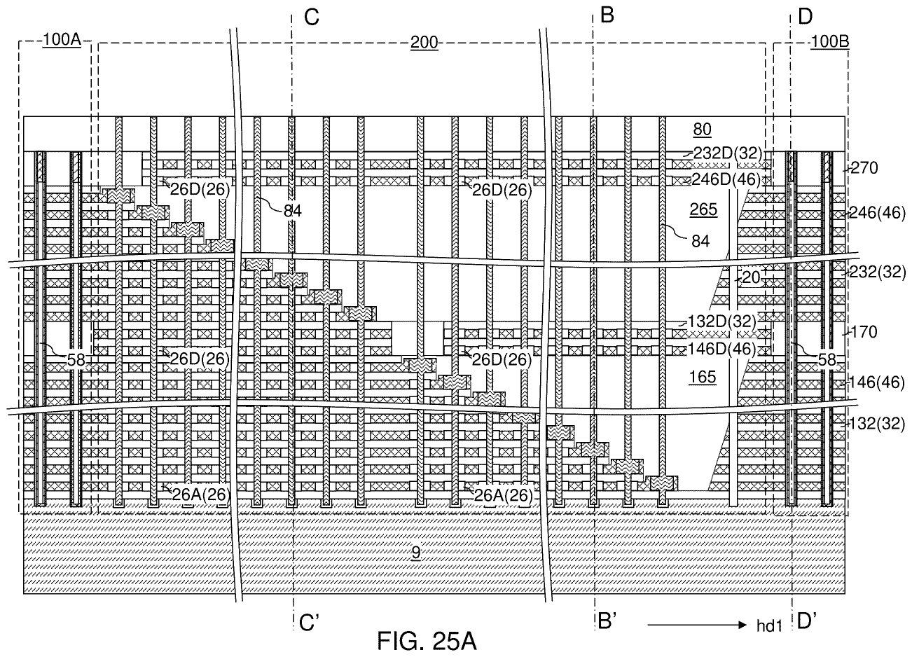

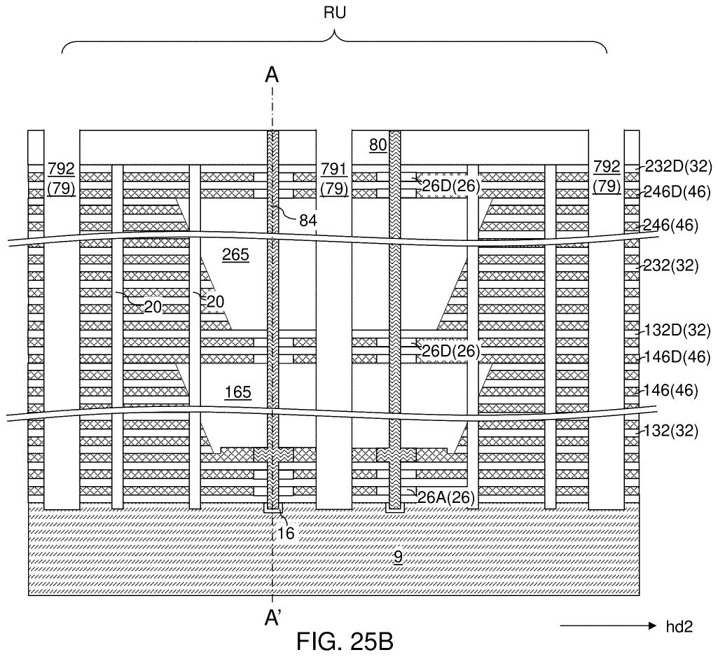

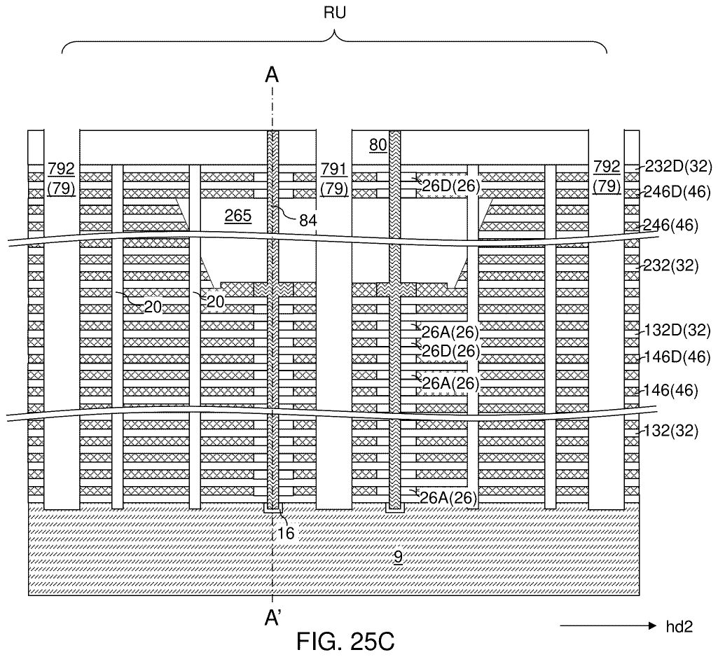

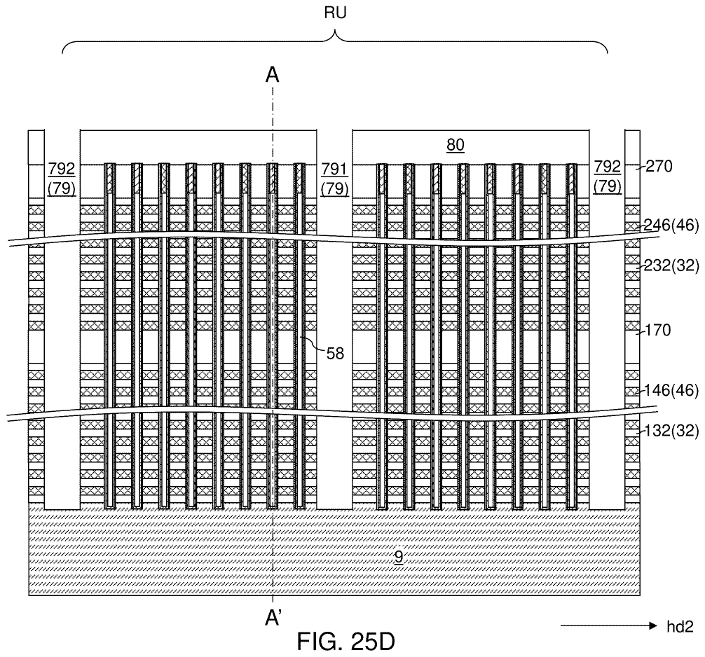

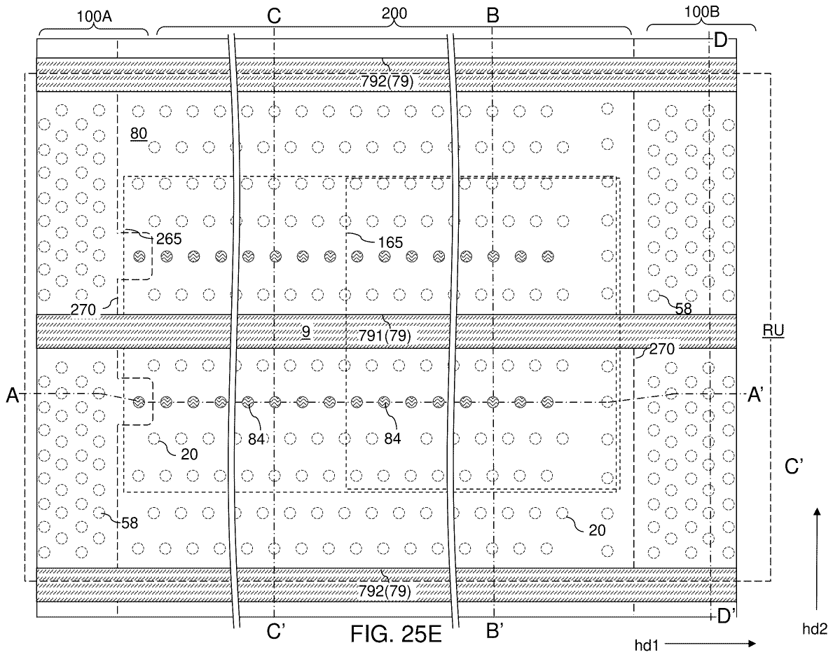

Referring to FIGS. 25A-24E, an outer blocking dielectric layer (not expressly shown) may be conformally deposited in peripheral portions of the laterally-extending cavities 43, the contact via cavities 85, and the lateral isolation trenches 79. The outer blocking dielectric layer includes a dielectric material, such as a dielectric metal oxide (e.g., aluminum oxide), silicon oxide, or a combination thereof. The outer blocking dielectric layer may be formed as a continuous material layer having a uniform thickness throughout by a conformal deposition process such as an atomic layer deposition process and/or a chemical vapor deposition process. The thickness of the outer blocking dielectric layer may be in a range from 2 nm to 10 nm, such as from 3 nm to 8 nm, although lesser and greater thicknesses may also be employed.

A continuous electrically conductive material layer (not illustrated) may be deposited over the outer blocking dielectric layer to fill remaining volumes of the laterally-extending cavities 43, peripheral portions of the lateral isolation trenches 79, and peripheral portions of the contact via cavities 85. The contact via cavities 85 and the lateral isolation trenches 79 are used conduits for transporting the reactants (e.g., CVD or ALD reactants) to the volumes of the laterally-extending cavities 43. In one embodiment, the continuous electrically conductive material layer may comprise a continuous metallic barrier liner layer (not expressly shown) and a continuous metal fill material layer (not expressly shown).

Specifically, a continuous metallic barrier liner layer may be conformally deposited on the physically exposed surfaces of the outer blocking dielectric layer in peripheral portions of the laterally-extending cavities 43 and the lateral isolation trenches 79. The continuous metallic barrier liner layer comprises a metallic diffusion barrier material. For example, the continuous metallic barrier liner layer may comprise and/or may consist essentially of a conductive metal nitride material, such as TiN, TaN, WN, and/or MoN. The continuous metallic barrier liner layer may be formed as a continuous material layer having a uniform thickness throughout by a conformal deposition process such as an atomic layer deposition process and/or a chemical vapor deposition process. The thickness of the continuous metallic barrier liner layer may be in a range from 1.5 nm to 8 nm, such as from 3 nm to 6 nm, although lesser and greater thicknesses may also be employed. In one embodiment, the continuous metallic barrier liner layer extends continuously over the entirety of the outer blocking dielectric layer as a single continuous material layer.

The continuous metal fill material layer may be conformally deposited on the physically exposed surfaces of the continuous metallic barrier liner layer in remaining unfilled volumes of the laterally-extending cavities 43 and in peripheral regions of the lateral isolation trenches 79. The continuous metal fill material layer comprises a metal fill material that provides high electrical conductivity. For example, the continuous metal fill material layer comprises and/or consists essentially of an elemental metal such as W, Co, Ru, Mo, Cu, or a combination thereof. The continuous metal fill material layer may be formed by a conformal deposition process, such as a chemical vapor deposition (CVD) process or an atomic layer deposition (ALD) process. The lateral isolation trenches 79 may be used as conduits for the reactant that deposits the continuous metal fill material layer. In one embodiment, the continuous metal fill material layer extends continuously over the entirety of the continuous metallic barrier liner layer as a single continuous material layer.

The combination of the outer blocking dielectric layer, the continuous metallic barrier liner layer, and the continuous metal fill material layer fill the entirety of the laterally-extending cavities 43, and fill peripheral portions of the lateral isolation trenches 79. Generally, at least one conformal deposition process can be performed after formation of the outer blocking dielectric layer to deposit at least one first electrically conductive material of the electrically conductive material layer in remaining volumes of the laterally-extending cavities 43, and in an elongated tubular regions of each lateral isolation trench 79. Each portion of the continuous electrically conductive material layer that replaces an unthickened portion of the sacrificial material layers 42 may have a first thickness, and each portion of the continuous electrically conductive material layer that replace a thickened portion of the sacrificial material layers 42 may have a second thickness which is greater than the first thickness.

A selective etch process can be performed to etch portions of the continuous electrically conductive material layer from inside the lateral isolation trenches 79. Each remaining portion of the combination of the continuous metallic barrier liner layer and the continuous metal fill material layer that fills a respective laterally-extending cavity 43 constitutes an electrically conductive layer 46. In summary, remaining portions of the active sacrificial material layers (142, 242) and the at least one dummy sacrificial material layer (142D and/or 242D) after formation of the lateral isolation trenches 79 may be replaced with electrically conductive layers 46. The electrically conductive layers 46 comprise active electrically conductive layers (146, 246) that replace the remaining portions of the active sacrificial material layers 42 and at least one dummy electrically conductive layer (146D or 246D) that replaces remaining portions of the at least one dummy sacrificial material layer (142D and/or 242D).

The electrically conductive layers 46 comprise first-tier electrically conductive layers 146 that are formed in the first-tier laterally-extending cavities 143, second-tier electrically conductive layers 246 that are formed in the second-tier laterally-extending cavities 243, first-tier dummy electrically conductive layers 146D that are formed in the first-tier dummy-level laterally-extending cavities 143D, and second-tier dummy electrically conductive layers 246D that are formed in the second-tier dummy-level laterally-extending cavities 243D. First-tier alternating stacks (132, 246, 132D, 146D) of first-tier insulating layers 132 and first-tier electrically conductive layers (146, 146D) are formed within the first-tier structure, and second-tier alternating stacks (132, 246, 232D, 246D) of second-tier insulating layers 232 and second-tier electrically conductive layers (246, 246D) are formed within the second-tier structure. The first-tier electrically conductive layers (146, 146D) comprise first-tier active electrically conductive layers 146 and first-tier dummy electrically conductive layers 146D. The second-tier electrically conductive layers (246, 246D) comprise second-tier active electrically conductive layers 246 and second-tier dummy electrically conductive layers 246D.

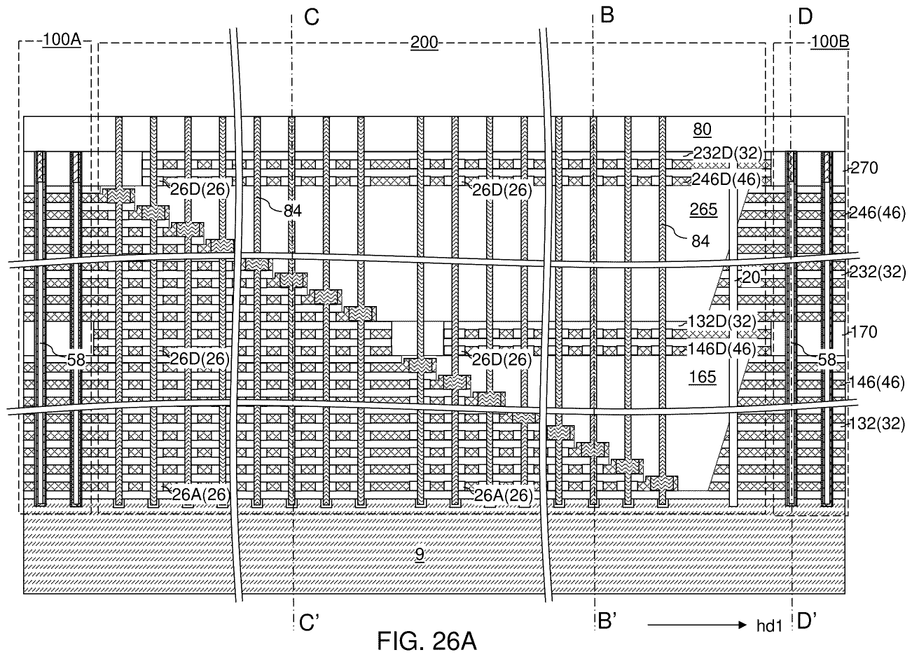

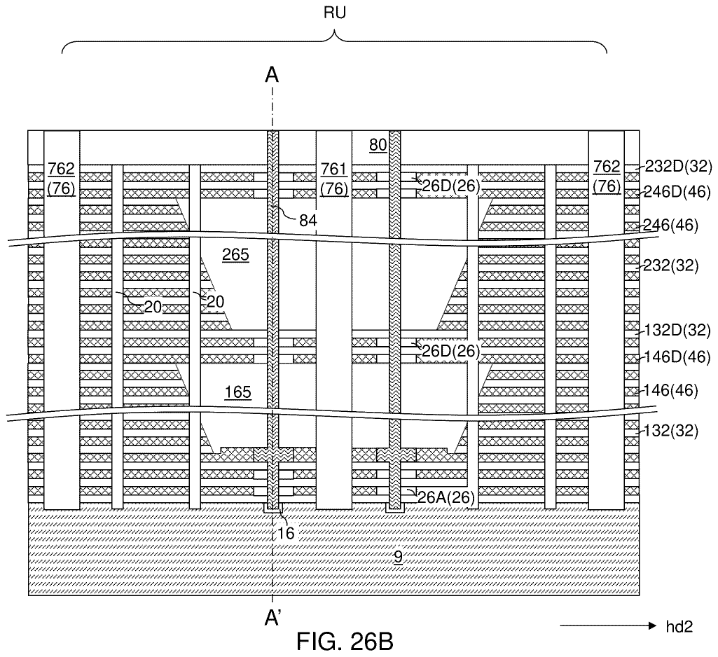

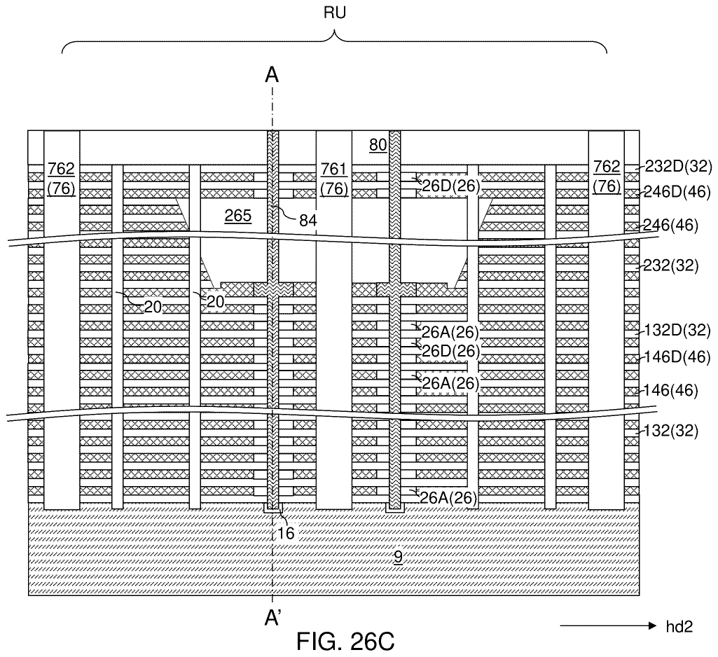

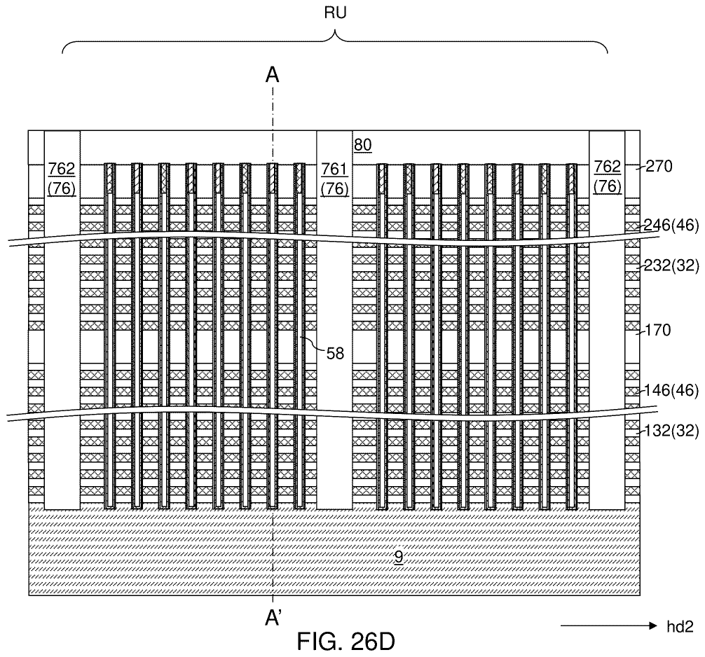

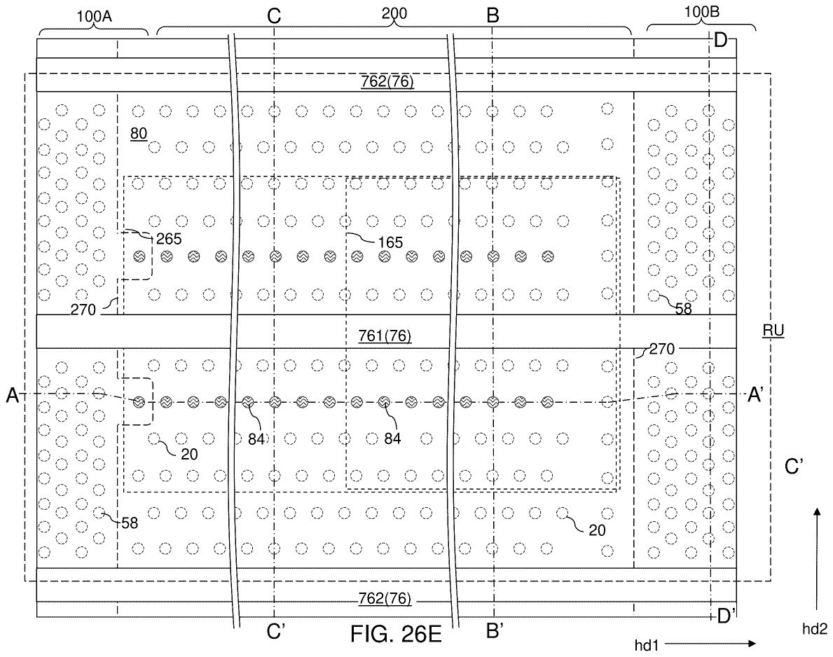

Referring to FIGS. 26A-26E, a dielectric fill material, such as undoped silicate glass or a doped silicate glass, can be deposited in the lateral isolation trenches 79 by a conformal deposition process. Excess portions of the dielectric fill material may be removed from above the horizontal plane including the top surface of the contact-level dielectric layer 80 by a planarization process, which may comprise a recess etch process and/or a chemical mechanical polishing process. Each remaining portion of the dielectric fill material that fills a respective one of the lateral isolation trenches 79 constitute a lateral isolation trench fill structure 76. The lateral isolation trench fill structures 76 may comprise first-type lateral isolation trench fill structures 761 that are formed in the first-type lateral isolation trenches 791 and second-type lateral isolation trench fill structures 762 that are formed in the second-type lateral isolation trenches 792.

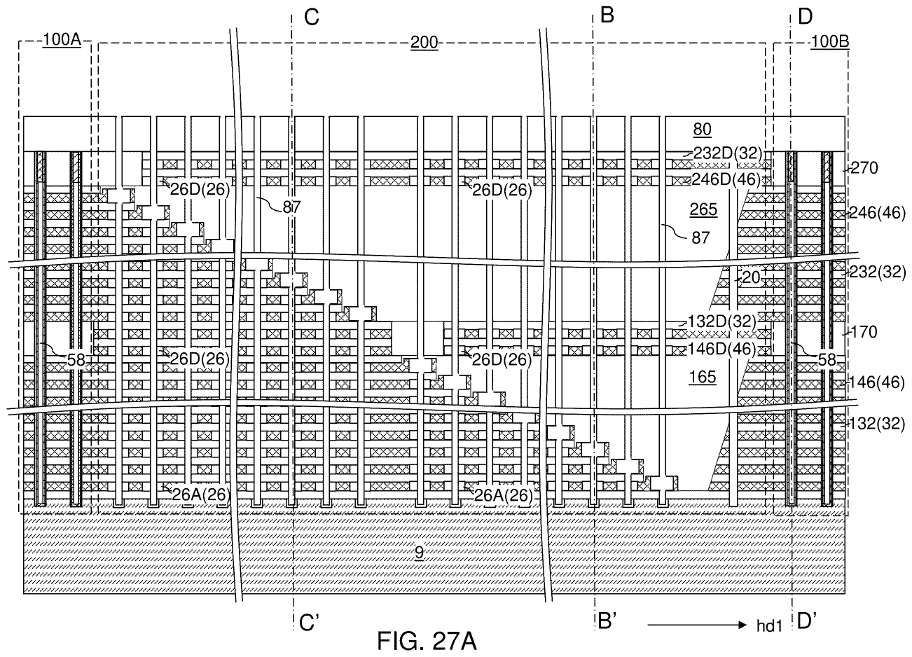

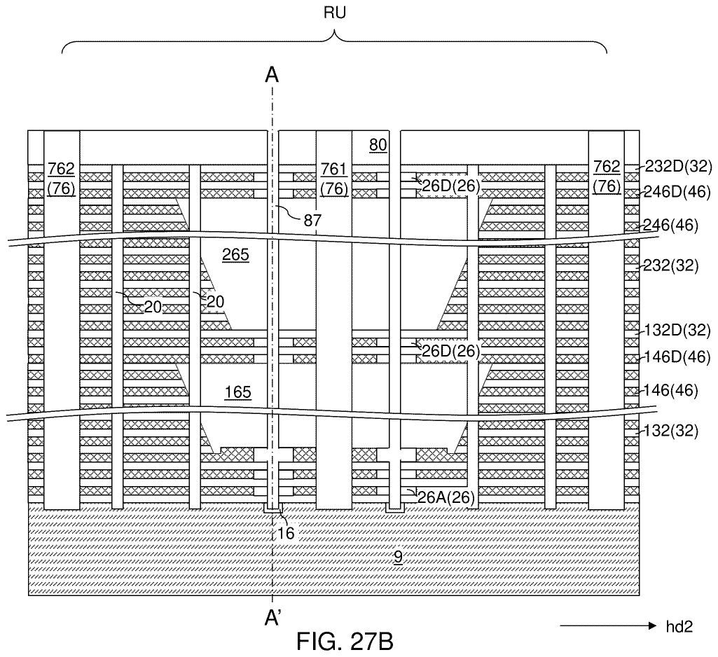

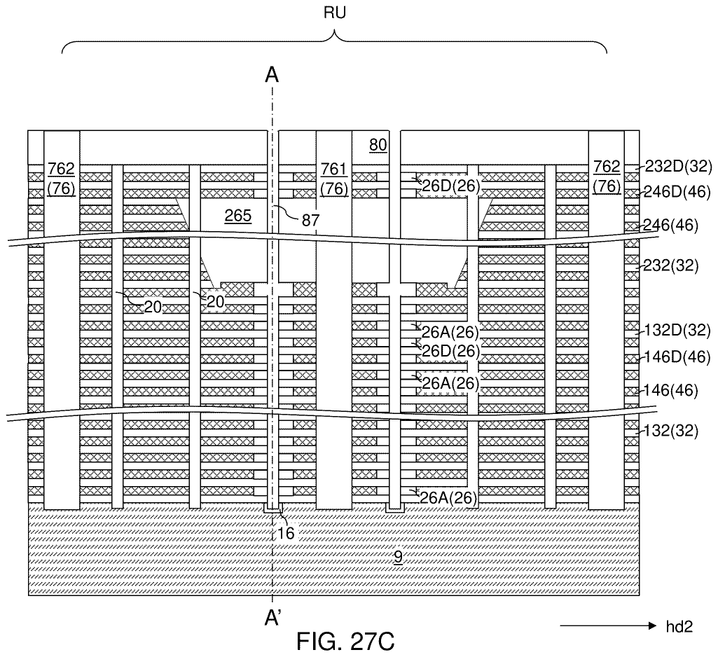

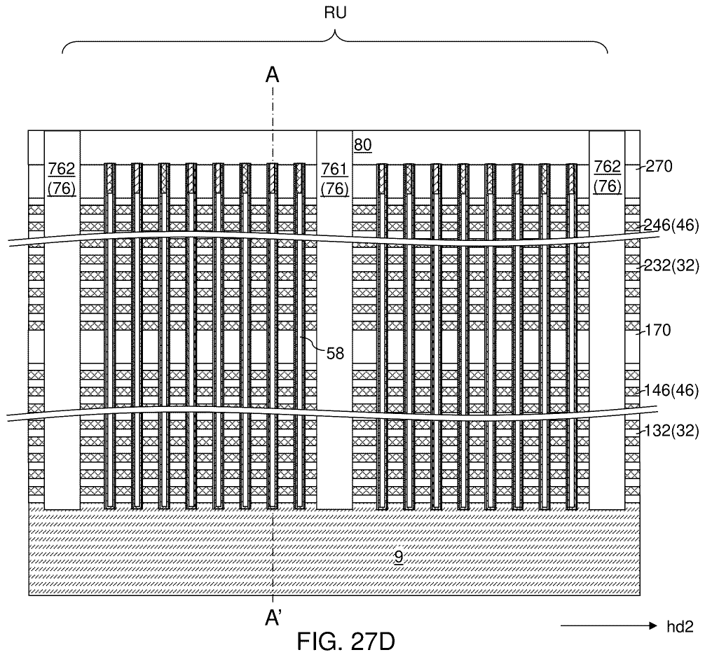

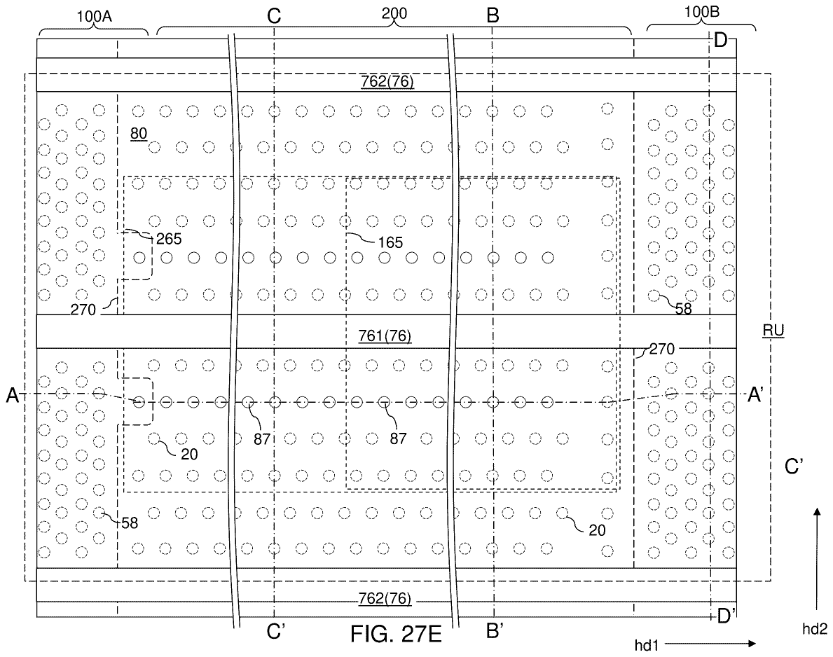

Referring to FIGS. 27A-27E, a selective etch process may be performed to remove sacrificial through-via structures 84 selective to the materials of the contact-level dielectric layer 80, the retro-stepped dielectric material portions (165, 265), the insulating layers 32, and the electrically conductive layers 46. Through-via cavities 87 can be formed in the volumes from which the sacrificial through-via structures 84 are removed. An isotropic etch process may be performed to remove any physically exposed portion of the outer blocking dielectric layers (not shown) from around the through-via cavities 87. Each through-via cavity 87 is a contact via cavity to which a surface of a respective electrically conductive layer 46 is physically exposed. In one embodiment, each through-via cavity 87 comprises a respective annular recess region to which a cylindrical sidewall of a respective electrically conductive layer 46 is physically exposed.

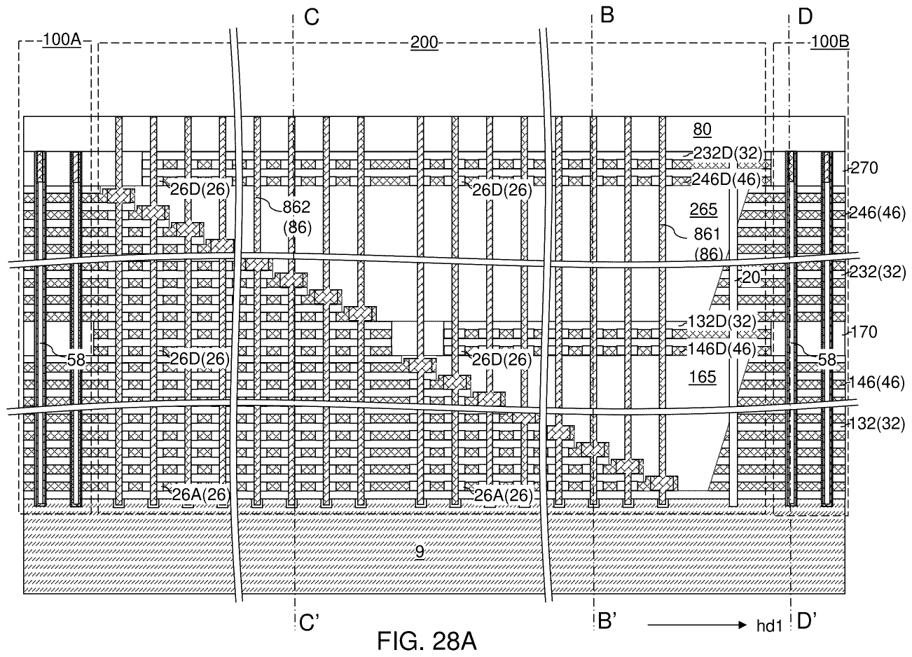

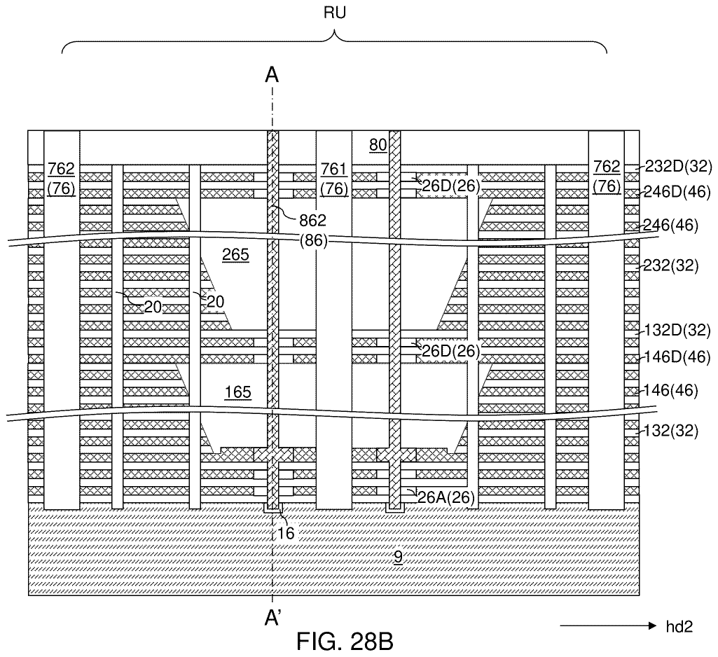

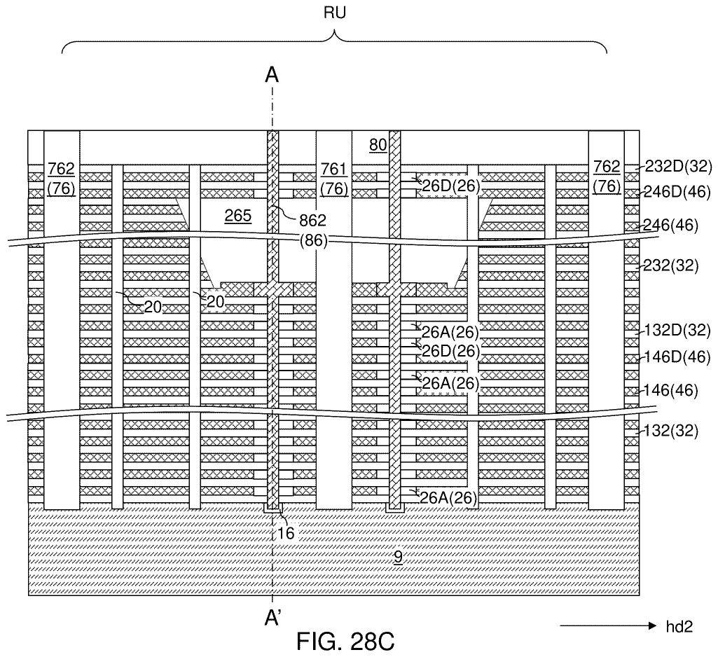

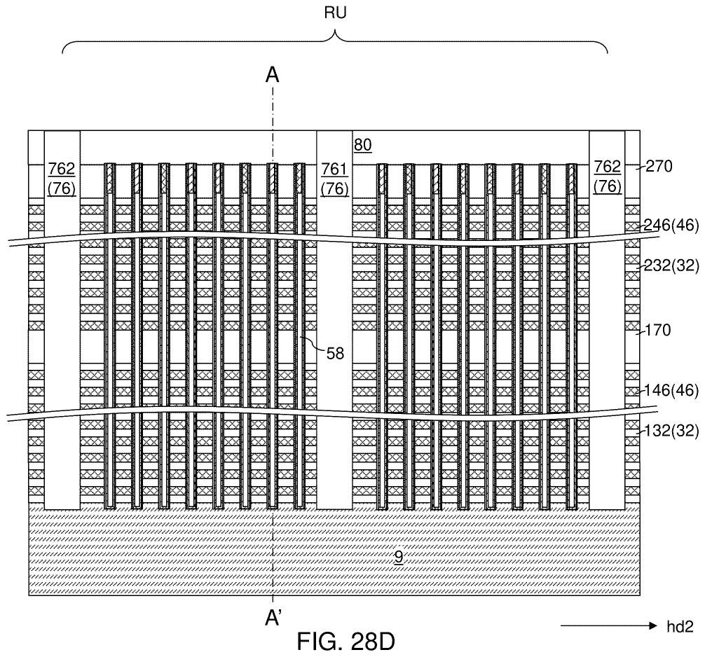

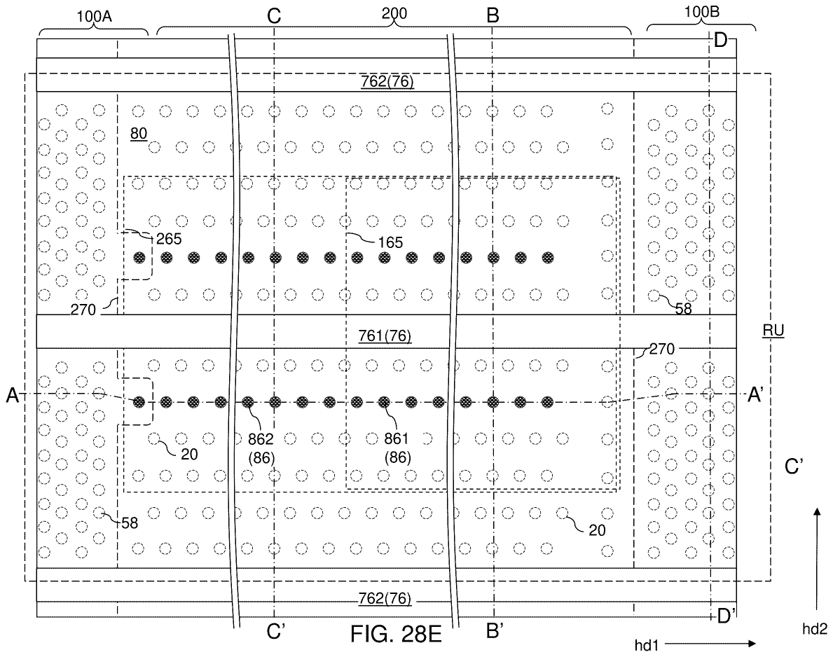

Referring to FIGS. 28A-28E, at least one electrically conductive material, such as a combination of a metallic barrier liner material and an electrically conductive fill material, can be conformally deposited in the through-via cavities 87 directly on physically exposed surface segments of the electrically conductive layers 46. Excess portions of the at least one electrically conductive material may be removed from above the horizontal plane including the top surface of the contact-level dielectric layer 80 by a planarization process, which may comprise a recess etch process and/or a chemical mechanical polishing process. Each remaining portion of the at least one electrically conductive material filling a respective one of the through-via cavities 87 constitute a through-via contact structure 86. The through-via contact structures 86 comprise first-tier-contact through-via contact structures 861 that contact a respective one of the first-tier electrically conductive layers 461, and second-tier-contact through-via contact structures 862 that contact a respective one of the second-tier electrically conductive layers 462.

Each through-via contact structure 86 vertically extends through a respective retro-stepped dielectric material portion (165 or 265) and a set of at least one electrically conductive layer 46 located within a same tier structure as the respective retro-stepped dielectric material portion (165 or 265) and underlies the respective retro-stepped dielectric material portion (165 or 265). Each through-via contact structure 86 is electrically connected to, and is in direct contact with, a topmost electrically conductive layer 46 within the set of at least one electrically conductive layer 46. If the set of at least one electrically conductive layer 46 comprises a plurality of electrically conductive layers 46, the through-via contact structure 86 is laterally spaced from, and is electrically isolated from, each electrically conductive layer 46 within the set except the topmost electrically conductive layer 46 within the set by at least one annular dielectric spacer 26. In case the through-via contact structure 86 vertically extends through any opening in any other electrically conductive layer 46 that overlies the tier structure or underlies the tier structure, the through-via contact structure 86 is laterally spaced from, and is electrically isolated from, any such electrically conductive layer 46 by a respective annular dielectric spacer 26.

At least a predominant fraction (i.e., greater than 50%) of the through-via contact structure 86 vertically extends through the at least one dummy electrically conductive layer (146D or 246D), through a portion of a respective retro-stepped dielectric material portion (165 or 265) having a horizontal bottom surface segment, and a subset of the active electrically conductive layers (146, 246) that underlies the horizontal bottom surface segment of the retro-stepped dielectric material portion (165 or 265). The predominant fraction may comprise all through-substrate via structures 86 that contacts any active electrically conductive layer (146, 246) other than a topmost active electrically conductive layer (142 or 246) in a tier structure. In some embodiment, each of the through-via contact structure 86 vertically extends through the at least one dummy electrically conductive layer (146D or 246D), through a portion of a respective retro-stepped dielectric material portion (165 or 265) having a horizontal bottom surface segment, and a subset of the active electrically conductive layers (146, 246) that underlies the horizontal bottom surface segment of the retro-stepped dielectric material portion (165 or 265).

For any arbitrarily selected through-via contact structure 86, the through-via contact structure 86 vertically extends through a horizontal bottom surface segment of a respective one of the retro-stepped dielectric material portions (165, 265), and a respective subset of the active electrically conductive layers (146, 246) underlies the horizontal plane including the horizontal bottom surface segment of the respective one of the retro-stepped dielectric material portions (165, 265). The through-via contact structure 86 is electrically connected to and directly contacts a topmost active electrically conductive layer (146, 246) within the subset.

For each through-via contact via structure 86 vertically extending through each of the at least one dummy electrically conductive layer (146D or 246D), the through-via contact structure 86 vertically extends through the retro-stepped dielectric material portion (165 or 265), and a subset of the active electrically conductive layers (146, 246) that underlies a horizontal bottom surface of the retro-stepped dielectric material portion (165 or 265), and is electrically connected to a topmost active electrically conductive layer (146, 246) within the subset. The through-via contact structure 86 is electrically isolated from each active electrically conductive layer (146, 246) within the subset except the topmost active electrically conductive layer (146, 246) by at least one annular dielectric spacer 26. The through-via contact structure 86 is also electrically isolated from each of the at least one dummy electrically conductive layer (146D or 246D) by at least one dummy-level annular dielectric spacer 26D.

For each through-via contact via structure 86, a cylindrical surface segment of the through-via contact structure 86 is in contact with the retro-stepped dielectric material portion (165 or 265). A semiconductor material layer (which may comprise the substrate 9 or a source structure that subsequently replaces the substrate 9) underlies each alternating stack (32, 46). For each through-via contact via structure 86, a bottom surface of the through-via contact structure 86 is located below a horizontal plane including a top surface of the semiconductor material layer.

In one embodiment, a contact-level dielectric layer 80 overlies the alternating stack (32, 46). A top surface of each through-via contact structure 86 can be located within a horizontal plane including a top surface of the contact-level dielectric layer 80. Within each tier structure, an insulating cap layer (170 or 270) having a bottom surface located within or above a horizontal plane including a top surface of a retro-stepped dielectric material portion (165 or 265) is provided. Each memory opening fill structure 58 vertically extends through the insulating cap layer (170 or 270). Within each tier structure, each of the at least one dummy electrically conductive layer (146D or 246D) can be located entirely between a first horizontal plane including a bottom surface of the insulating cap layer (170 or 270) of the tier structure and a second horizontal plane including a top surface of the insulating cap layer (170 or 270) of the tier structure. In one embodiment, top surfaces of the memory opening fill structures 58 can be located within a horizontal plane including a top surface of the insulating cap layer (such as the second-tier insulating cap layer 270) of the topmost tier structure.

In one embodiment, support pillar structures 20 vertically extend through the alternating stack (32, 46) and have top surfaces located within a horizontal plane including a bottom surface of the contact-level dielectric layer 80. In one embodiment, the support pillar structures 20 vertically extend through the retro-stepped dielectric material portion (165 or 265).

Within each tier structure, an insulating cap layer (170 or 270) can overlie each of the active electrically conductive layers (146, 246) and can have a bottom surface located within or above a bottommost surface of the at least one dummy electrically conductive layer (146D or 246D). The insulating cap layer (170 or 270) can contact sidewalls of the memory opening fill structures 58. In one embodiment, a predominant fraction of the through-via contact structures 86 may be laterally spaced from the insulating cap layer (170 or 270), and may comprise a sidewall segment that contacts the contact-level dielectric layer 80.

In one embodiment, an opening can be formed in a stack of at least one dummy insulating layer (132D or 232D) and at least one dummy electrically conductive layer (146D or 246D) over a locally thickened portion of a topmost active electrically conductive layer (146 or 246) in a tier structure. For through-via contact structures 86 contacting such a topmost active electrically conductive layer (146 or 246), the through-via contact structure 86 may vertically extend through the contact-level dielectric layer 80, the insulating cap layer (170 or 270), and a portion of the retro-stepped dielectric material portion (165 or 265).

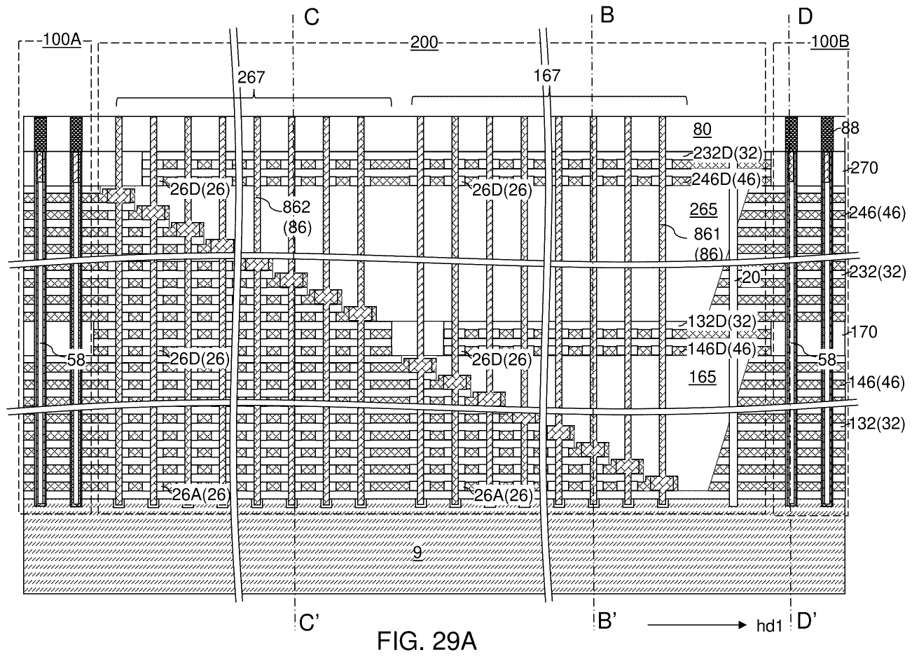

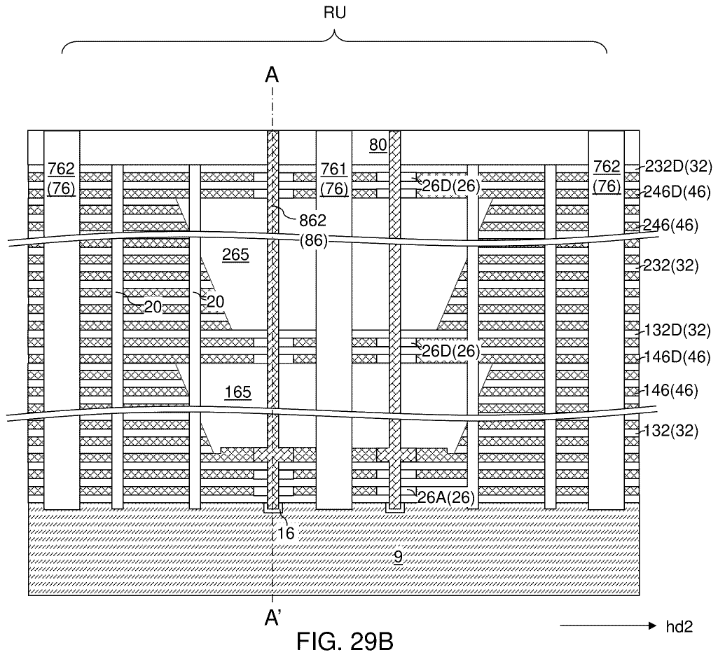

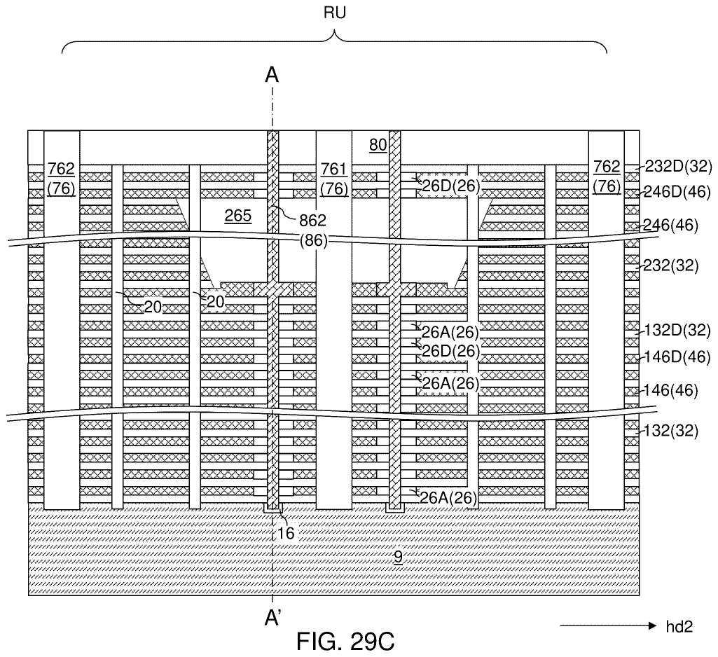

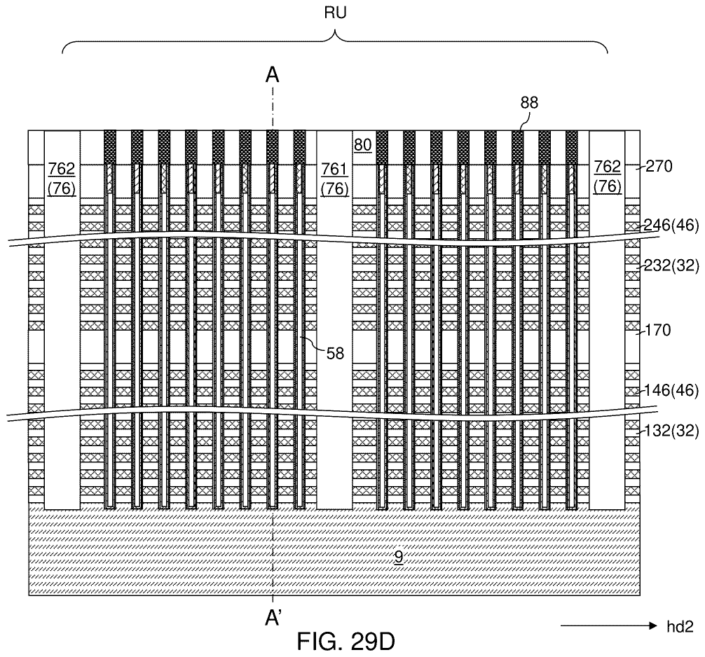

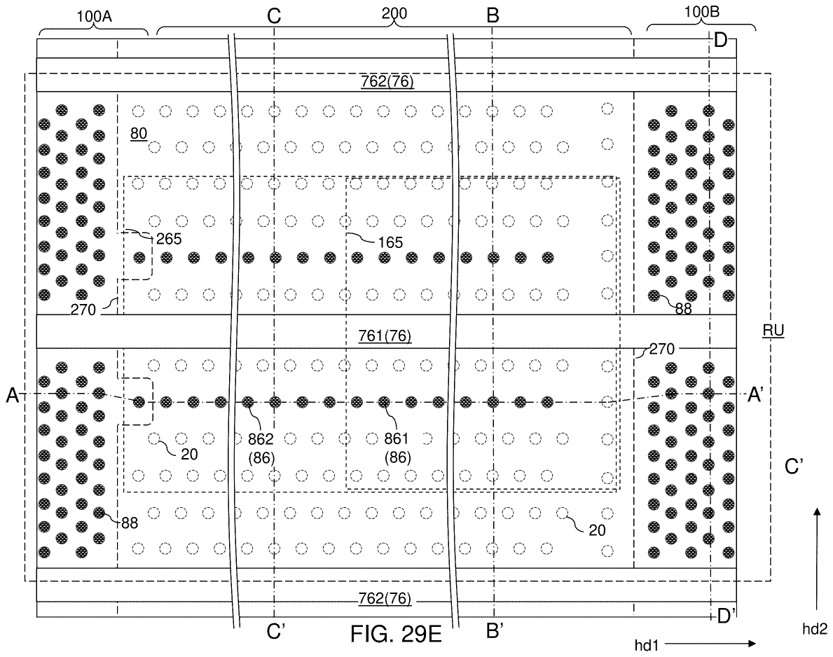

Referring to FIGS. 29A-29E, drain contact via structures 88 can be formed through the contact-level dielectric layer 80 on the drain regions 63 within the memory opening fill structures 58. Each drain region 634 may be contacted by a respective one of the drain contact via structures 88.

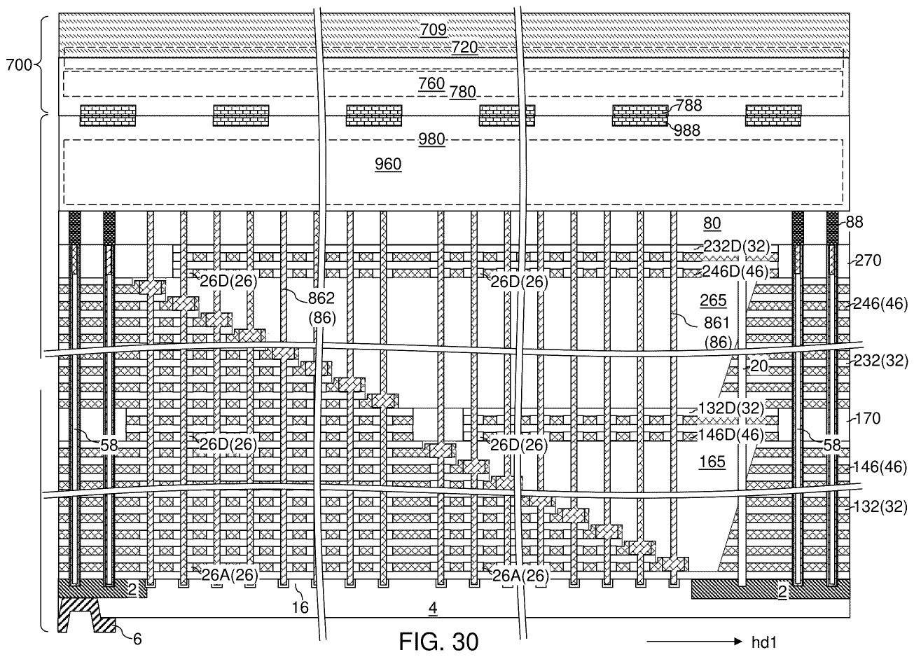

Referring to FIG. 30, additional dielectric material layers can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The dielectric material layers that are formed above the contact-level dielectric layer 80 are herein collectively referred to as memory-side dielectric material layers 960. The additional metal interconnect structures are collectively referred to as memory-side dielectric material layers 960. The memory-side dielectric material layers 960 comprise a bit-line-level dielectric material layer embedding bit lines, which are a subset of the memory-side metal interconnect structures 980.

Metal bonding pads, which are herein referred to as memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the alternating stacks of insulating layers 32 and electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer of the memory-side dielectric material layers 960. The memory-side bonding pads 988 can be electrically connected to the memory-side metal interconnect structures 980.

In summary, the memory die 900 comprises a memory array (32, 46, 58), memory-side metal interconnect structures 980, and memory-side bonding pads 988 embedded within memory-side dielectric material layers 960. The memory array may comprise a three-dimensional memory array including an alternating stack of insulating layers 32 and electrically conductive layers 46, and further comprises a two-dimensional array of NAND strings (e.g., memory opening fill structures 58) vertically extending through the alternating stack (32, 46). In one embodiment, the electrically conductive layers 46 comprise word lines and select gate electrodes of the two-dimensional array of NAND strings. In one embodiment, the memory-side metal interconnect structures 980 comprise bit lines for the two-dimensional array of NAND strings.

Further, a logic die 700 can be provided. The logic die 700 includes a logic-side substrate 709, a peripheral circuit 720 located on the logic-side substrate 709 and comprising logic-side semiconductor devices (such as field effect transistors), logic-side metal interconnect structures 780 embedded within logic-side dielectric material layers 760, and logic-side bonding pads 778. The peripheral circuit 720 can be configured to control operation of the memory array within the memory die 900. Specifically, the peripheral circuit 720 can be configured to drive various electrical components within the memory array including, but not limited to, the electrically conductive layers 46, the drain regions 63, and a source contact structure to be subsequently formed. The peripheral circuit 720 can be configured to control operation of the vertical stack of memory elements in the memory array in the memory die 900. Particularly, the peripheral circuit 720 comprises word line driver transistors configured to drive the word lines in the memory die 900.

The logic die 700 can be attached to the memory die 900, for example, by bonding the logic-side bonding pads 788 to the memory-side bonding pads 988 at a bonding interface. The bonding between the memory die 900 and the logic die 700 may be performed employing a wafer-to-wafer bonding process in which a two-dimensional array of memory dies 900 is bonded to a two-dimensional array of logic dies 700, by a die-to-die bonding process, or by a die-to-wafer bonding process. The logic-side bonding pads 788 within each logic die 700 can be bonded to the memory-side bonding pads 988 within a respective memory die 900.

The substrate 9 can be removed, for example, by grinding, polishing, cleaving, an isotropic etch process, an anisotropic etch process, and/or a combination thereof. In one embodiment, at least a terminal step of at least one removal process that is employed to remove the substrate 9 may comprise a selective wet etch process that etches the material of the substrate 9 (such as a semiconductor material of the substrate 9) selective to dielectric materials of the memory films 50. In an illustrative example, if the substrate 9 comprises silicon, the terminal step of the at least one removal process may comprise a wet etch process using hot trimethyl-2 hydroxyethyl ammonium hydroxide (“hot TMY”) or tetramethyl ammonium hydroxide (TMAH). The entirety of the substrate 9 can be removed by the selective wet etch process. Backside end surfaces of the support pillar structures (not shown) can be physically exposed upon removal of the substrate 9.

An end portion of each memory opening fill structure 58 can be removed. In one embodiment, an end portion of each memory film 50 may be removed by performing a sequence of wet etch processes. A horizontal end portion of each vertical semiconductor channel 60 may be physically exposed. In one embodiment, the sequence of wet etch processes may be selective to the material of the vertical semiconductor channels 60.

At least one source structure 2 (e.g., a source region and/or source line) can be formed in contact vertical semiconductor channels 60. The at least one source structure 2 may comprise a heavily doped semiconductor material and/or a metallic material (e.g., a metal and/or an electrically conductive metal nitride or silicide). A backside dielectric layer 4 and backside contact structures 6 can be subsequently formed.

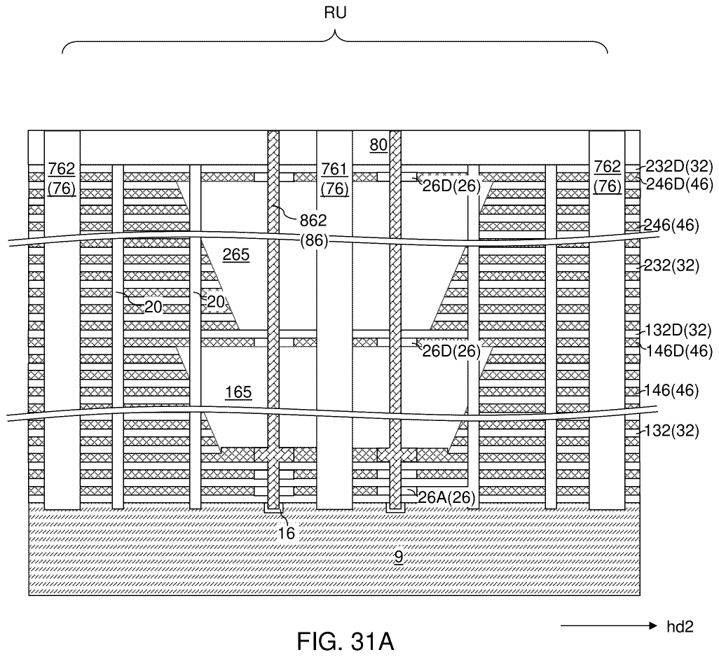

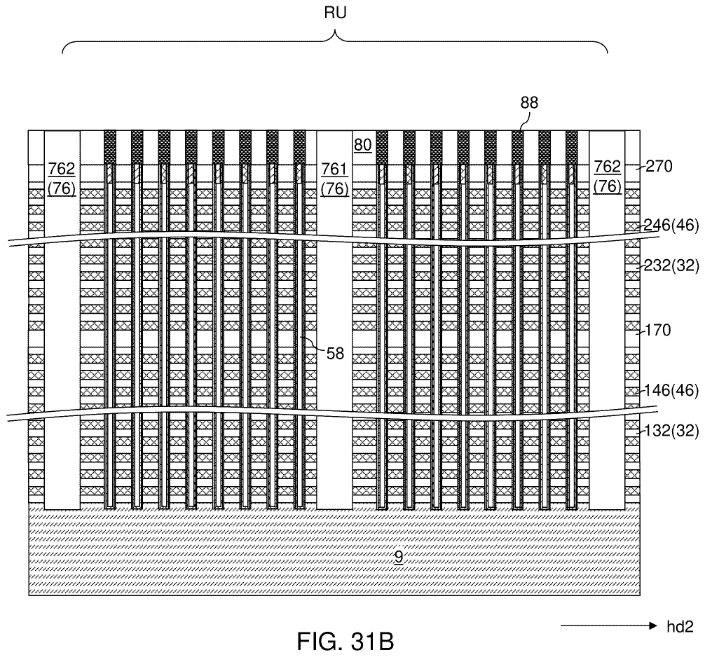

Referring to FIGS. 31A and 31B, a second exemplary structure is illustrated after formation of through-via contact structures 86 and drain contact via structures 88 according to an embodiment of the present disclosure. The second exemplary structure can be derived from the first exemplary structure by employing a single pair of a dummy insulating layer (132D or 232D) and a dummy electrically conductive layer (146D or 246D) within each tier structure.

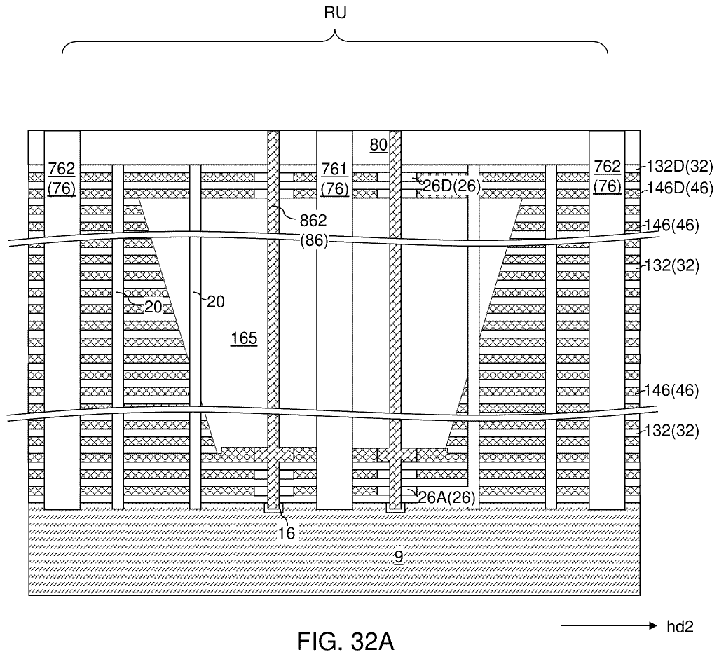

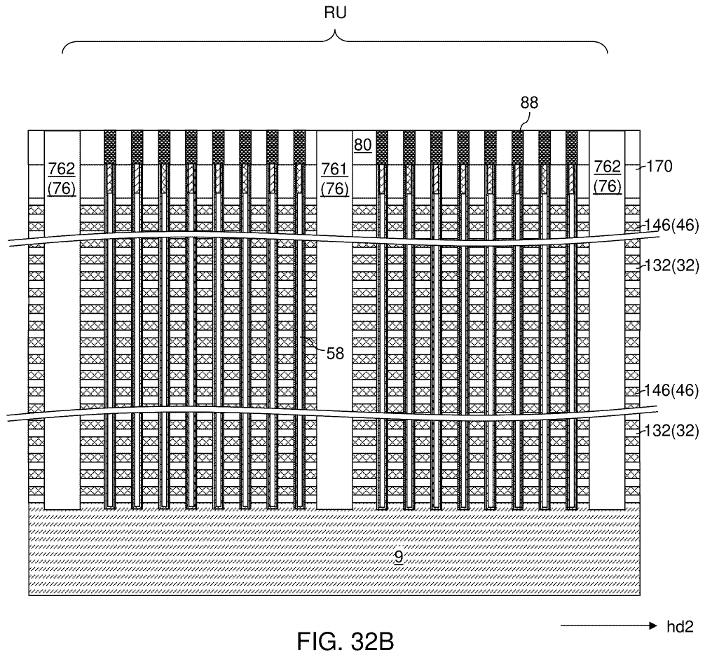

Referring to FIGS. 32A and 32B, a third exemplary structure is illustrated after formation of through-via contact structures 86 and drain contact via structures 88 according to an embodiment of the present disclosure. The third exemplary structure can be derived from the first exemplary structure or the second exemplary structure by employing a single tier structure, such as the first tier structure only, in lieu of a vertical stack of multiple tier structures.

Referring collectively to all drawings and according to various embodiments of the present disclosure, a device structure is provided, which comprises: an alternating stack (32, 46) of insulating layers 32 and electrically conductive layers 46 embedding a retro-stepped dielectric material portion (165 or 265), wherein the electrically conductive layers 46 comprise active electrically conductive layers (146, 246) located below a horizontal plane including a topmost surface of the retro-stepped dielectric material portion (165 or 265) and at least one dummy electrically conductive layer (146D or 246D) overlying the retro-stepped dielectric material portion (165 or 265); memory openings 49 vertically extending through each of the active electrically conductive layers (146, 246) and laterally spaced from each of the at least one dummy electrically conductive layer (146D or 246D); and memory opening fill structures 58 located in the memory openings 49, wherein each of the memory opening fill structures 58 comprises a respective vertical stack of memory elements located at levels of the active electrically conductive layers (146, 246), a vertical semiconductor channel vertically extending through each of the active electrically conductive layers (146, 246), and a drain region located above the horizontal plane.

In one embodiment, the device structure also comprises a through-via contact structure 86 vertically extending through the retro-stepped dielectric material portion (165 or 265), a subset of the active electrically conductive layers (146, 246) that underlies a horizontal bottom surface of the retro-stepped dielectric material portion (165 or 265), and each of the at least one dummy electrically conductive layer (146D or 246D), and electrically connected to a topmost active electrically conductive layer (146, 246) within the subset. In one embodiment, the through-via contact structure 86 is electrically isolated from each active electrically conductive layer (146, 246) within the subset except the topmost active electrically conductive layer (146, 246) by at least one annular dielectric spacer 26. In one embodiment, the through-via contact structure 86 is electrically isolated from each of the at least one dummy electrically conductive layer (146D or 246D) by at least one dummy-level annular dielectric spacer 26D. In one embodiment, a cylindrical surface segment of the through-via contact structure 86 is in contact with the retro-stepped dielectric material portion (165 or 265). In one embodiment, the device structure comprises a semiconductor material layer (2 or 9) that underlies the alternating stack (32, 46), wherein a bottom surface of the through-via contact structure 86 is located below a horizontal plane including a top surface of the semiconductor material layer.

In one embodiment, the device structure comprises a contact-level dielectric layer 80 overlying the alternating stack (32, 46), wherein a top surface of the through-via contact structure 86 is located within a horizontal plane including a top surface of the contact-level dielectric layer 80. In one embodiment, the device structure comprises an insulating cap layer (170 or 270) having a bottom surface located within or above a horizontal plane including a top surface of the retro-stepped dielectric material portion (165 or 265), wherein the memory openings 49 vertically extend through the insulating cap layer (170 or 270). In one embodiment, top surfaces of the memory opening fill structures 58 are located within a horizontal plane including a top surface of the insulating cap layer (170 or 270).

In one embodiment, each of the at least one dummy electrically conductive layer (146D or 246D) is located entirely between a first horizontal plane including a bottom surface of the insulating cap layer (170 or 270) and a second horizontal plane including a top surface of the insulating cap layer (170 or 270). In one embodiment, the device structure comprises support pillar structures 20 vertically extending through the alternating stack (32, 46) and having top surfaces located within a horizontal plane including a bottom surface of the contact-level dielectric layer 80. In one embodiment, the support pillar structures 20 vertically extend through the retro-stepped dielectric material portion (165 or 265).

In one embodiment, the insulating cap layer (170 or 270) overlies each of the active electrically conductive layers (146, 246) and has a bottom surface located within or above a bottommost surface of the at least one dummy electrically conductive layer (146D or 246D). In one embodiment, the through-via contact structure 86 is laterally spaced from the insulating cap layer (170 or 270), and comprises a sidewall segment that contacts the contact-level dielectric layer 80. In one embodiment, the device structure comprises an additional through-via contact structure 86 vertically extending through the contact-level dielectric layer 80, the insulating cap layer (170 or 270), and a portion of the retro-stepped dielectric material portion (165 or 265) and in direct contact with a topmost active electrically conductive layer (146, 246) of the active electrically conductive layers (146, 246) of the alternating stack (32, 46).

In one embodiment, the retro-stepped dielectric material portion (165, 265) overlies stepped surfaces of the electrically conductive layers 46 that form a staircase region (167, 267). The memory opening fill structures 58 are located in memory array regions (100A, 100B) which are laterally separated from the staircase region (167, 267) along the first horizontal direction hd1. The active electrically conductive layers (146, 246) are located in the staircase region (167, 267) and in the memory array regions (100A, 100B), while the at least one dummy electrically conductive layer (146D, 246D) is located in the staircase region (167, 267) but not in the memory array regions (100A, 100B).

The various embodiments of the present disclosure provide at least one dummy electrically conductive layer (146D, 246D) to reduce deformation and yield loss associated with patterned stepped surfaces in a contact region 200 of a three-dimensional memory device. Deformation of alternating stacks of insulating layers 32 and electrically conductive layers 46 due to presence of lateral isolation trenches 79 can result in tilting of the alternating stacks and subsidence issues. By incorporating a stack of at least one dummy insulating layer (132D or 232D) and at least one dummy electrically conductive layer (146D or 246D) between the lateral isolation trenches 79, embodiments of the present disclosure mitigate deformation caused by stress induced by asymmetric patterns of the active electrically conductive layers (146, 246). This configuration reduces the occurrence of structural irregularities during and after the fill processes, contributing to the stability of the alternating stack (32, 42).

The stack of at least one dummy insulating layer (132D or 232D) and at least one dummy electrically conductive layer (146D or 246D) is confined to areas of the patterned stepped surfaces in the contact region (200), and does not extend into the memory array regions (100A, 100B). Thus, there is no need to electrically bias the dummy electrically conductive layers (146D or 246D) during operation of the three-dimensional memory array of the present disclosure. In some embodiments, multiple pairs of dummy insulating layers (132D or 232D) and dummy electrically conductive layers (146D or 246D) may be employed to suppress the deformation of patterned stepped surfaces in the contact region 200. Thus, embodiments of the present disclosure may be employed to reduce deformation in patterned stepped surfaces in the contact region 200 in a three-dimensional memory device, and to increase the yield of the three-dimensional memory device during a manufacture process.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A device structure, comprising:
an alternating stack of insulating layers and electrically conductive layers embedding a retro-stepped dielectric material portion, wherein the electrically conductive layers comprise active electrically conductive layers located below a horizontal plane including a topmost surface of the retro-stepped dielectric material portion and at least one dummy electrically conductive layer overlying the retro-stepped dielectric material portion;
memory openings vertically extending through each of the active electrically conductive layers and laterally spaced from each of the at least one dummy electrically conductive layer; and
memory opening fill structures located in the memory openings, wherein each of the memory opening fill structures comprises a respective vertical stack of memory elements located at levels of the active electrically conductive layers, a vertical semiconductor channel vertically extending through each of the active electrically conductive layers, and a drain region located above the horizontal plane.

2. The device structure of claim 1, further comprising a through-via contact structure vertically extending through the retro-stepped dielectric material portion, a subset of the active electrically conductive layers that underlies a horizontal bottom surface of the retro-stepped dielectric material portion, and each of the at least one dummy electrically conductive layer, and electrically connected to a topmost active electrically conductive layer within the subset.

3. The device structure of claim 2, wherein the through-via contact structure is electrically isolated from each active electrically conductive layer within the subset except the topmost active electrically conductive layer by at least one annular dielectric spacer.

4. The device structure of claim 3, wherein the through-via contact structure is electrically isolated from each of the at least one dummy electrically conductive layer by at least one dummy-level annular dielectric spacer.

5. The device structure of claim 2, wherein a cylindrical surface segment of the through-via contact structure is in contact with the retro-stepped dielectric material portion.

6. The device structure of claim 2, further comprising a semiconductor material layer that underlies the alternating stack, wherein a bottom surface of the through-via contact structure is located below a horizontal plane including a top surface of the semiconductor material layer.

7. The device structure of claim 2, further comprising a contact-level dielectric layer overlying the alternating stack, wherein a top surface of the through-via contact structure is located within a horizontal plane including a top surface of the contact-level dielectric layer.

8. The device structure of claim 7, further comprising an insulating cap layer having a bottom surface located within or above a horizontal plane including a top surface of the retro-stepped dielectric material portion, wherein the memory openings vertically extend through the insulating cap layer.

9. The device structure of claim 8, wherein top surfaces of the memory opening fill structures are located within a horizontal plane including a top surface of the insulating cap layer.

10. The device structure of claim 7, wherein each of the at least one dummy electrically conductive layer is located entirely between a first horizontal plane including a bottom surface of the insulating cap layer and a second horizontal plane including a top surface of the insulating cap layer.

11. The device structure of claim 7, further comprising support pillar structures vertically extending through the alternating stack and having top surfaces located within a horizontal plane including a bottom surface of the contact-level dielectric layer.

12. The device structure of claim 11, wherein the support pillar structures vertically extend through the retro-stepped dielectric material portion.

13. The device structure of claim 8, wherein:
the bottom surface of the insulating cap layer is located within or above a bottommost surface of the at least one dummy electrically conductive layer; and
the through-via contact structure is laterally spaced from the insulating cap layer, and comprises a sidewall segment that contacts the contact-level dielectric layer.

14. The device structure of claim 13, further comprising an additional through-via contact structure vertically extending through the contact-level dielectric layer, the insulating cap layer, and a portion of the retro-stepped dielectric material portion and in direct contact with a topmost active electrically conductive layer of the active electrically conductive layers of the alternating stack.

15. The device structure of claim 1, wherein:
the retro-stepped dielectric material portion overlies stepped surfaces of the electrically conductive layers that form a staircase region;
the memory opening fill structures are located in memory array regions which are laterally separated from the staircase region;
the active electrically conductive layers are located in the staircase region and in the memory array regions; and
the at least one dummy electrically conductive layer is located in the staircase region but not in the memory array regions.

16. A method of forming a device structure, comprising:
forming an alternating stack of insulating layers and active sacrificial material layers embedding a retro-stepped dielectric material portion over a substrate;
forming at least one dummy sacrificial material layer over the retro-stepped dielectric material portion such that the at least one dummy sacrificial material layer does not cover a memory array region in a plan view;
forming memory openings through the alternating stack in the memory array region;
forming memory opening fill structures in the memory openings, wherein each of the memory openings comprises a respective vertical stack of memory elements and a vertical semiconductor channel;
forming lateral isolation trenches through a combination of the alternating stack, the retro-stepped dielectric material portion, and the at least one dummy sacrificial material layer; and
replacing remaining portions of the active sacrificial material layers and the at least one dummy sacrificial material layer with electrically conductive layers, wherein the electrically conductive layers comprise active electrically conductive layers that replace the remaining portions of the active sacrificial material layers and at least one dummy electrically conductive layer that replaces remaining portions of the at least one dummy sacrificial material layer.

17. The method of claim 16, further comprising forming a through-via contact structure through the at least one dummy electrically conductive layer, through a portion of the retro-stepped dielectric material portion, and a subset of the active electrically conductive layers that underlies the portion of the retro-stepped dielectric material portion, wherein the through-via contact structure is electrically connected to a topmost active electrically conductive layer within the subset.

18. The method of claim 17, further comprising forming a contact via cavity through the at least one dummy sacrificial material layer, through the retro-stepped dielectric material portion having a planar bottom surface segment, and a subset of the active sacrificial material layers that underlies the planar bottom surface segment, wherein the through-via contact structure fills a volume of the contact via cavity.

19. The method of claim 18, further comprising:
forming annular recess regions by laterally recessing proximal portions of the active sacrificial material layers and the at least one dummy sacrificial material layer that are proximal to the contact via cavity; and
forming annular dielectric spacers within a subset of the annular recess regions.

20. The method of claim 19, further comprising:
forming a sacrificial through-via structure within the volume of the contact via cavity and within a volume of an annular recess region that is not filled with the annular dielectric spacers; and
replacing the sacrificial through-via structure with the through-via contact structure which is isolated from the at least one dummy electrically conductive layer by at least one of the annular dielectric spacers.
